(19) United States
(12) Patent Application Publication
(10) Pub. No.: US 2025/0372522 A1
(43) Pub. Date: Dec. 4, 2025

(54) THREE-DIMENSIONAL MEMORY DEVICE CONTAINING TOP SOURCE CONTACT TO DOPED SEMICONDUCTOR SOURCE TIPS AND METHODS FOR FORMING THE SAME

(71) Applicant: SANDISK TECHNOLOGIES LLC, ADDISON, TX (US)

(72) Inventor: Masato NOGUCHI, Yokkaichi (JP)

(21) Appl. No.: 18/789,041

(22) Filed: Jul. 30, 2024

Related U.S. Application Data
(60) Provisional application No. 63/655,829, filed on Jun. 4, 2024.

(51) Int. Cl. H01L 23/532; G11C 16/04; H01L 23/528; H10B 41/10; H10B 41/27; H10B 41/35; H10B 43/10; H10B 43/27; H10B 43/35

(52) U.S. Cl. CPC H01L 23/53295; G11C 16/0483; H01L 23/5283; H10B 41/10; H10B 41/27; H10B 41/35; H10B 43/10; H10B 43/27; H10B 43/35

(57) ABSTRACT

An alternating stack of insulating layers and spacer material layers is formed over a substrate. The spacer material layers are formed as, or are subsequently replaced with, electrically conductive layers. A memory opening is formed through the alternating stack. A memory material layer, a semiconductor source structure, a vertical semiconductor channel, a dielectric core, and a drain region are formed in the memory opening. Dopants in the semiconductor source structure are activated after formation of the drain region. Subsequently, the substrate and a bottom portion of the memory film are removed and a metallic source layer is formed on the semiconductor source structure.

### FIELD

The present disclosure relates generally to the field of semiconductor devices, and particularly to a three-dimensional memory device containing a top source contact to doped semiconductor source tips and methods for manufacturing the same.

### BACKGROUND

Three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a memory device comprises: an alternating stack of insulating layers and electrically conductive layers located over a semiconductor material layer; a memory opening vertically extending through the alternating stack and through the semiconductor material layer; and a memory opening fill structure located in the memory opening and comprising a vertical semiconductor channel that vertically extends through each electrically conductive layer in the alternating stack, a semiconductor source structure adjoined to a first end of the vertical semiconductor channel and laterally surrounded by the semiconductor material layer, and a drain region contacting a second end of the vertical semiconductor channel, wherein the semiconductor source structure comprises a pillar semiconductor source portion having a first width along a horizontal direction and a tubular semiconductor source portion having an inner cavity and an outer cylindrical surface which has a second width along the horizontal direction, the second width being greater than the first width.

According to another aspect of the present disclosure, a method of forming a device structure comprises: forming a semiconductor material layer and an alternating stack of insulating layers and spacer material layers over a semiconductor substrate, wherein the spacer material layers are formed as, or are subsequently replaced with, electrically conductive layers; forming a memory opening vertically extending through the alternating stack, the semiconductor material layer, and an upper portion of the semiconductor substrate; oxidizing surface portions of the semiconductor material layer and the semiconductor substrate around a bottom portion of the memory opening, whereby a semiconductor oxide spacer structure including a first cylindrical portion having a first thickness at a level of the semiconductor substrate and a second cylindrical portion having a second thickness at a level of the semiconductor material layer is formed, and wherein the first thickness is greater than the second thickness; forming a memory opening fill structure comprising a memory film, a semiconductor source structure, a vertical semiconductor channel, a dielectric core, and a drain region in a remaining volume of the memory opening; removing the semiconductor substrate, a bottom portion of the semiconductor oxide spacer structure, and a bottom portion of the memory film; and forming a metallic source layer on the semiconductor source structure.

According to yet another aspect of the present disclosure, a memory device comprises: an alternating stack of insulating layers and electrically conductive layers; a memory opening vertically extending through the alternating stack; a memory opening fill structure located in the memory opening and comprising a memory film, a vertical semiconductor channel, a semiconductor source structure adjoined to a first end of the vertical semiconductor channel, and a drain region contacting a second end of the vertical semiconductor channel; and a metallic source layer that contacts a bottom end and a sidewall surface of the semiconductor source structure.

According to still another aspect of the present disclosure, a method of forming a device structure comprises: forming an alternating stack of insulating layers and spacer material layers over a substrate, wherein the spacer material layers are formed as, or are subsequently replaced with, electrically conductive layers; forming a memory opening vertically extending through the alternating stack, wherein a volume of a void within the memory opening has a stepped vertical cross-sectional profile including a straight upper cylindrical sidewall, a straight lower cylindrical sidewall, and a horizontal annular surface segment that connects the straight upper cylindrical sidewall and the straight lower cylindrical sidewall; forming a memory opening fill structure comprising a memory material layer, a semiconductor source structure, a vertical semiconductor channel, a dielectric core, and a drain region in a remaining volume of the memory opening; removing the substrate and a bottom portion of the memory film; and forming a metallic source layer on the semiconductor source structure.

### BRIEF DESCRIPTION OF THE DRAWINGS

FIG. 1 is a schematic vertical cross-sectional view of a first exemplary structure after formation of a backside insulating layer, a semiconductor material layer, and an alternating stack of insulating layers and sacrificial material layers over a semiconductor substrate according to a first embodiment of the present disclosure.

FIG. 2 is a schematic vertical cross-sectional view of the first exemplary structure after formation of stepped surfaces and a stepped dielectric material portion according to the first embodiment of the present disclosure.

FIG. 3A is a schematic vertical cross-sectional view of the first exemplary structure after formation of memory openings and support openings according to the first embodiment of the present disclosure. FIG. 3B is a top-down view of the first exemplary structure of FIG. 3A. The hinged vertical cross-sectional plane A-A′ is the cut plane of the vertical cross-sectional view of FIG. 3A.

FIG. 4 is a schematic vertical cross-sectional view of the first exemplary structure after formation of sacrificial opening fill structures according to the first embodiment of the present disclosure.

FIG. 5 is a vertical cross-sectional view of the first exemplary structure after formation of support pillar structures according to the first embodiment of the present disclosure.

FIG. 6 is a schematic vertical cross-sectional view of the first exemplary structure after removal of sacrificial memory opening fill structures according to the first embodiment of the present disclosure.

FIGS. 7A-7J are sequential vertical cross-sectional views of a memory opening in the first exemplary structure during formation of a memory opening fill structure according to the first embodiments of the present disclosure.

FIG. 8A is a schematic vertical cross-sectional view of the first exemplary structure after formation of memory opening fill structures according to the first embodiment of the present disclosure. FIG. 8B is a top-down view of the first exemplary structure of FIG. 8A. The vertical plane A-A′ is the cut plane of the vertical cross-sectional view of FIG. 8A.

FIG. 9A is a vertical cross-sectional view of the first exemplary structure after formation of a contact-level dielectric layer, lateral isolation trenches, and semiconductor oxide barrier layers according to the first embodiment of the present disclosure. FIG. 9B is a top-down view of the first exemplary structure of FIG. 9A. The vertical plane A-A′ is the cut plane of the vertical cross-sectional view of FIG. 9A.

FIG. 10 is a vertical cross-sectional view of the first exemplary structure after formation of laterally-extending cavities according to the first embodiment of the present disclosure.

FIG. 11A is a schematic vertical cross-sectional view of the first exemplary structure after formation of electrically conductive layers according to the first embodiment of the present disclosure. FIG. 11B is a magnified view of a region around a memory opening fill structure in the first exemplary structure of FIG. 11A.

FIG. 12A is a vertical cross-sectional view of the first exemplary structure after formation of lateral isolation trench fill structures and drain-select-level isolation structures according to the first embodiment of the present disclosure. FIG. 12B is a top-down view of the first exemplary structure of FIG. 12A. The hinged vertical cross-sectional plane A-A′ in FIG. 12B is the cut plane of the vertical cross-sectional view of FIG. 12A.

FIG. 13A is a vertical cross-sectional view of the first exemplary structure after formation of layer contact via structures and drain contact via structures according to the first embodiment of the present disclosure. FIG. 13B is a top-down view of the first exemplary structure of FIG. 13A. The vertical plane A-A′ is the cut plane of the vertical cross-sectional view of FIG. 13A.

FIG. 14 is a vertical cross-sectional view of the first exemplary structure after formation of a memory die according to the first embodiment of the present disclosure.

FIG. 15 is a vertical cross-sectional view of a logic die according to the first embodiment of the present disclosure.

FIG. 16 is a vertical cross-sectional view of the first exemplary structure after attaching the logic die to the memory die according to the first embodiment of the present disclosure.

FIG. 17A is a vertical cross-sectional view of the first exemplary structure after removal of the semiconductor substrate according to the first embodiment of the present disclosure. FIG. 17B is a magnified view of a region around a memory opening fill structure in the first exemplary structure of FIG. 17A.

FIGS. 18A and 18B are sequential vertical cross-sectional views of a region around a memory opening fill structure during removal of the backside insulating layer and end portions of a memory film and formation of a metallic source layer according to the first embodiment of the present disclosure.

FIG. 19 is a vertical cross-sectional view of the first exemplary structure after formation of the metallic source layer according to the first embodiment of the present disclosure.

FIG. 20 is a vertical cross-sectional view of the first exemplary structure after formation of a backside dielectric layer and backside bonding pads according to the first embodiment of the present disclosure.

FIG. 21A is a schematic vertical cross-sectional view of a second exemplary structure after formation of memory openings and support openings according to the second embodiment of the present disclosure. FIG. 21B is a top-down view of the second exemplary structure of FIG. 21A. The hinged vertical cross-sectional plane A-A′ is the cut plane of the vertical cross-sectional view of FIG. 21A.

FIG. 22 is a schematic vertical cross-sectional view of the second exemplary structure after formation of sacrificial opening fill structures according to the second embodiment of the present disclosure.

FIG. 23 is a vertical cross-sectional view of the second exemplary structure after formation of support pillar structures according to the second embodiment of the present disclosure.

FIG. 24 is a schematic vertical cross-sectional view of the second exemplary structure after removal of sacrificial memory opening fill structures according to the second embodiment of the present disclosure.

FIGS. 25A-25N are sequential vertical cross-sectional views of a memory opening in the second exemplary structure during formation of a memory opening fill structure according to the second embodiments of the present disclosure.

FIG. 26A is a schematic vertical cross-sectional view of the second exemplary structure after formation of memory opening fill structures according to the second embodiment of the present disclosure. FIG. 26B is a top-down view of the second exemplary structure of FIG. 26A. The vertical plane A-A is the cut plane of the vertical cross-sectional view of FIG. 26A.

FIG. 27A is a vertical cross-sectional view of the second exemplary structure after formation of a contact-level dielectric layer, lateral isolation trenches, and semiconductor oxide barrier layers according to the second embodiment of the present disclosure. FIG. 27B is a top-down view of the second exemplary structure of FIG. 27A. The vertical plane A-A is the cut plane of the vertical cross-sectional view of FIG. 27A.

FIG. 28 is a vertical cross-sectional view of the second exemplary structure after formation of laterally-extending cavities according to the second embodiment of the present disclosure.

FIG. 29A is a schematic vertical cross-sectional view of the second exemplary structure after formation of electrically conductive layers according to the second embodiment of the present disclosure. FIG. 29B is a magnified view of a region around a memory opening fill structure in the second exemplary structure of FIG. 29A.

FIG. 30A is a vertical cross-sectional view of the second exemplary structure after formation of lateral isolation trench fill structures and drain-select-level isolation structures according to the second embodiment of the present disclosure. FIG. 30B is a top-down view of the second exemplary structure of FIG. 30A. The hinged vertical cross-sectional plane A-A′ in FIG. 30B is the cut plane of the vertical cross-sectional view of FIG. 30A.

FIG. 31A is a vertical cross-sectional view of the second exemplary structure after formation of layer contact via structures and drain contact via structures according to the second embodiment of the present disclosure. FIG. 31B is a top-down view of the second exemplary structure of FIG. 31A. The vertical plane A-A is the cut plane of the vertical cross-sectional view of FIG. 31A.

FIG. 32 is a vertical cross-sectional view of the second exemplary structure after formation of a memory die according to the second embodiment of the present disclosure.

FIG. 33 is a vertical cross-sectional view of the second exemplary structure after attaching the logic die to the memory die according to the second embodiment of the present disclosure.

FIG. 34A is a vertical cross-sectional view of the second exemplary structure after removal of a carrier substrate according to the second embodiment of the present disclosure.

FIG. 34B is a magnified view of a region around a memory opening fill structure in the second exemplary structure of FIG. 34A.

FIGS. 35A and 35B are sequential vertical cross-sectional views of a region around a memory opening fill structure in the second exemplary structure during removal of the backside insulating layer and end portions of a memory film and formation of a metallic source layer according to the second embodiment of the present disclosure.

FIG. 35C is a vertical cross-sectional view of a region around a memory opening fill structure in the second exemplary structure during removal of the backside insulating layer and end portions of a memory film and formation of a metallic source layer according to an alternative configuration of the second embodiment of the present disclosure.

FIG. 36 is a vertical cross-sectional view of the second exemplary structure after formation of the metallic source layer according to the second embodiment of the present disclosure.

FIG. 37 is a vertical cross-sectional view of the second exemplary structure after formation of a backside dielectric layer and backside bonding pads according to the second embodiment of the present disclosure.

FIGS. 38A-38D are sequential vertical cross-sectional views of a memory opening in an alternative embodiment of the second exemplary structure during formation of a memory opening fill structure according to the second embodiments of the present disclosure.

FIG. 39 is a vertical cross-sectional view of a region around the alternative configuration of the exemplary structure after replacement of the sacrificial material layers with electrically conductive layers according the second exemplary structure of the present disclosure.

FIG. 40 is a vertical cross-sectional view of a region around the alternative configuration of the exemplary structure after removal of a carrier substrate and a backside insulating layer according to the second exemplary structure of the present disclosure.

FIGS. 41A and 41B are sequential vertical cross-sectional views of a region around a memory opening fill structure in the alternative embodiment of the second exemplary structure during removal of the backside insulating layer and end portions of a memory film and formation of a metallic source layer according to the second embodiment of the present disclosure.

FIGS. 41C and 41D are vertical cross-sectional views of a region around a memory opening fill structure in additional alternative embodiments of the second exemplary structure after formation of a metallic source layer according to the second embodiment of the present disclosure.

### DETAILED DESCRIPTION

Embodiments of the present disclosure are directed to a three-dimensional memory device containing a top source contact to doped semiconductor source tips and methods for manufacturing the same. Embodiments of the disclosure can be employed to form various structures including a three-dimensional memory structure, non-limiting examples of which include three-dimensional NAND memory devices.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein. As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1×10⁻⁵ S/m to 1×10⁵ S/m. As used herein, a “semiconductor material” refers to a material having electrical conductivity in the range from 1×10⁻⁵ S/m to 1 S/m in the absence of electrical dopants therein, and is capable of producing a doped material having electrical conductivity in a range from 1 S/m to 1×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1×10⁵ S/m. As used herein, an “insulator material” or a “dielectric material” refers to a material having electrical conductivity less than 1×10⁻⁵ S/m. As used herein, a “heavily-doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1×10⁵ S/m. A “doped semiconductor material” may be a heavily-doped semiconductor material, or may be a semiconductor material that includes electrical dopants (i.e., p-type dopants and/or n-type dopants) at a concentration that provides electrical conductivity in the range from 1×10⁻⁵ S/m to 1×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

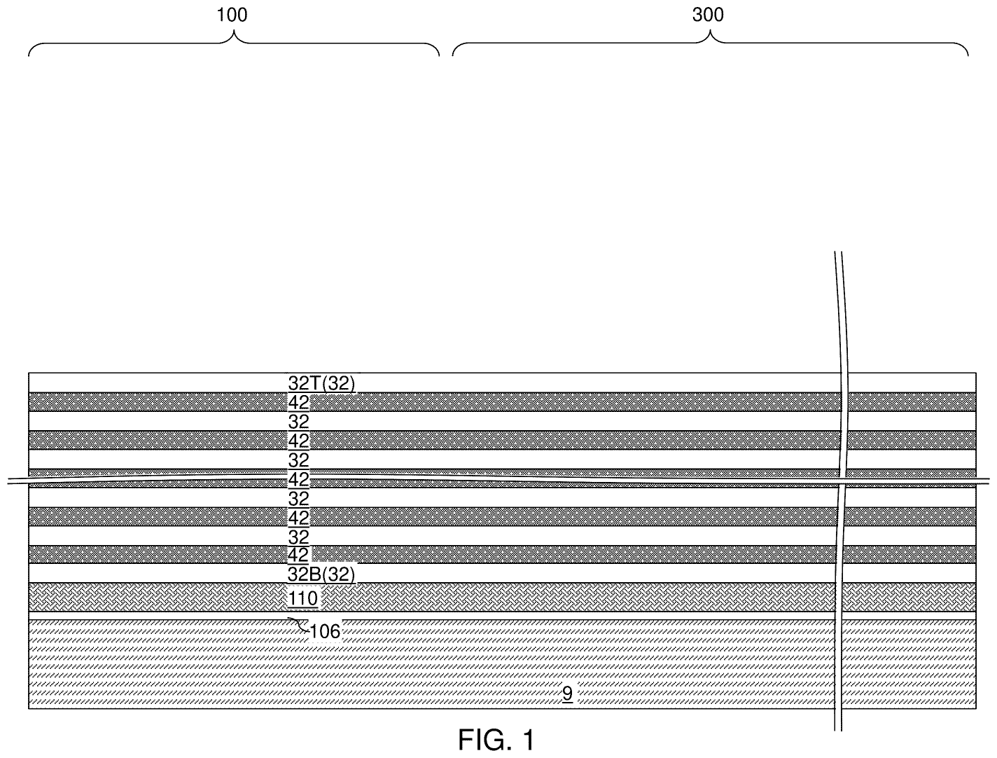

Referring to FIG. 1, a first exemplary structure according to the first embodiment of the present disclosure is illustrated. The first exemplary structure comprises a semiconductor substrate 9 which may comprise a first semiconductor material at least in a top portion thereof. For example, the semiconductor substrate 9 may comprise a silicon wafer. The first semiconductor material may comprise a doped well in the silicon wafer, an upper portion of a doped silicon wafer, or a doped silicon layer on a top surface of the silicon wafer. Thus, the first semiconductor material may be present only in an upper portion of the semiconductor substrate 9, or alternatively, the semiconductor substrate 9 may consist of the first semiconductor material (e.g., doped silicon). The thickness of the first semiconductor material may be in a range from 50 nm to the thickness of the semiconductor substrate 9. The thickness of the semiconductor substrate 9 may be in a range from 300 microns to 1 mm, although lesser and greater thicknesses may also be employed. A backside insulating layer 106 can be formed on a top surface of the semiconductor substrate 9. The backside insulating layer 106 comprises an insulating material, such as silicon oxide, and may have a thickness in a range from 5 nm to 100 nm, such as from 10 nm to 60 nm, although lesser and greater thicknesses may also be employed. A semiconductor material layer 110 comprising a second semiconductor material can be formed over the backside insulating layer 106.

According to an aspect of the present disclosure, the first semiconductor material and the second semiconductor material are selected such that the oxidation rate of the first semiconductor material is higher than the oxidation rate of the second semiconductor material during an oxidation process, such as a wet oxidation process, which may comprise a thermal oxidation process employing water vapor as an oxidation agent. For example, the ratio of the oxidation rate of the first semiconductor material to the oxidation rate of the second semiconductor material may be in a range from 1.2 to 4.0, such as from 1.4 to 3.0, and/or from 1.6 to 2.5, although lesser and greater ratios may also be employed. In an illustrative example, the first semiconductor material may comprise heavily doped p-type silicon (e.g., boron-doped silicon including boron atoms at an atomic concentration in a range from 5×10¹⁸/cm³ to 2×10²¹/cm³) and the second semiconductor material may comprise intrinsic polysilicon or lightly doped polysilicon (e.g., including electrical dopants, such as p-type dopants or n-type dopants at an atomic concentration less than 1×10¹⁷/cm³). Thus, the first semiconductor material has a higher doping concentration than the second semiconductor material in this example. In another illustrative example, the first semiconductor material may comprise an intrinsic or boron-doped silicon-germanium compound semiconductor material, and the second semiconductor material may comprise intrinsic polysilicon or polysilicon including electrical dopants (such as p-type dopants or n-type dopants) at an atomic concentration less than 1×10¹⁷/cm³.

An alternating stack of first material layers and second material layers can be formed over the semiconductor substrate 9. The first material layers may be insulating layers, and the second material layers may be spacer material layers. In one embodiment, the spacer material layers may comprise sacrificial material layers 42. In this case, an alternating stack (32, 42) of insulating layers 32 and sacrificial material layers 42 can be formed over the semiconductor substrate 9. The insulating layers 32 comprise an insulating material such as undoped silicate glass or a doped silicate glass, and the sacrificial material layers 42 comprise a sacrificial material such as silicon nitride or a silicon-germanium alloy. In one embodiment, the insulating layers 32 (i.e., the first material layers) may comprise silicon oxide layers, and the sacrificial material layers 42 (i.e., the second material layers) may comprise silicon nitride layers.

The alternating stack (32, 42) may comprise multiple repetitions of a unit layer stack including an insulating layer 32 and a sacrificial material layer 42. The total number of repetitions of the unit layer stack within the alternating stack (32, 42) may be, for example, in a range from 8 to 1,024, such as from 32 to 256, although lesser and greater number of repetitions may also be employed. The topmost one of the insulating layers 32 is hereafter referred to as a topmost insulating layer 32T. The bottommost one of the insulating layers 32 (i.e., an insulating layer 32 that is most proximal to the semiconductor substrate 9) is herein referred to as a bottommost insulating layer 32B.

Each of the insulating layers 32 other than the topmost insulating layer 32T may have a thickness in a range from 20 nm to 100 nm, such as from 30 nm to 60 nm, although lesser and greater thicknesses may also be employed. Each of the sacrificial material layers 42 may have a thickness in a range from 20 nm to 100 nm, such as from 30 nm to 60 nm, although lesser and greater thicknesses may also be employed. In one embodiment, the topmost insulating layer 32T may have a thickness of about one half of the thickness of other insulating layers 32.

The first exemplary structure comprises a memory array region 100 in which a three-dimensional array of memory elements is to be subsequently formed, and a contact region 300 in which layer contact via structures contacting word lines are to be subsequently formed.

While an embodiment is described in which the spacer material layers are formed as sacrificial material layers 42, the spacer material layers may be formed as electrically conductive layers in an alternative embodiment. Generally, spacer material layers of the present disclosure may be formed as, or may be subsequently replaced at least partly with, electrically conductive layers.

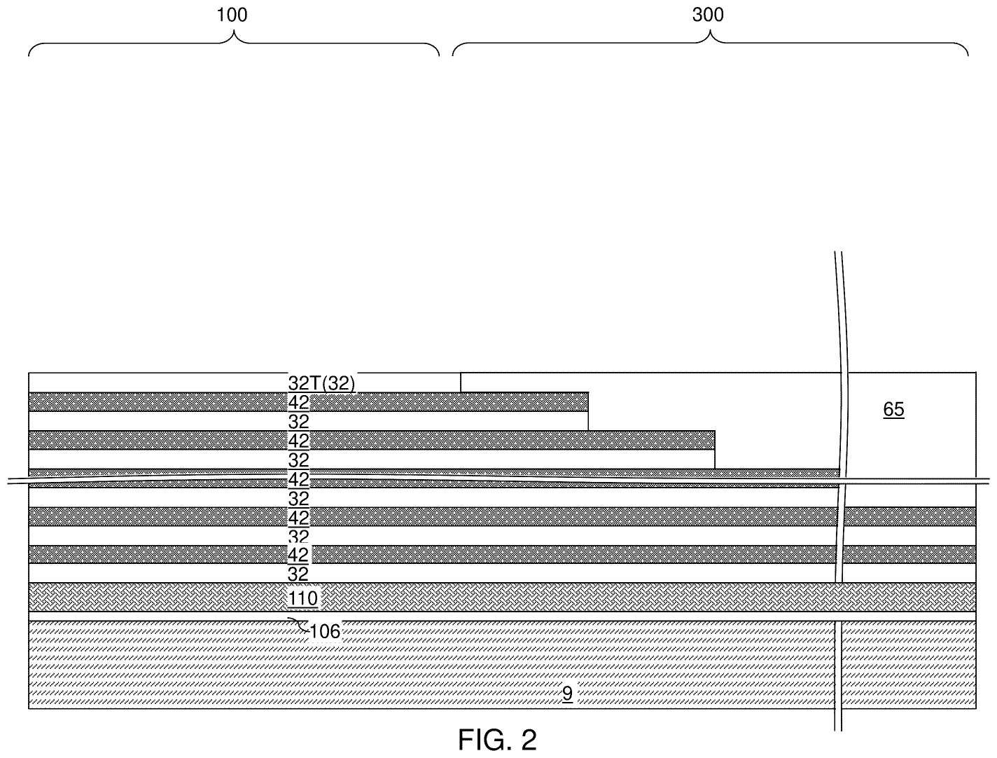

Referring to FIG. 2, optional stepped surfaces are formed in the contact region 300. As used herein, “stepped surfaces” refer to a set of surfaces that include at least two horizontal surfaces and at least two vertical surfaces such that each horizontal surface is adjoined to a first vertical surface that extends upward from a edge of the horizontal surface, and is adjoined to a second vertical surface that extends downward from a second edge of the horizontal surface. A stepped cavity is formed within the volume from which portions of the alternating stack (32, 42) are removed through formation of the stepped surfaces. A “stepped cavity” refers to a cavity having stepped surfaces.

The stepped cavity can have various stepped surfaces such that the horizontal cross-sectional shape of the stepped cavity changes in steps as a function of the vertical distance from the top surface of the semiconductor substrate 9. In one embodiment, the stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each sacrificial material layer 42 other than a topmost sacrificial material layer 42 within the alternating stack (32, 42) laterally extends farther than any overlying sacrificial material layer 42 within the alternating stack (32, 42) in the terrace region. The stepped surfaces of the alternating stack (32, 42) continuously extend from a bottommost layer within the alternating stack (32, 42) (such as the bottommost insulating layer 32B) to a topmost layer within the alternating stack (32, 42) (such as the topmost insulating layer 32T).

A stepped dielectric material portion 65 (i.e., an insulating fill material portion) can be formed in the stepped cavity by deposition of a dielectric material therein. For example, a dielectric material such as silicon oxide can be deposited in the stepped cavity. Excess portions of the deposited dielectric material can be removed from above the top surface of the topmost insulating layer 32T, for example, by chemical mechanical planarization (CMP). The remaining portion of the deposited dielectric material filling the stepped cavity constitutes the stepped dielectric material portion 65. As used herein, a “stepped” element refers to an element that has stepped surfaces and a horizontal cross-sectional area that increases or decreases stepwise as a function of a vertical distance from a top surface of a substrate on which the element is present. If silicon oxide is employed for the stepped dielectric material portion 65, the silicon oxide of the stepped dielectric material portion 65 may, or may not, be doped with dopants such as B, P, and/or F.

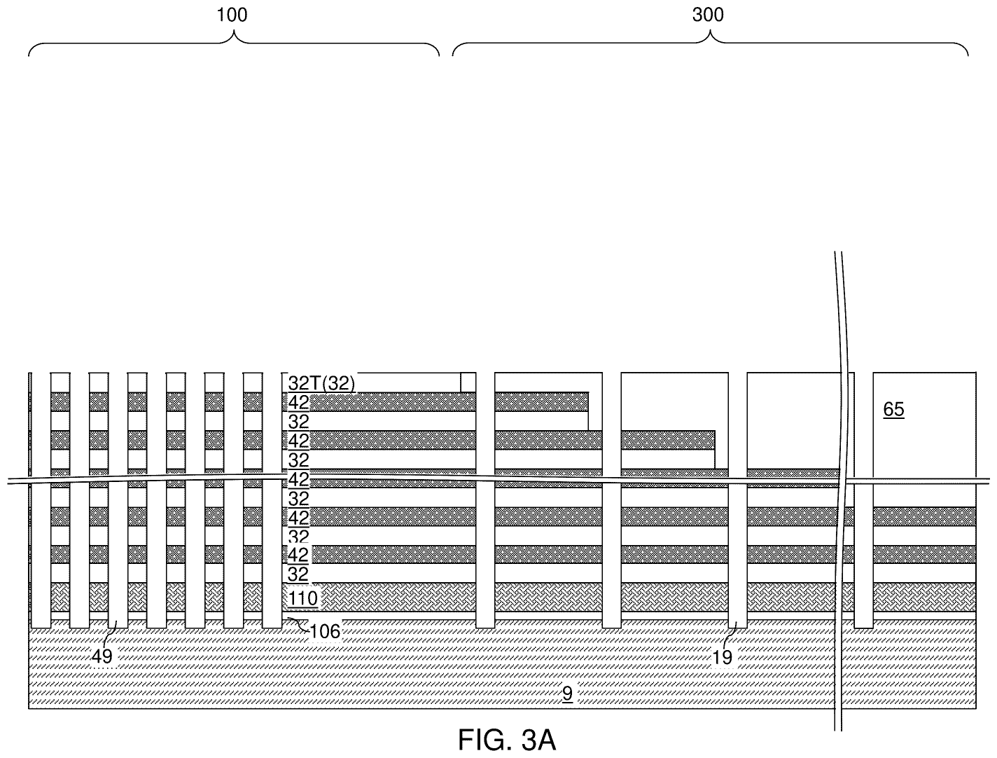

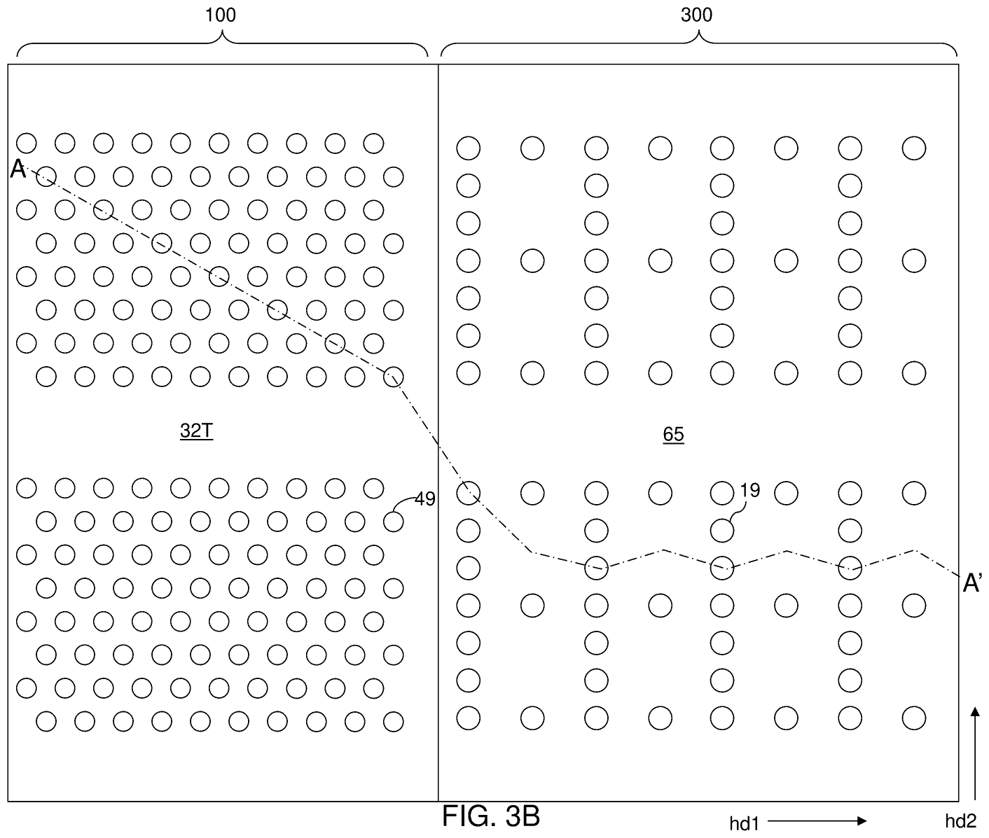

Referring to FIGS. 3A and 3B, an etch mask layer (such as a photoresist layer) can be formed over the alternating stack (32, 42), and can be lithographically patterned to form openings in the memory array region 100 and in the contact region 300. An anisotropic etch process can be performed to transfer the pattern of the openings in the etch mask layer through the stepped dielectric material portion 65, the alternating stack (32, 42), the semiconductor material layer 110, and the backside insulating layer 106, and into an upper portion of the semiconductor substrate 9. Memory openings 49 are formed through the alternating stack (32, 42) in the memory array region 100. Support openings 19 can optionally be formed through the stepped dielectric material portion 65 and the alternating stack (32, 42) in the contact region 300.

Each of the memory openings 49 and the support openings 19 can vertically extend into the semiconductor substrate 9. In one embodiment, bottom surfaces of the memory openings 49 and the support openings 19 may be formed below the top surface of the semiconductor substrate 9. The vertical distance between the bottom surfaces of the memory openings 49 and the support openings 19 and the horizontal plane including the top surface of the semiconductor substrate 9 may be in a range from 30 nm to 300 nm, such as from 60 nm to 150 nm. The entirety of the physically exposed surfaces of the semiconductor substrate 9 that are exposed to the memory openings 49 and the support openings 19 may be surfaces of the first semiconductor material. The memory openings 49 may have a diameter in a range from 60 nm to 400 nm, such as from 120 nm to 300 nm, although lesser and greater diameters may be employed. The support openings 19 may have a diameter in a range from 60 nm to 400 nm, such as from 120 nm to 300 nm, although lesser and greater diameters may be employed.

Each cluster of memory openings 49 (which corresponds to an area of a memory block) may comprise a plurality of rows of memory openings 49. Each row of memory openings 49 may comprise a plurality of memory openings 49 that are arranged along the first horizontal direction hd1 (which may be a word line direction) with a uniform pitch. The rows of memory openings 49 may be laterally spaced from each other along the second horizontal direction hd2 (which may be a bit line direction), which may be perpendicular to the first horizontal direction hd1. In one embodiment, each cluster of memory openings 49 may be formed as a two-dimensional periodic array of memory openings 49.

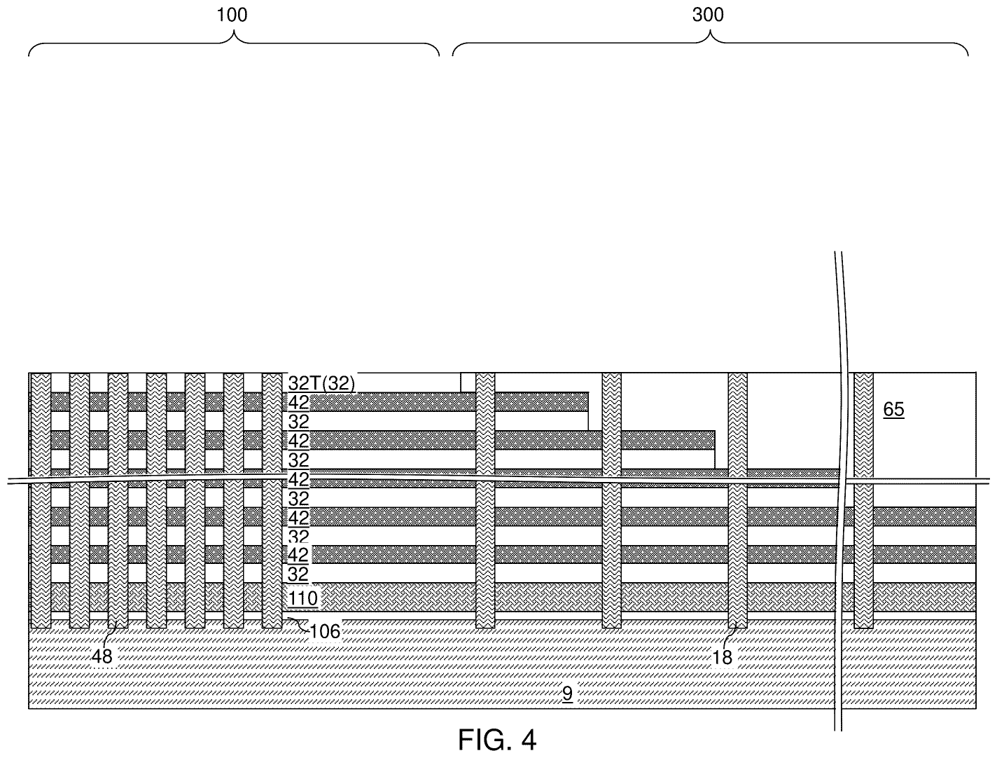

Referring to FIG. 4, an optional sacrificial liner layer (such as a thin silicon oxide layer) and a sacrificial fill material can be deposited in the memory openings 49 and in the support openings 19. The sacrificial fill material may comprise a carbon-based material (such as amorphous carbon or diamond-like carbon), a semiconductor material such as amorphous silicon or silicon-germanium), a polymer material, or a dielectric material (such as organosilicate glass or borosilicate glass). Excess portions of the sacrificial fill material may be removed from above the horizontal plane including the top surface of the topmost insulating layer 32T. Each remaining portion of the sacrificial fill material that fills a memory opening 49 constitutes a sacrificial memory opening fill structure 48. Each remaining portion of the sacrificial fill material that fills a support opening 19 constitutes a sacrificial support opening fill structure 18.

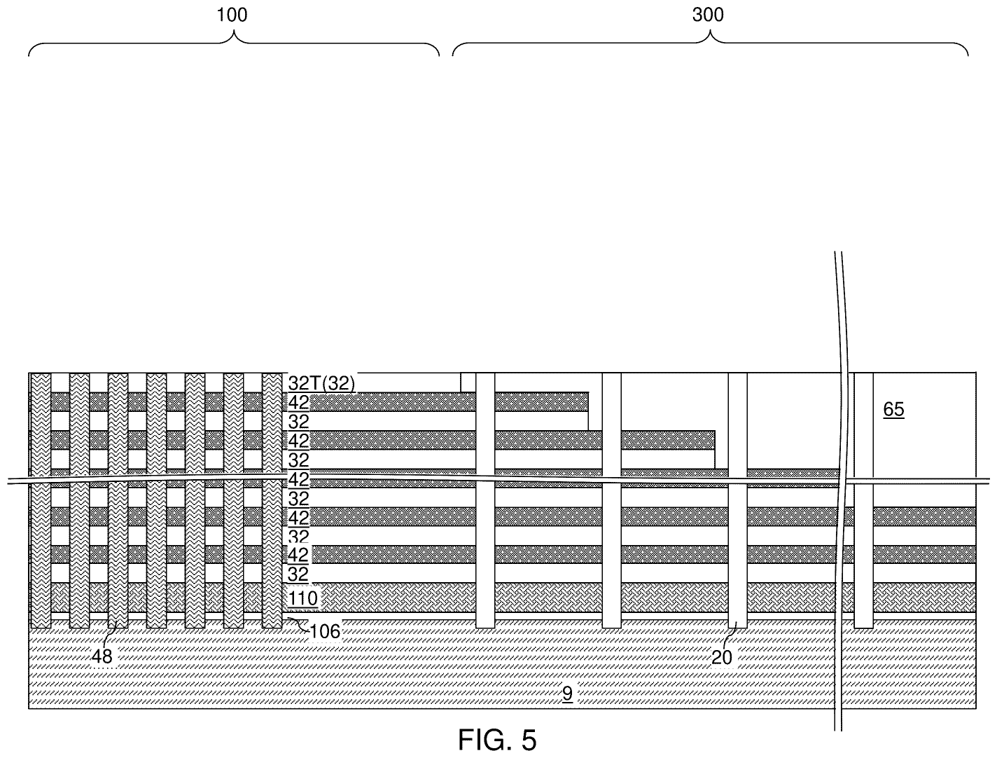

Referring to FIG. 5, a photoresist layer (not shown) can be applied over the first exemplary structure, and can be lithographically patterned to cover the sacrificial memory opening fill structures 48 in the memory array region 100 without covering the sacrificial support opening fill structures 18 in the contact region 300. The sacrificial support opening fill structures 18 are subsequently removed selective to the materials of the insulating layers 32, the sacrificial material layers 42, the semiconductor material layer 110, the backside insulating layer 106, and the semiconductor substrate 9 by ashing or selective etching. Voids are formed in the volumes of the support openings 19 from which the sacrificial support opening fill structures 18 are removed.

A dielectric fill material, such as silicon oxide, can be deposited in the support openings 19 by a conformal deposition process. Excess portions of the dielectric fill material can be removed from above the top surface of the topmost insulating layer 32T, for example, by a recess etch process. Each portion of the dielectric fill material that fills a respective support opening 19 constitutes a support pillar structure 20, which can be employed to provide structural support to the insulating layers 32 and the stepped dielectric material portion 65 during replacement of the sacrificial material layers 42 with electrically conductive layers. Alternatively, the support openings 19 can be formed at a later step at the same time as the memory openings, and the support pillar structures 20 can be formed in the support openings 19 at the same time as the memory opening fill structures are formed in the memory openings, as will be described below.

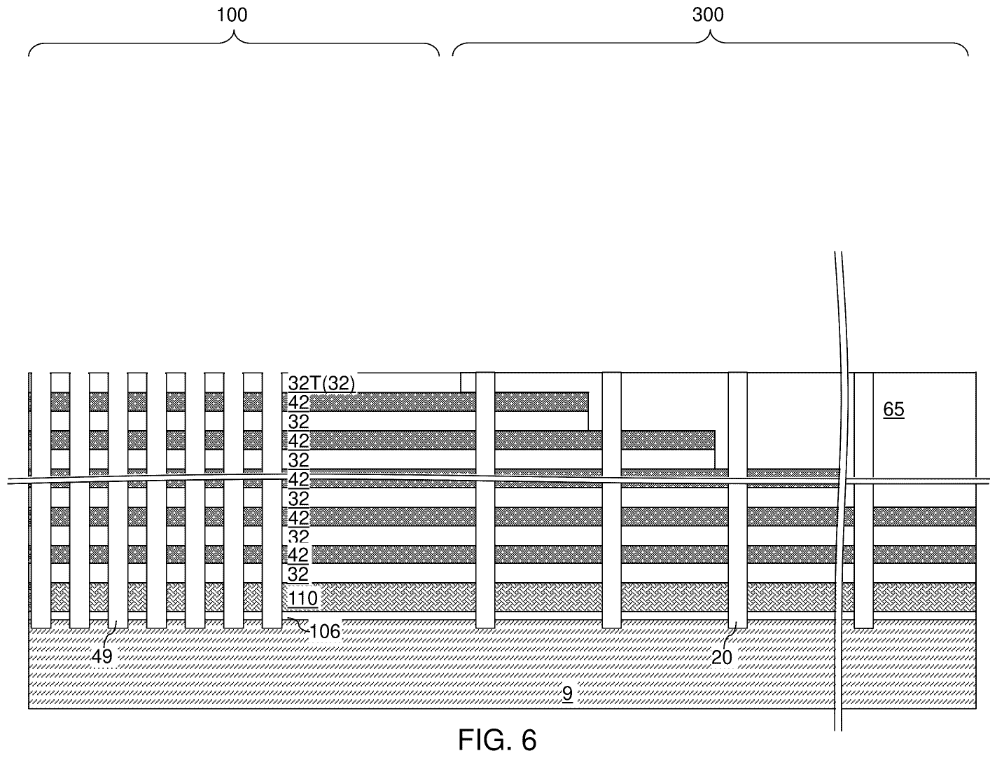

Referring to FIG. 6, sacrificial memory opening fill structures 48 are subsequently removed selective to the materials of the insulating layers 32, the sacrificial material layers 42, the semiconductor material layer 110, the backside insulating layer 106, and the semiconductor substrate 9. Voids are formed in the volumes of the memory openings 49 from which the sacrificial memory opening fill structures 48 are removed.

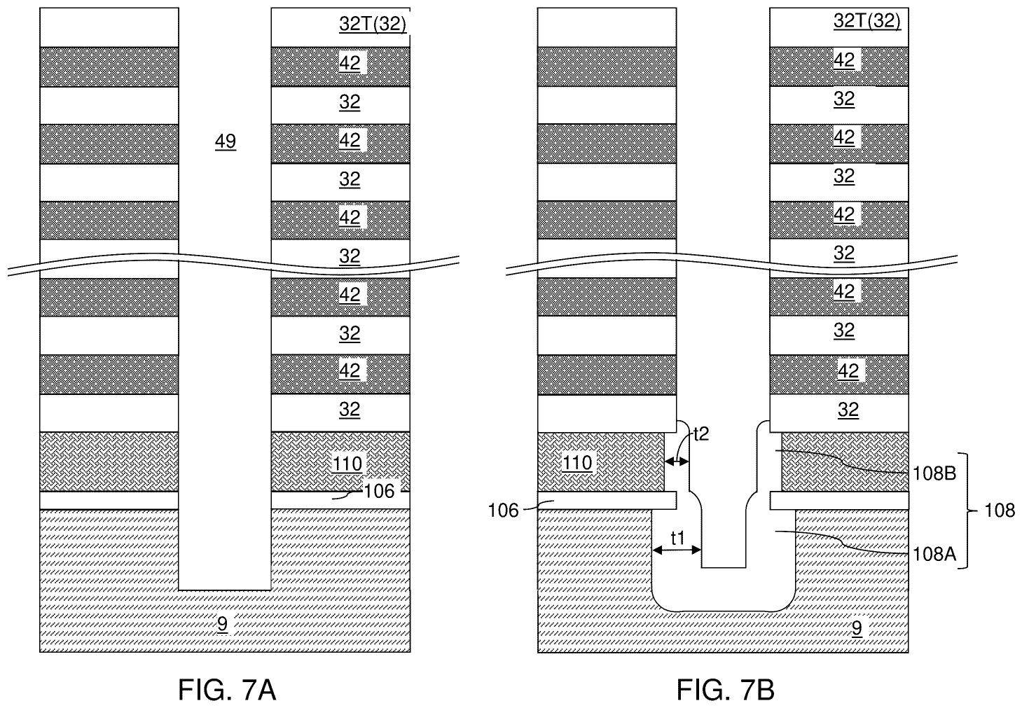

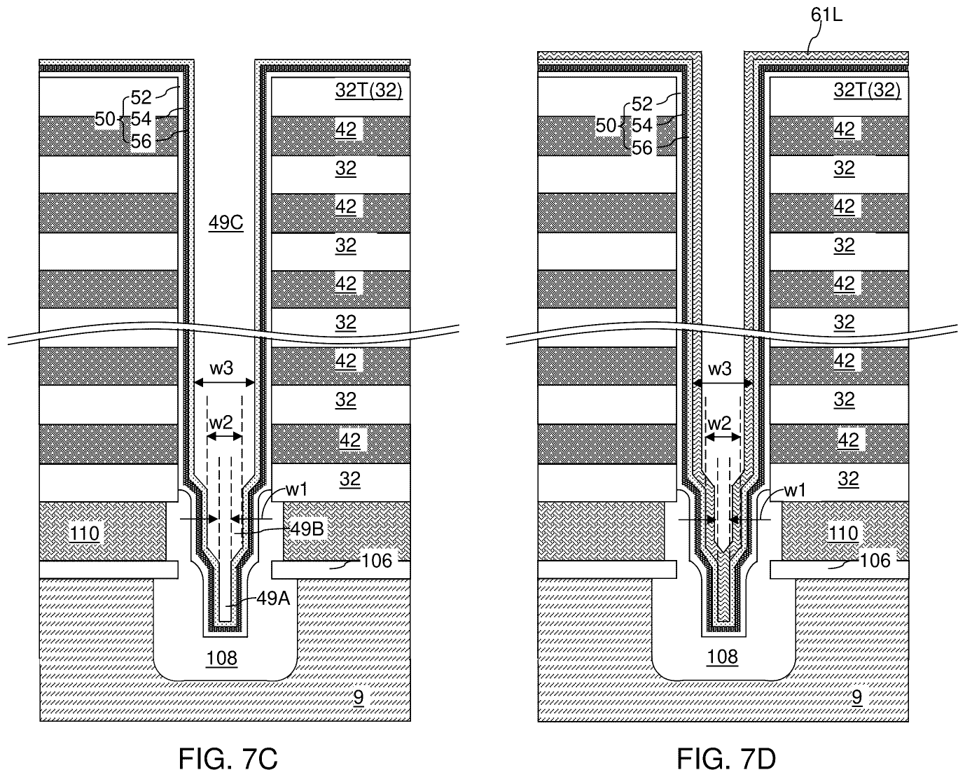

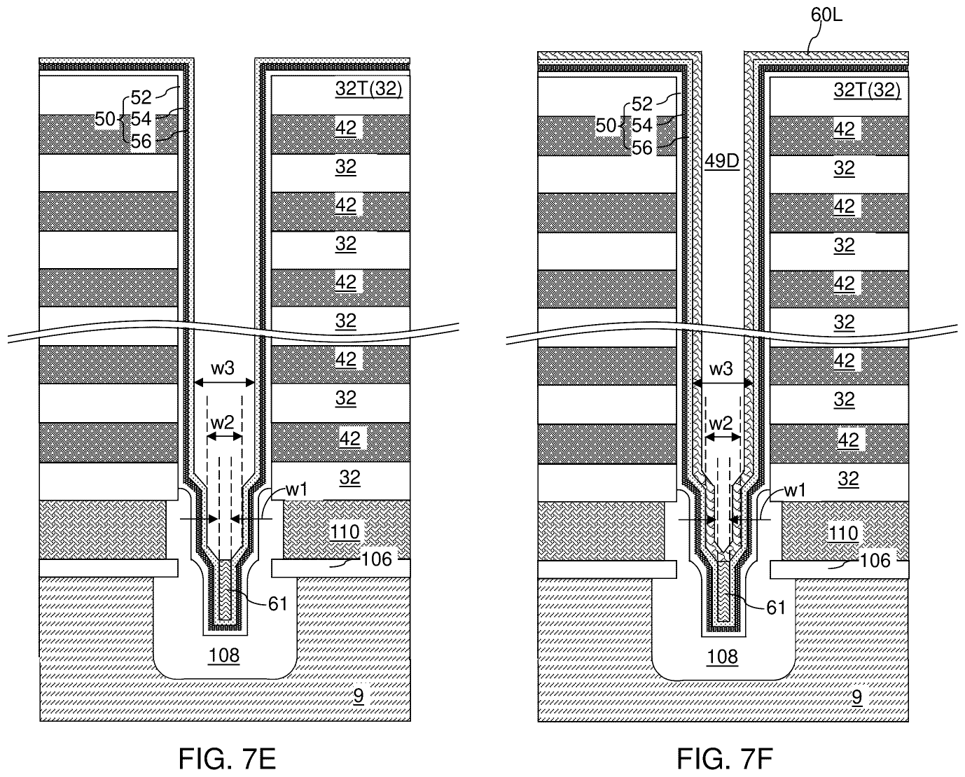

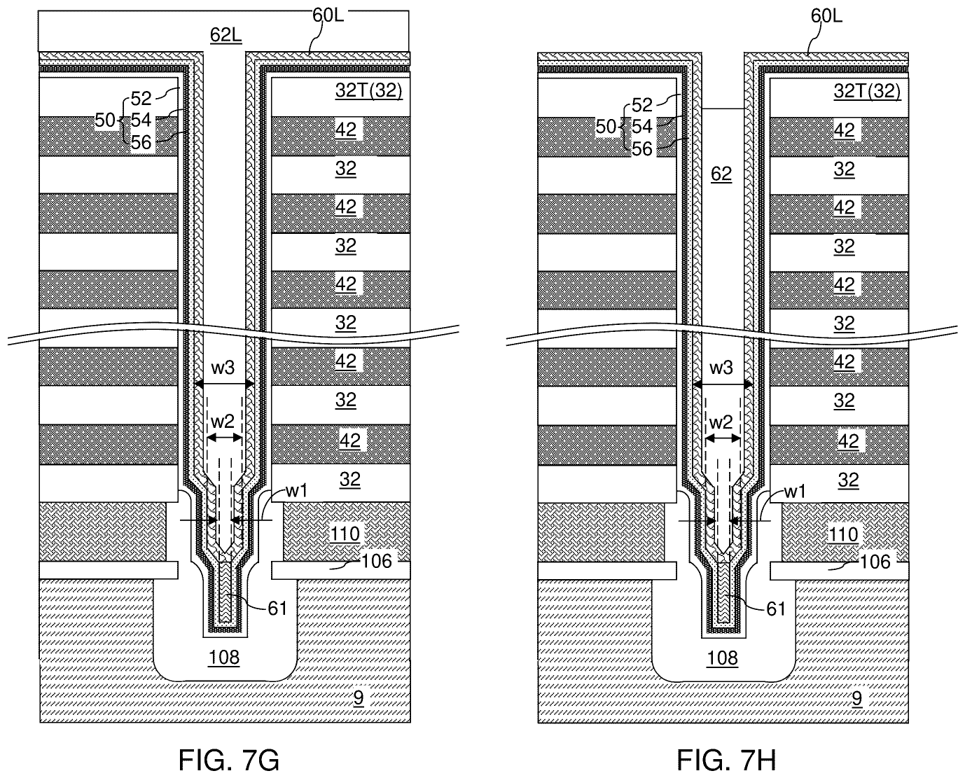

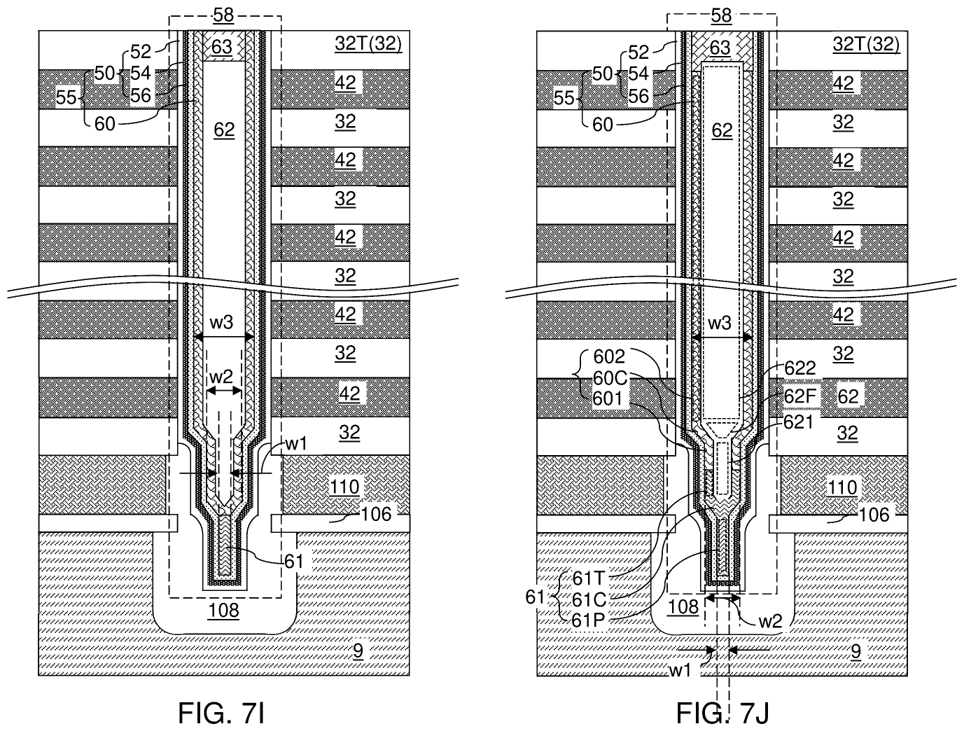

FIGS. 7A-7J are sequential vertical cross-sectional views of a memory opening 49 in the first exemplary structure during formation of a memory opening fill structure 58 according to the first embodiments of the present disclosure.

Referring to FIG. 7A, a memory opening 49 is illustrated after the processing steps of FIG. 6.

Referring to FIG. 7B, surface portions of the semiconductor material layer 110 and the semiconductor substrate 9 can be oxidized around the bottom portion of each memory opening 49. Oxidized surface portions of the semiconductor material layer 110 and the semiconductor substrate 9 merge to form a semiconductor oxide spacer structure 108 around the bottom portion of each memory opening 49. Each semiconductor oxide spacer structure 108 includes a first cylindrical portion 108A formed by oxidation of a surface portion of the semiconductor substrate 9, and having a first thickness t1. Further, each semiconductor oxide spacer structure 108 includes a second cylindrical portion 108B formed by oxidation of a surface portion of the semiconductor material layer 110, having a second thickness t2, and formed at the level of the semiconductor material layer 110.

In one embodiment, the first thickness t1 is greater than the second thickness t2. The ratio of the first thickness t1 to the second thickness t2 may be in a range from 1.2 to 4, such as from 1.4 to 3, and/or from 1.5 to 2.5, although lesser and greater ratios may also be employed. The first thickness t1 may be in a range from 20 nm to 200 nm, such as from 40 nm to 100 nm, although lesser and greater first thicknesses may be employed.

Referring to FIG. 7C, a layer stack including a memory material layer 54 can be conformally deposited. In an illustrative example, the layer stack may comprise an optional blocking dielectric layer 52, the memory material layer 54, and an optional dielectric liner 56. The layer stack is herein referred to as a memory film 50. The blocking dielectric layer 52 may include a single dielectric material layer or a stack of a plurality of dielectric material layers. In one embodiment, the blocking dielectric layer may include a dielectric metal oxide layer consisting essentially of a dielectric metal oxide, and/or may include a silicon oxide layer. The memory material layer 54 includes a memory material, i.e., a material that can store data bits therein. The memory material layer 54 may comprise a charge storage material (such as silicon nitride), a ferroelectric material, a phase change memory material, or any other memory material that can store data bits by inducing a change in the electrical resistivity, ferroelectric polarization, or any other measurable physical property. The optional dielectric liner 56, if present, comprises a dielectric material. In case the memory material layer 54 comprises a charge storage material, the optional dielectric liner 56 may comprise a tunneling dielectric layer. In one embodiment, the tunneling dielectric layer may comprise a silicon oxide layer or an ONO stack, i.e., a layer stack including a first silicon oxide layer, a silicon nitride layer, and a second silicon oxide layer.

A cavity located within the unfilled volume of each memory opening 49 may comprise multiple cavity portions having different widths. For example, the cavity may comprise a first cavity portion 49A having a first width w1, a second cavity portion 49B overlying the first cavity portion 49A and having a second width w2 that is greater than the first width w1, and a third cavity portion 49C overlying the second cavity portion 49B and having a third width w3 that is greater than the second width w2. The first cavity portion 49A may be laterally surrounded by the semiconductor substrate 9, the second cavity portion 49B may be laterally surrounded by the semiconductor material layer 110, and the third cavity portion 49C may be laterally surrounded by the alternating stack (32, 42). In one embodiment, the first width w1 may be in a range from 15 nm to 100 nm, such as from 20 nm to 60 nm, although lesser and greater first widths w1 may also be employed.

Referring to FIG. 7D, a heavily-doped semiconductor material layer 61L is conformally deposited over the memory film 50. In other words, the heavily-doped semiconductor material layer 61L comprises a doped semiconductor material having an electrical conductivity greater than 1×10⁵ S/m. In one embodiment, vertical semiconductor channels to be subsequently formed may have a first conductivity type, and the heavily-doped semiconductor material layer 61L has a doping of a second conductivity type that is the opposite of the first conductivity type. For example, if the first conductivity type is p-type, the second conductivity type is n-type. The thickness of the heavily-doped semiconductor material layer 61L is greater than one half of the first width w1, and is less than one half of the second width w2. For example, the thickness of the heavily-doped semiconductor material layer 61L may be in a range from 8 nm to 80 nm, such as from 16 nm to 50 nm, although lesser and greater thicknesses may also be employed. In one embodiment, the heavily-doped semiconductor material layer 61L may comprise heavily doped n-doped amorphous silicon or n-doped polysilicon including n-type electrical dopants at an atomic concentration in a range from 5×10¹⁸/cm³ to 2×10²¹/cm³, although lesser and greater atomic concentrations may also be employed.

Referring to FIG. 7E, an isotropic recess etch process may be performed, which etches the semiconductor material of the heavily-doped semiconductor material layer 61L selective to the material of the dielectric liner 56 (or selective to the memory material layer 54 in case the dielectric liner 56 is omitted). For example, a wet etch process employing a dilute tetramethylammonium hydroxide (TMAH), such as 1% TMAH, may be performed to isotropically recess the heavily-doped semiconductor material layer 61L. The duration of the isotropic etch process can be selected such that the heavily-doped semiconductor material layer 61L is removed from within the second cavity portion 49B having the second width w2 and from within the third cavity portion 49C having the third width w3, and an inner sidewall of the memory film 50 is exposed around the second cavity portion 49B and the third cavity portion 49C. A remaining portion of the heavily-doped semiconductor material layer 61L that fills a first cavity portion 49A comprises a semiconductor source structure 61.

The semiconductor source structure 61 comprises a cylindrical heavily-doped semiconductor material portion having a doping of the second conductivity type. The semiconductor source structure 61 may have a shape of a cylindrical pillar having a diameter of the first width w1. Generally, the semiconductor source structure 61 is formed after formation of the memory film 50 within a first void (i.e., the first cavity portion 49A) of the memory opening 49 that is laterally surrounded by a first cylindrical portion of a memory material layer 54 that is located below a horizontal plane including the top surface of the semiconductor substrate 9. In one embodiment, a top surface of the semiconductor source structure 61 is formed at or below a horizontal plane including a bottom surface of the semiconductor material layer 110.

Referring to FIG. 7F, a semiconductor channel material layer 60L can be deposited over the layer stack (52, 54, 56) by performing a conformal deposition process. The semiconductor channel material layer 60L may be intrinsic, or may include electrical dopants of the first conductivity type (e.g., p-type dopants, such as boron in an amorphous silicon or polysilicon channel material layer). If the semiconductor channel material layer 60L is doped, the atomic concentration of dopants of the first conductivity type within the semiconductor channel material layer 60L may be less than 3×10¹⁶/cm³, such as 1×10¹²/cm³ to 2×10¹⁶/cm³. The thickness of the semiconductor channel material layer 60L may be in a range from 5 nm to 50 nm, such as from 10 nm to 30 nm, although lesser and greater thicknesses may also be employed. In one embodiment, a cavity 49D that is not filled within the semiconductor channel material layer 60L may be present at the level of the semiconductor material layer 110.

Referring to FIG. 7G, a dielectric core layer 62L comprising a dielectric fill material, such as silicon oxide, can be deposited in remaining volumes (i.e., in the cavity 49D) of the memory openings 49. The dielectric core layer 62L can be deposited employing a conformal deposition process, such as a chemical vapor deposition process.

Referring to FIG. 7H, the dielectric core layer 62L can be vertically recessed such that each remaining portion of the dielectric core layer has a top surface at, or about, the horizontal plane including the bottom surface of the topmost insulating layers 32. Each remaining portion of the dielectric core layer constitutes a dielectric core 62.

Referring to FIG. 7I, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5×10¹⁸/cm³ to 2×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel material layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel material layer 60L (which has a doping of the first conductivity type) constitutes a vertical semiconductor channel 60.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Generally, a memory film 50, a semiconductor source structure 61, a vertical semiconductor channel 60, a dielectric core 62, and a drain region 63 can be formed in a remaining volume of the memory opening 49 after formation of a semiconductor oxide spacer structure 108 to form a memory opening fill structure 58. Each combination a semiconductor oxide spacer structure 108, a memory stack structure 55, a semiconductor source structure 61, a dielectric core 62, and a drain region 63 within a memory opening 49 constitutes a memory opening fill structure 58. Each memory opening fill structure 58 comprises a respective vertical stack of memory elements, which may comprise portions of the memory material layer 54 located at levels of the sacrificial material layers 42, or generally speaking, at levels of spacer material layers that may be formed as, or may be subsequently replaced at least partly with, electrically conductive layers.

In the alternative embodiment, the support pillar structures 20 may be formed in the support openings 19 at the same time as the memory opening fill structures 58 are formed in the memory openings 49. In this case, the support pillar structures 20 comprise the same materials as the memory opening fill structures 58.

Referring to FIG. 7J, an anneal process can be performed to activate electrical dopants in the semiconductor source structure 61, the drain region 63, and the vertical semiconductor channel 60, and to crystallize amorphous semiconductor material into polycrystalline semiconductor material. In this case, any amorphous semiconductor material (e.g., amorphous silicon) in the vertical semiconductor channel 60, the semiconductor source structure 61 and/or the semiconductor material layer 110 is converted into a polycrystalline semiconductor material (e.g., polysilicon), during the crystallization anneal process. Alternatively, if the above layers comprise polycrystalline semiconductor material, then the grain size in the polycrystalline material is increased during the anneal process (i.e., during the recrystallization anneal). In one embodiment, grains within the vertical semiconductor channel 60 may extends predominantly along a respective local direction that is perpendicular to a respective proximal portion of an inner sidewall of the vertical semiconductor channel 60 and perpendicular to a respective proximal portion of an outer sidewall of the vertical semiconductor channel 60. As used herein, the grains extend predominantly along a specific direction if more than 50% of the drains extend along the specific direction.

Some of the dopants of the second conductivity type in the semiconductor source structure 61 diffuse upward into a lower portion of the vertical semiconductor channel 60, and the lower portion of the vertical semiconductor channel 60 can be converted into a doped semiconductor material portion (e.g., 61C, 61T) having a net doping of the second conductivity type. In this case, the newly-formed semiconductor material portion (e.g., 61C, 61T) having a net doping of the second conductivity type is incorporated into the semiconductor source structure 61.

In summary, each memory opening fill structure 58 can be located in a respective memory opening 49, and comprises a vertical semiconductor channel 60 that vertically extends through each sacrificial material layer 42 in the alternating stack (32, 42), a semiconductor source structure 61 adjoined to a first end of the vertical semiconductor channel 60 and laterally surrounded by the semiconductor material layer 110, and a drain region 63 contacting a second end of the vertical semiconductor channel 60. In one embodiment, the semiconductor source structure 61 comprises a pillar semiconductor source portion 61P having a first width w1 along a horizontal direction and a tubular semiconductor source portion 61T having an inner cavity and an outer cylindrical surface which has a second width w2 along the horizontal direction, the second width w2 being greater than the first width w1. In one embodiment, the semiconductor source structure 61 may also comprise a conical semiconductor source portion 61C that connects the pillar semiconductor source portion 61P and the tubular semiconductor source portion 61T and having a shape of a truncated hollow cone. The conical semiconductor source portion 61C has a variable lateral dimension that increases with a vertical distance from the horizontal plane including the bottom surface of the semiconductor material layer 110.

In one embodiment, the vertical semiconductor channel 60 comprises: a first tubular channel portion 601 having a first cylindrical outer sidewall that has the second width w2 along the horizontal direction; and a second tubular channel portion 602 having a second cylindrical outer sidewall that has a third width w3 along the horizontal direction, the third width w3 being greater than the second width w2. In one embodiment, the vertical semiconductor channel 60 also comprises a connecting tapered tubular channel portion 60C that connects the first tubular channel portion 601 and the second tubular channel portion 602 and has a variable lateral dimension that increases with a vertical distance from a horizontal plane including a bottom surface of the semiconductor material layer 110. In one embodiment, a bottom periphery of the first cylindrical outer sidewall of the first tubular channel portion 601 coincides with a top periphery of the outer cylindrical surface of the tubular semiconductor source portion 61T.

In one embodiment, the memory opening fill structure 58 also comprises a dielectric core 62 that is laterally surrounded by the vertical semiconductor channel 60. In one embodiment, the dielectric core 62 comprises: a first cylindrical dielectric core portion 621 that is laterally surrounded by the first tubular channel portion 601 and the tubular semiconductor source portion 61T and has a first lateral dimension; and a second cylindrical dielectric core portion 622 that is laterally surrounded by the second tubular channel portion 602 and has a second lateral dimension that is greater than the first lateral dimension. In one embodiment, the dielectric core 62 also comprises a frustum dielectric core portion 62F that connects the first cylindrical dielectric core portion 621 and the second cylindrical dielectric core portion 622.

In one embodiment, dopant ions (e.g., boron, phosphorus and/or arsenic) are not implanted into the dielectric cores 62. In this case, the semiconductor source structure 61 comprises atoms of an electrical dopant therein; and the dielectric core 62 has a homogeneous material composition throughout and is free of the electrical dopant. The memory opening fill structure 58 also comprises a memory film 50 that laterally surrounds the vertical semiconductor channel 60 and the semiconductor source structure 61.

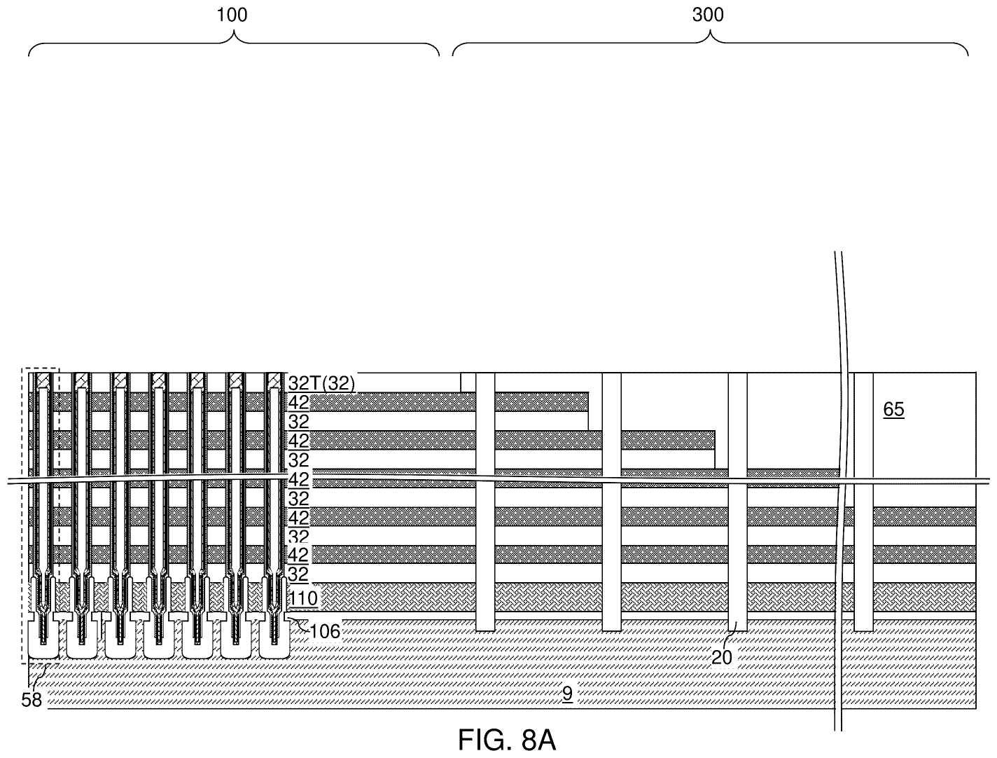

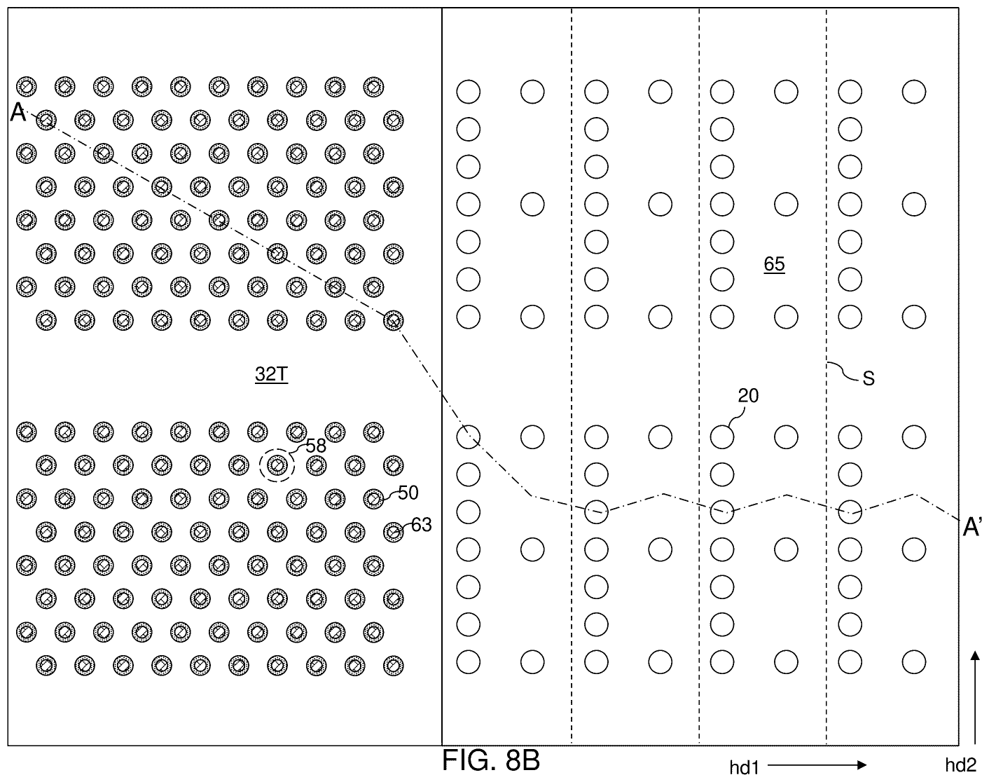

Referring to FIGS. 8A and 8B, the first exemplary structure is illustrated after formation of memory opening fill structures 58 within the memory openings 49. The memory opening fill structures 58 are located in the memory openings 49. Each of the memory opening fill structures 58 comprises a respective memory film 50 and a respective vertical semiconductor channel 60.

The memory opening fill structures 58 are arranged in rows laterally extending along a first horizontal direction hd1, and the rows are laterally spaced apart from each other along a second horizontal direction hd2 that is perpendicular to the first horizontal direction hd1. Each of the memory opening fill structures 58 comprises a vertical stack of memory elements (which may comprise portions of a memory film 50 located at levels of the sacrificial material layers 42), and a respective drain region 63.

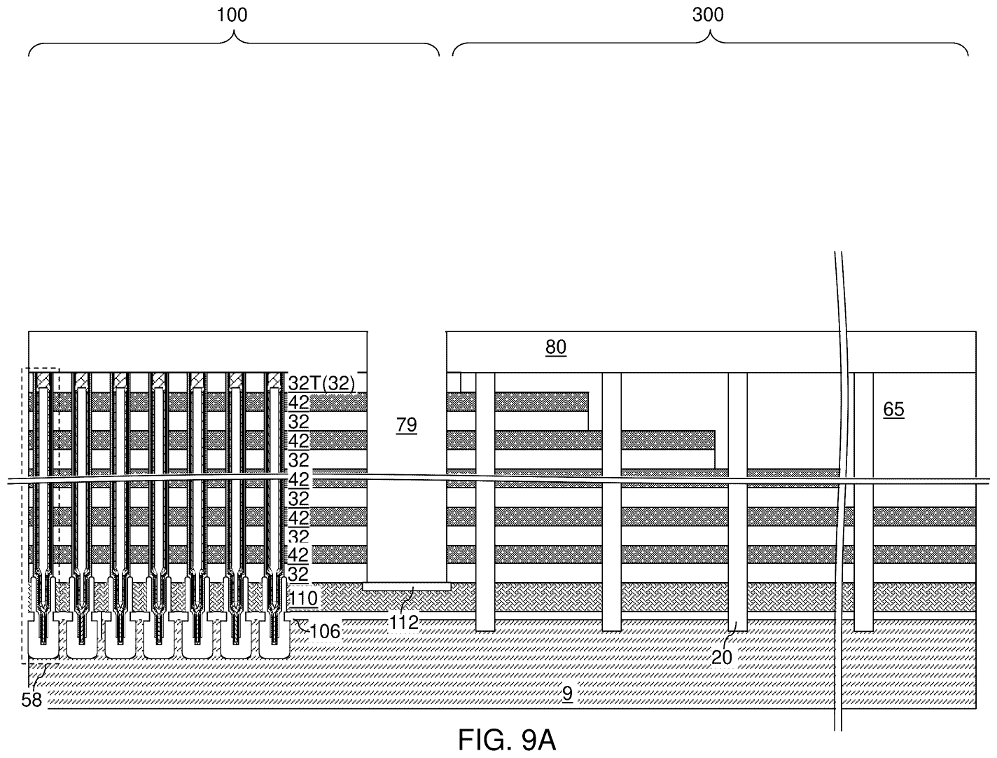

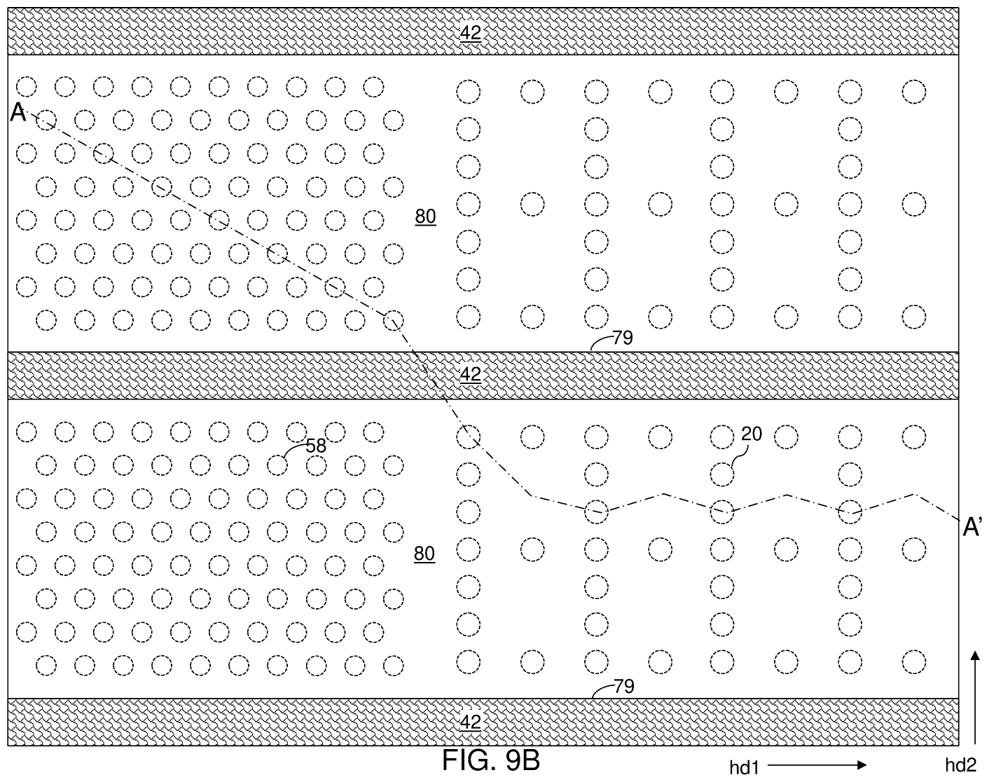

Referring to FIGS. 9A and 9B, a dielectric material such as undoped silicate glass or a doped silicate glass can be deposited over the alternating stack (32, 42) to form a contact-level dielectric layer 80. The thickness of the contact-level dielectric layer 80 may be in a range from 100 nm to 600 nm, such as from 200 nm to 400 nm, although lesser and greater thicknesses may also be employed.

A photoresist layer (not shown) can be applied over the contact-level dielectric layer 80, and can be lithographically patterned to form elongated openings that laterally extend along the first horizontal direction hd1 between neighboring clusters of memory opening fill structures 58. An anisotropic etch process can be performed to transfer the pattern of the openings in the photoresist layer through the contact-level dielectric layer 80, the alternating stack (32, 42), and the stepped dielectric material portion 65. Lateral isolation trenches 79 laterally extending along the first horizontal direction hd1 can be formed through the alternating stack (32, 42), the stepped dielectric material portion 65, and the contact-level dielectric layer 80. Each of the lateral isolation trenches 79 may comprise a respective pair of lengthwise sidewalls that are parallel to the first horizontal direction hd1 and vertically extend from the semiconductor material layer 110 to the top surface of the contact-level dielectric layer 80. A top surface of semiconductor material layer 110 can be physically exposed underneath each lateral isolation trench 79. The lateral isolation trenches 79 isolate adjacent memory blocks from each other along the second horizontal direction hd2. The photoresist layer can be subsequently removed, for example, by ashing. An optional surface oxidation process can be performed to convert physically exposed surface portions of the semiconductor material layer 110 into optional semiconductor oxide barrier layers 112. The semiconductor oxide barrier layers 112 may be employed to protect the semiconductor material layer 110 during subsequent processing steps that are employed to remove the sacrificial material layers 42 with electrically conductive layers.

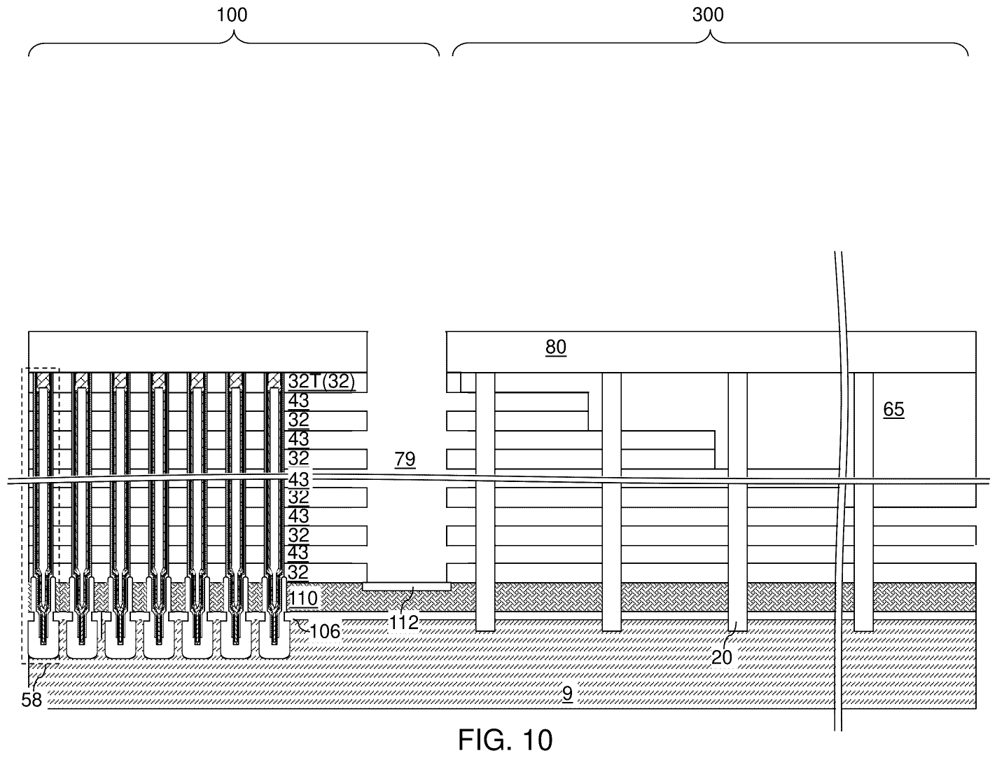

Referring to FIG. 10, an isotropic etch process can be performed to remove the sacrificial material layers 42 selective to the insulating layers 32, the stepped dielectric material portion 65, the memory opening fill structures 58, and the semiconductor oxide barrier layers 112. Laterally-extending cavities 43 can be formed in volumes from which the sacrificial material layers 42 are removed. Sidewall surface segments of the memory opening fill structures 58 can be physically exposed to the laterally-extending cavities 43. In an illustrative example, if the sacrificial material layers 42 comprise silicon nitride, the isotropic etch process may comprise a wet etch process employing phosphoric acid. A suitable cleaning process may be performed as needed. Generally, the laterally-extending cavities 43 can be formed by removing the sacrificial material layers 42 selective to the insulating layers 32 and the memory opening fill structures 58.

Each laterally-extending cavity 43 can be a laterally extending cavity having a lateral dimension that is greater than the vertical extent of the cavity. In other words, the lateral dimension of each laterally-extending cavity 43 can be greater than the height of the laterally-extending cavity 43. A plurality of laterally-extending cavities 43 can be formed in the volumes from which the second material of the sacrificial material layers 42 is removed. Each of the plurality of laterally-extending cavities 43 can extend substantially parallel to the top surface of the semiconductor substrate 9. A laterally-extending cavity 43 can be vertically bounded by a top surface of an underlying insulating layer 32 and a bottom surface of an overlying insulating layer 32. In one embodiment, each laterally-extending cavity 43 can have a uniform height throughout.

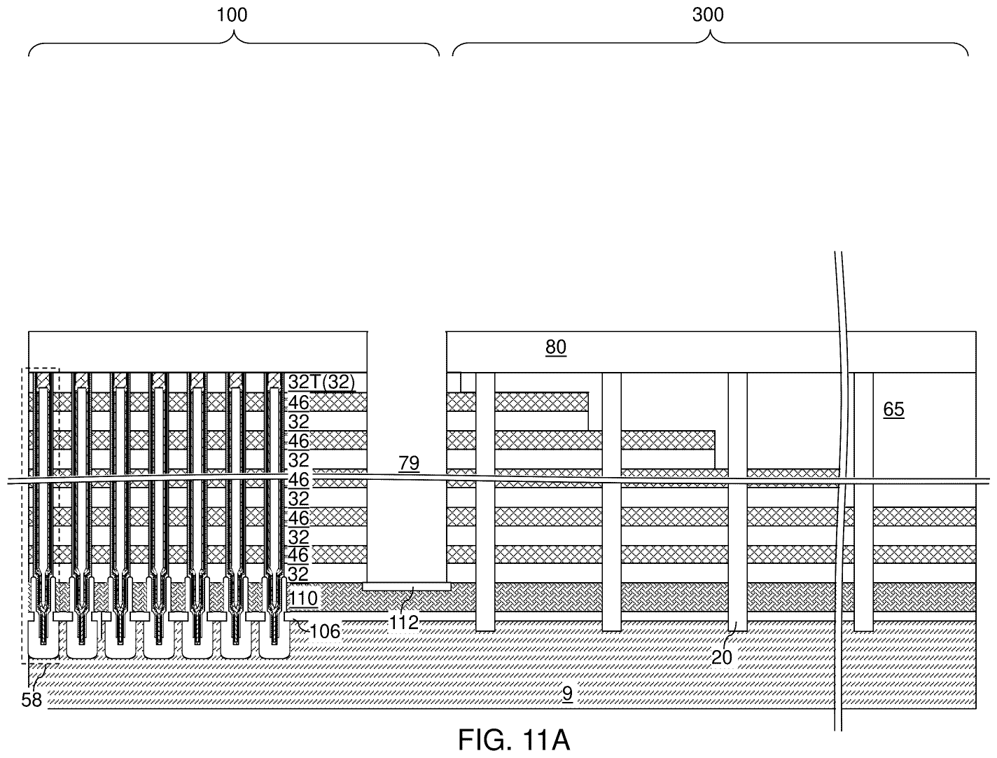

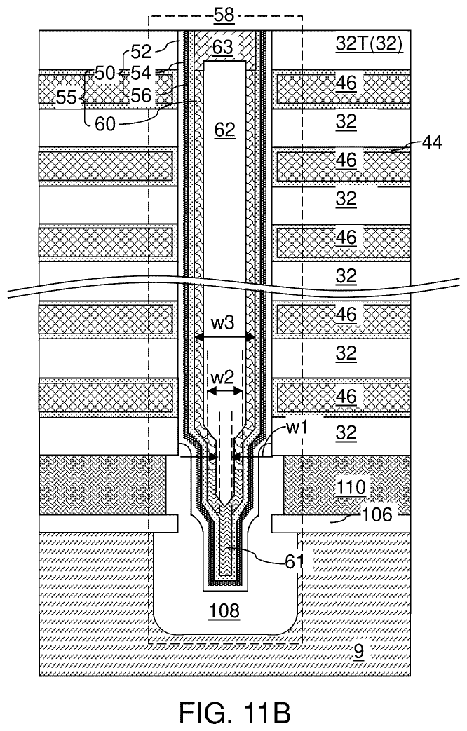

Referring to FIGS. 11A and 11B, an outer blocking dielectric layer 44 can be optionally formed. The outer blocking dielectric layer 44, if present, comprises a dielectric material that functions as a control gate dielectric for the control gates to be subsequently formed in the laterally-extending cavities 43. In case the blocking dielectric layer 52 is present within each memory opening, the outer blocking dielectric layer 44 is optional. In case the blocking dielectric layer 52 is omitted, the outer blocking dielectric layer 44 is present.

At least one conductive material can be deposited in the laterally-extending cavities 43 by providing at least one reactant gas into the laterally-extending cavities 43 through the lateral isolation trenches 79. A metallic barrier layer can be deposited in the laterally-extending cavities 43. The metallic barrier layer includes an electrically conductive metallic material that can function as a diffusion barrier layer and/or adhesion promotion layer for a metal fill material to be subsequently deposited. The metallic barrier layer can include a conductive metallic nitride material such as TiN, TaN, WN, or a stack thereof, or can include a conductive metallic carbide material such as TiC, TaC, WC, or a stack thereof. In one embodiment, the metallic barrier layer can be deposited by a conformal deposition process such as chemical vapor deposition (CVD) or atomic layer deposition (ALD). The thickness of the metallic barrier layer can be in a range from 2 nm to 8 nm, such as from 3 nm to 6 nm, although lesser and greater thicknesses can also be employed. In one embodiment, the metallic barrier layer can consist essentially of a conductive metal nitride such as TiN.

A metal fill material is deposited in the plurality of laterally-extending cavities 43, on the sidewalls of each lateral isolation trench 79, and over the top surface of the contact-level dielectric layer 80 to form a metallic fill material layer. The metallic fill material can be deposited by a conformal deposition method, which can be, for example, chemical vapor deposition (CVD), atomic layer deposition (ALD), electroless plating, electroplating, or a combination thereof. In one embodiment, the metallic fill material layer can consist essentially of at least one elemental metal. The at least one elemental metal of the metallic fill material layer can be selected, for example, from tungsten, cobalt, ruthenium, titanium, and tantalum. In one embodiment, the metallic fill material layer can consist essentially of a single elemental metal. In one embodiment, the metallic fill material layer can be deposited employing a fluorine-containing precursor gas such as WF₆. In one embodiment, the metallic fill material layer can be a tungsten layer including a residual level of fluorine atoms as impurities. The metallic fill material layer is spaced from the insulating layers 32 and the memory stack structures 55 by the metallic barrier layer, which is a metallic barrier layer that blocks diffusion of fluorine atoms therethrough.

A plurality of electrically conductive layers 46 can be formed in the plurality of laterally-extending cavities 43, and a continuous metallic material layer can be formed on the sidewalls of each lateral isolation trench 79 and over the contact-level dielectric layer 80. Each electrically conductive layer 46 includes a portion of the metallic barrier layer and a portion of the metal fill material layer that are located between a vertically neighboring pair of dielectric material layers such as a pair of insulating layers 32. The continuous metallic material layer includes a continuous portion of the metallic barrier layer and a continuous portion of the metal fill material layer that are located in the lateral isolation trenches 79 or above the contact-level dielectric layer 80.

The deposited metallic material of the continuous electrically conductive material layer is etched back from the sidewalls of each lateral isolation trench 79 and from above the contact-level dielectric layer 80 by performing an isotropic etch process that etches the at least one conductive material of the continuous electrically conductive material layer. Each remaining portion of the deposited metallic material in the laterally-extending cavities 43 constitutes an electrically conductive layer 46. Each electrically conductive layer 46 can be a conductive line structure. Thus, the sacrificial material layers 42 are replaced with the electrically conductive layers 46. Generally, the electrically conductive layers 46 can be formed by providing a metallic precursor gas into the lateral isolation trenches 79 and into the laterally-extending cavities 43.

Each electrically conductive layer 46 may be embedded within a respective outer blocking dielectric layer 44, which may comprise a dielectric metal oxide material, such as aluminum oxide. Each outer blocking dielectric layer 44 may have a pair of horizontally-extending portions in contact with a respective one of the insulating layers 32, and a plurality of tubular portions laterally surrounding a respective one of the memory opening fill structures 58 and connecting the pair of horizontally-extending portions. The thickness of each outer blocking dielectric layer 44 may be in a range from 1 nm to 6 nm, although lesser and greater thicknesses may also be employed.

Generally, an assembly of an alternating stack (32, 46) and memory opening fill structures 58 can be formed. The alternating stack (32, 46) comprises a vertically alternating sequence of insulating layers 32 and electrically conductive layers 46. The memory opening fill structures 58 vertically extend through the alternating stack (32, 46). Each of the memory opening fill structures 58 comprises a respective vertical stack of memory elements (which may comprise portions of a memory material layer 54 located at levels of the electrically conductive layers 46), a respective vertical semiconductor channel 60, and a respective drain region 63. At least one uppermost electrically conductive layer 46 may comprise a drain side select gate electrode. At least one bottommost electrically conductive layer 46 may comprise a source side select gate electrode. The remaining electrically conductive layers 46 may comprise word lines. Each word line functions as a common control gate electrode for the plurality of vertical NAND strings (e.g., memory opening fill structures 58).

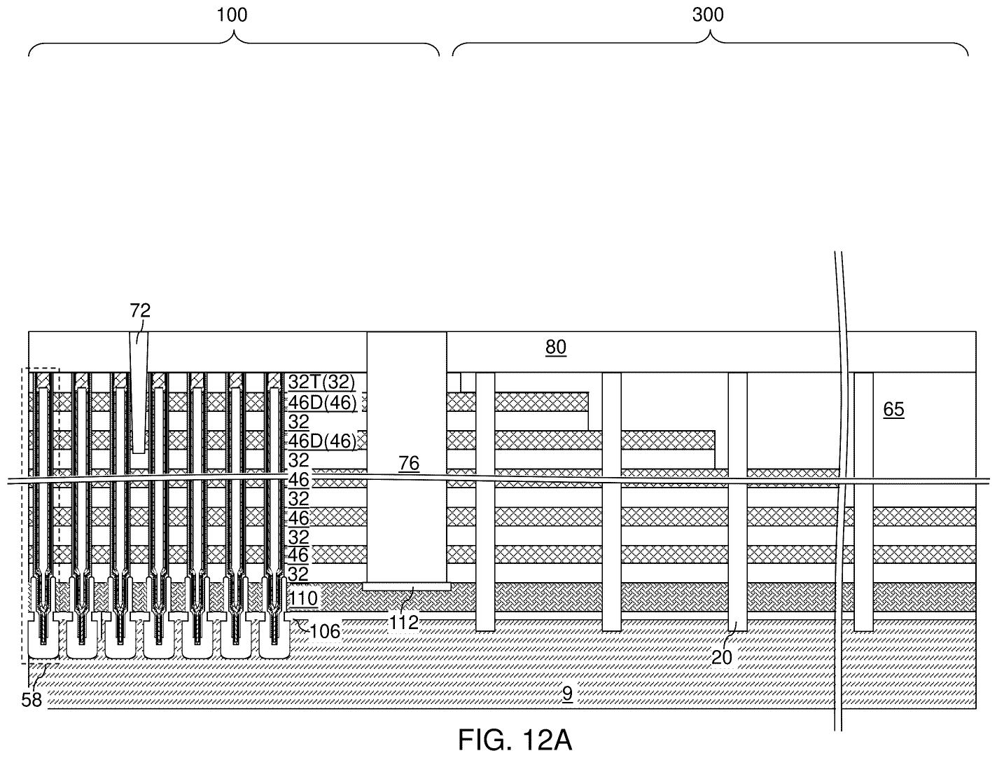

Referring to FIGS. 12A and 12B, a dielectric fill material, such as silicon oxide can be deposited in the lateral isolation trenches 79. Excess portions of the dielectric fill material can be removed from above the contact-level dielectric layer 80. Each remaining portion of the dielectric fill material that fills a respective one of the lateral isolation trenches 79 constitutes a lateral isolation trench fill structure 76, which may be a dielectric wall structure. In an alternative embodiment, an insulating spacer having a tubular configuration can be formed in peripheral portions of each of the lateral isolation trenches 79, and a through-stack conductive via structure may be formed within a respective one of the insulating spacers. In this case, each lateral isolation trench fill structure 76 may comprise a combination of a through-stack conductive via structure and an insulating spacer that laterally surrounds the through-stack conductive via structure.

Drain-select-level isolation trenches can be formed through a subset of the electrically conductive layers 46 including the topmost electrically conductive layer. A subset of the electrically conductive layers 46 can be divided along the second horizontal direction hd2. The electrically conductive layers 46 that are divided by the drain-select-level isolation trenches comprise drain-select-level electrically conductive layers 46D, which are employed as drain-select-level electrodes, i.e., electrodes that are employed to activate or deactivate a respective subset of the NAND strings during operation of the memory device. A dielectric fill material, such as silicon oxide, can be deposited in the drain-select-level isolation trenches to form drain-select-level isolation structures 72.

An alternating stack (32, 46) of insulating layers 32 and electrically conductive layers 46 can be formed in a memory block area between each neighboring pair of lateral isolation trench fill structures 76. The alternating stack (32, 46) can include at least one drain-select-level electrically conductive layer 46D (i.e., at least one drain side select gate electrode) which is employed to activate or deactivate NAND strings (e.g., the memory opening fill structures 58 and adjacent portions of the electrically conductive layers 46) vertically extending through the alternating stack (32, 46). A subset of the electrically conductive layers 46 that underlies the drain-select-level electrically conductive layers 46D comprises word lines, which comprise control electrodes of the NAND strings. A subset of one or more bottommost electrically conductive layers 46 which underlies the word lines comprises source-select-level electrically conductive layers.

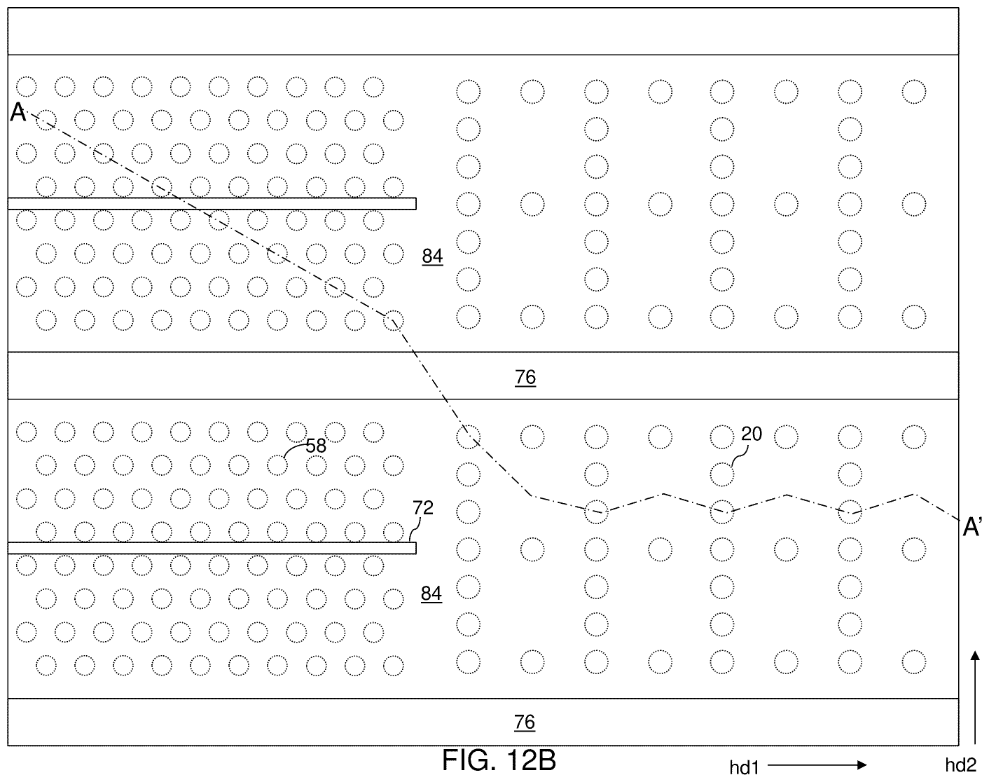

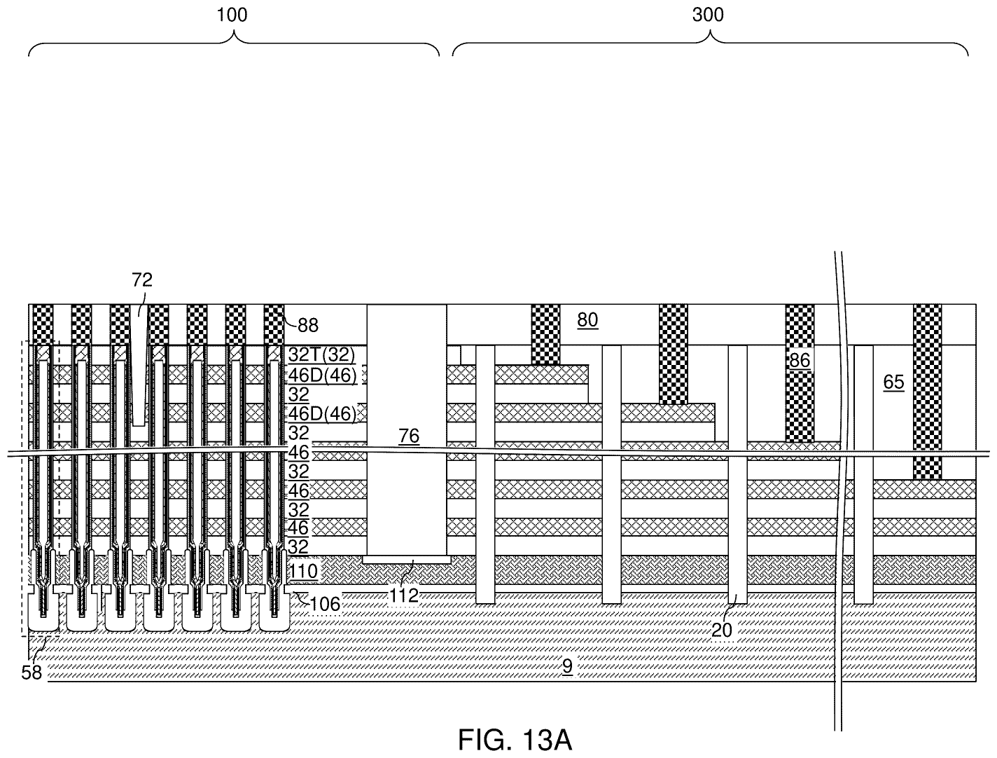

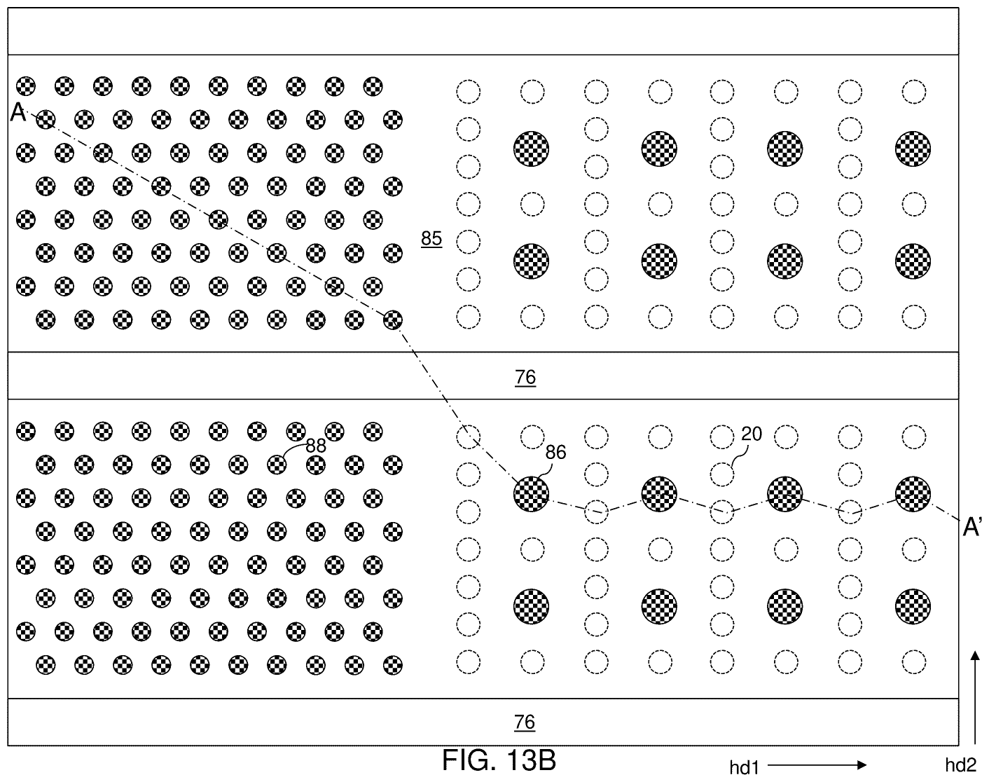

Referring to FIGS. 13A and 13B, drain contact via cavities can be formed through the contact-level dielectric layer 80 over the memory opening fill structures 58. Layer contact via structures can be formed through the contact-level dielectric layer 80 and the stepped dielectric material portion 65 on a top surface of a respective one of the electrically conductive layers 46. At least one combination of a lithographic patterning process and an anisotropic etch process may be employed to form the drain contact via cavities and the layer contact via cavities.

At least one conductive material, such as a combination of a metallic barrier material and a metal fill material, can be deposited in the drain contact via cavities, the layer contact via cavities, and the connection pad cavities. Excess portions of the at least one conductive material can be removed from above the horizontal plane including the top surface of the contact-level dielectric layer 80 by a planarization process, which may employ a recess etch process and/or a chemical mechanical polishing process. Remaining portions of the at least one conductive material that fills the drain contact via cavities constitute drain contact via structures 88 contacting a top surface of a respective one of the drain regions 63. Remaining portions of the at least one conductive material that fills the layer contact via cavities constitute layer contact via structures 86 contacting a top surface of a respective one of the electrically conductive layers 46.

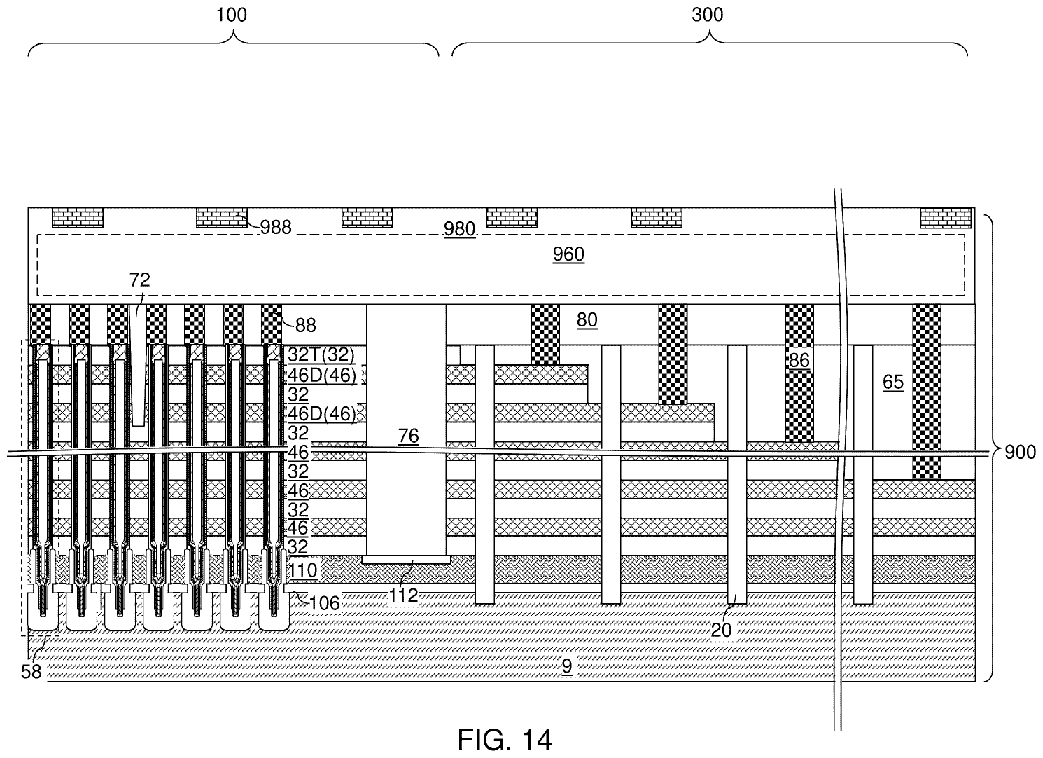

Referring to FIG. 14, additional dielectric material layers and additional metal interconnect structures can be formed over the contact-level dielectric layer 80. The additional dielectric material layers may include at least one via-level dielectric layer, at least one line-level dielectric layer, and/or at least one additional line-and-via-level dielectric layer. The additional metal interconnect structures may comprise metal via structures, metal line structures (including bit lines), and/or integrated metal line-and-via structures. The additional dielectric material layers that are formed above the contact-level dielectric layer 80 are herein referred to as memory-side dielectric material layers 960. The additional metal interconnect structures are collectively referred to as memory-side metal interconnect structures 980. The memory-side dielectric material layers 960 comprise a bit-line-level dielectric material layer embedding bit lines, which are a subset of the memory-side metal interconnect structures 980.

Metal bonding pads, which are herein referred to as memory-side bonding pads 988, may be formed at the topmost level of the memory-side dielectric material layers 960. The memory-side bonding pads 988 may be electrically connected to the memory-side metal interconnect structures 980 and various nodes of the three-dimensional memory array including the electrically conductive layers 46 and the memory opening fill structures 58. A memory die 900 can thus be provided.

The memory-side dielectric material layers 960 are formed over the alternating stacks (32, 46). The memory-side metal interconnect structures 980 are embedded in the memory-side dielectric material layers 960. The memory-side bonding pads 988 can be embedded within the memory-side dielectric material layers 960, and specifically, within the topmost layer among the memory-side dielectric material layers 960. The memory-side bonding pads 988 can be electrically connected to the memory-side metal interconnect structures 980.

In one embodiment, the memory die 900 may comprise: a three-dimensional memory array comprising an alternating stack (32, 46) of insulating layers 32 and electrically conductive layers 46, a two-dimensional array of memory openings 49 vertically extending through the alternating stack (32, 46), and a two-dimensional array of memory opening fill structures 58 located in the two-dimensional array of memory openings 49 and comprising a respective vertical stack of memory elements and a respective vertical semiconductor channel 60; and a two-dimensional array of contact via structures (such as the drain contact via structures 88) overlying the three-dimensional memory array and electrically connected to a respective one of the vertical semiconductor channels 60.

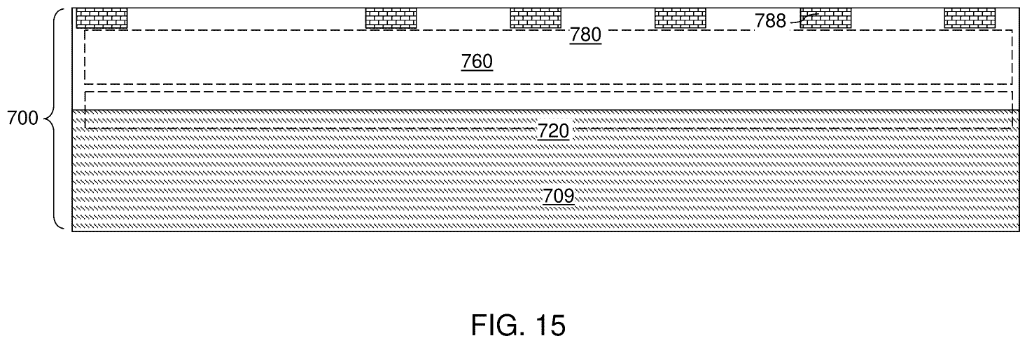

Referring to FIG. 15, a logic die 700 can be provided. The logic die 700 includes a logic-side substrate 709, a peripheral circuit 720 located on the logic-side substrate 709 and comprising logic-side semiconductor devices (such as field effect transistors), logic-side metal interconnect structures 780 embedded within logic-side dielectric material layers 760, and logic-side bonding pads 788. The peripheral circuit 720 can be configured to control operation of the memory array within the memory die 900. Specifically, the peripheral circuit 720 can be configured to drive various electrical components within the memory array including, but not limited to, the electrically conductive layers 46, the drain regions 63, and a source contact structure to be subsequently formed. The peripheral circuit 720 can be configured to control operation of the vertical stack of memory elements in the memory array in the memory die 900.

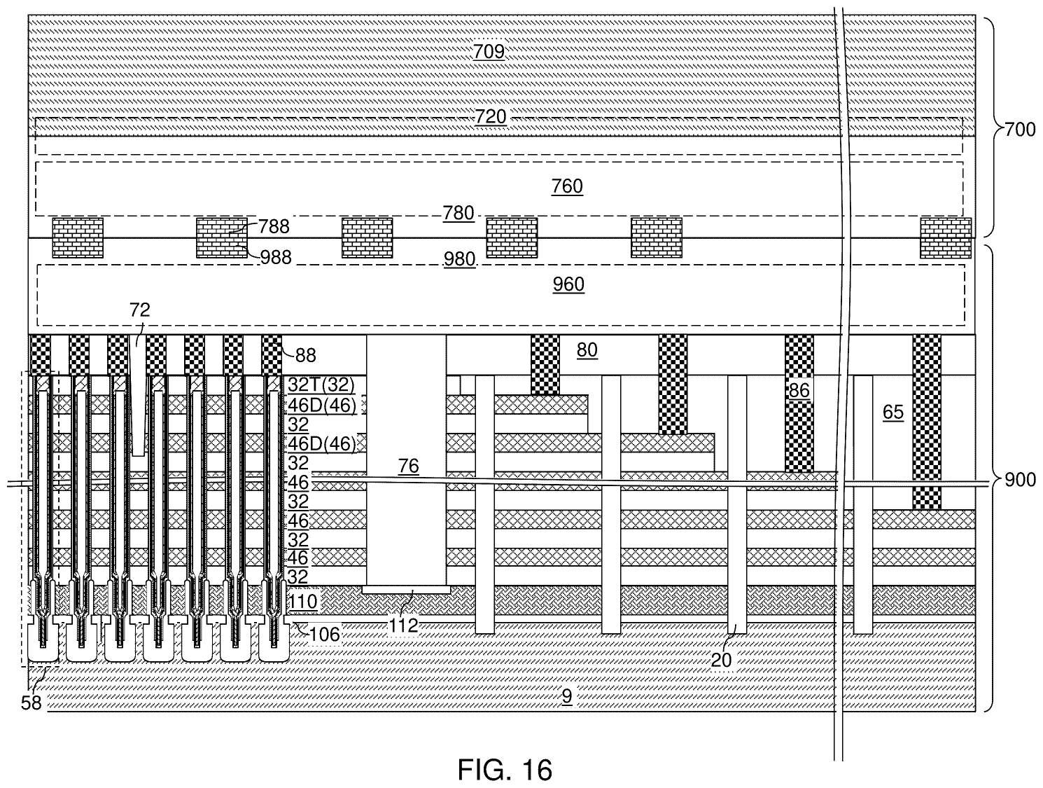

Referring to FIG. 16, the logic die 700 can be attached to the memory die 900, for example, by bonding the logic-side bonding pads 788 to the memory-side bonding pads 988 at a bonding interface. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

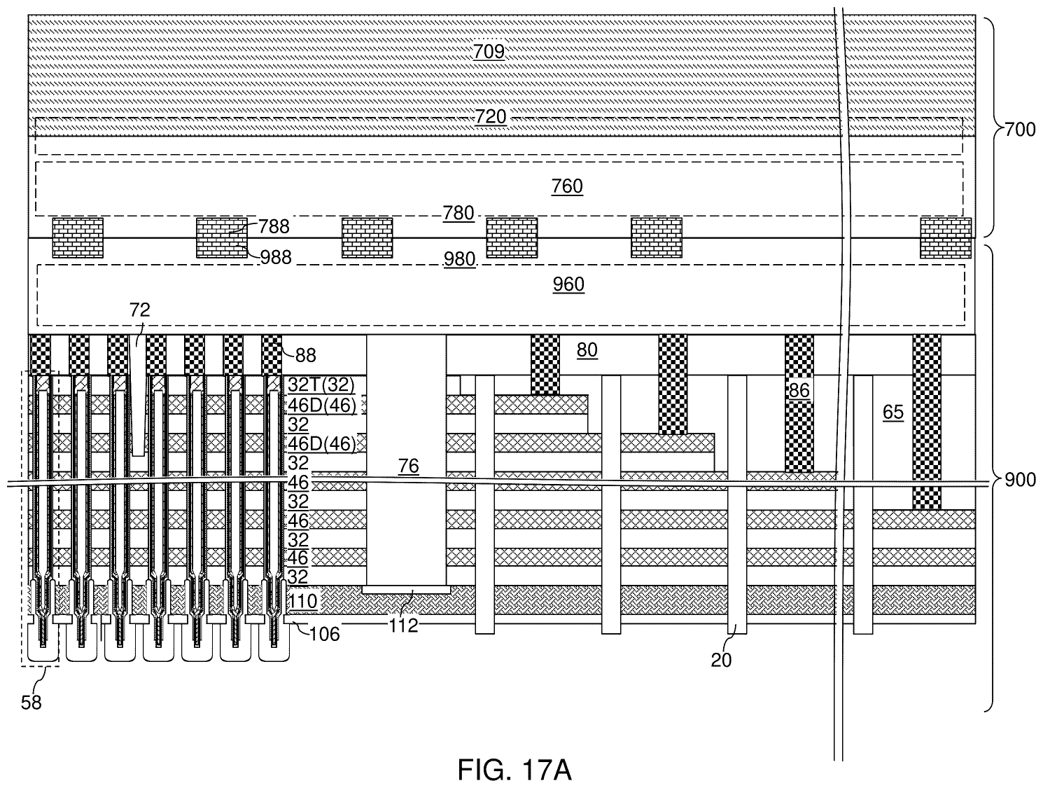

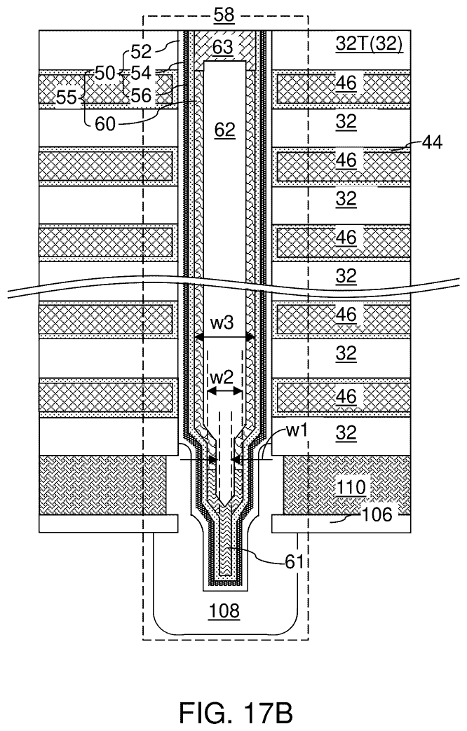

Referring to FIGS. 17A and 17B, the semiconductor substrate 9 can be removed, for example, by grinding, polishing, cleaving, an isotropic etch process, an anisotropic etch process, and/or a combination thereof. If an etch process is employed as a terminal step for removing the semiconductor substrate 9, the combination of the backside insulating layer 106 and the semiconductor oxide spacer structures 108 may be employed as an etch stop structure.

In one embodiment, at least a terminal step of at least one removal process that is employed to remove the semiconductor substrate 9 may comprise a selective wet etch process that etches the first semiconductor material of the semiconductor substrate 9 selective to the materials of the backside insulating layer 106 and the semiconductor oxide spacer structures 108. In an illustrative example, the terminal step of the at least one removal process may comprise a wet etch process using hot trimethyl-2 hydroxyethyl ammonium hydroxide (“hot TMY”) or tetramethyl ammonium hydroxide (TMAH). The entirety of the semiconductor substrate 9 can be removed by the selective wet etch process. Backside surfaces of the backside insulating layer 106 and the semiconductor oxide spacer structures 108 can be physically exposed upon removal of the semiconductor substrate 9.

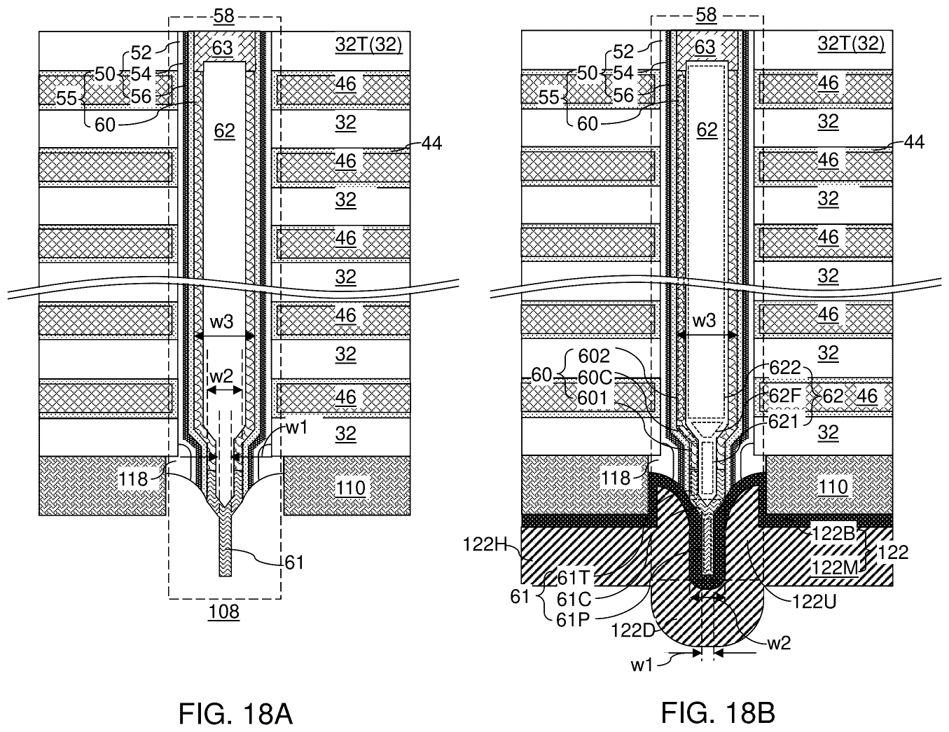

FIGS. 18A and 18B are sequential vertical cross-sectional views of a region around a memory opening fill structure 58 during removal of the backside insulating layer and end portions of a memory film 50 and formation of a metallic source layer 122 according to the first embodiment of the present disclosure.

Referring to FIG. 18A, a first isotropic etch process can be performed to etch the semiconductor oxide (e.g., silicon oxide) materials of the backside insulating layer 106 and the semiconductor oxide spacer structures 108 selective to the material of the semiconductor material layer 110. For example, a wet etch process employing dilute hydrofluoric acid can be performed to etch the entirety of the backside insulating layer 106 and a bottom portion of each semiconductor oxide spacer structure 108. According to an embodiment of the present disclosure, the duration of the first isotropic etch process can be selected such that a top portion of each semiconductor oxide spacer structure 108 remains after the first isotropic etch process. Each remaining top portion of the semiconductor oxide spacer structures 108 has an annular shape, and is herein referred to as an annular dielectric semiconductor oxide spacer 118. Each annular dielectric semiconductor oxide spacer 118 may comprise an annular concave bottom surface. As used herein, a convex surface of an element refers to a surface of the element that has a convex cross-sectional profile (i.e., a profile having an outward-protruding curved cross-sectional profile) such that each center of curvature of the surface is located on the side of the element with respect to the surface itself. As used herein, a concave surface of an element refers to a surface of the element that has a concave cross-sectional profile (i.e., a profile having an inward-recessed curved cross-sectional profile) such that each center of curvature of the surface is located on the opposite side (i.e., outside) of the element with respect to the surface. If a silicon oxide blocking dielectric layer 52 is present, then it is also removed to expose a bottom portion of the respective memory material layer 54.

A second isotropic etch process can be performed to remove physically exposed end portions of the memory material layers 54. For example, if the memory material layers 54 comprise silicon nitride, a wet etch process employing phosphoric acid can be employed to etch the physically exposed bottom end portions of the memory material layers 54.

In case each memory film 50 comprises a dielectric liner 56, a third isotropic etch process can be performed to remove physically exposed end portions of the dielectric liners 56. For example, a wet etch process employing dilute hydrofluoric acid may be employed to etch physically exposed end portions of the dielectric liners 56. A cylindrical surface and a bottom end surface of each semiconductor source structure 61 can be physically exposed.

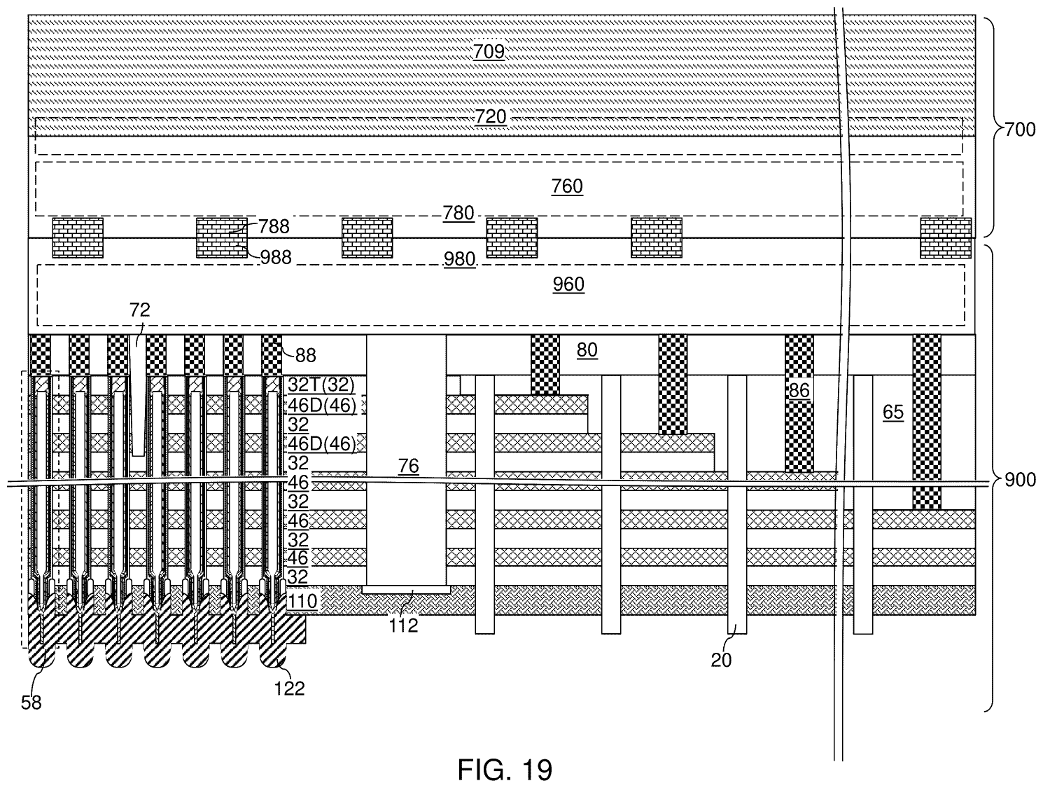

Referring to FIGS. 18B and 19, at least one metallic material can be deposited on the physically exposed surfaces of the semiconductor source structures 61, the memory films 50, the annular dielectric semiconductor oxide spacers 118, and the semiconductor material layer 110 to form a metallic source layer 122. In one embodiment, the metallic source layer 122 may comprise a metallic barrier liner layer 122B and a metal layer 122M. The metallic barrier liner layer 122B may comprise a metallic barrier material such as TiN, TaN, WN, or MON, and may have a thickness in a range from 2 nm to 30 nm, such as from 4 nm to 20 nm. The metal layer 122M comprises a metal such as W, Mo, Ru, Ti, Ta, Co, and/or Cu, and may have thickness in a range from 50 nm to 500 nm. The metallic source layer 122 can be patterned with a suitable pattern.

In one embodiment, the semiconductor source structure 61 comprises the conical semiconductor source portion 61C connecting the pillar semiconductor source portion 61P and the tubular semiconductor source portion 61T. In one embodiment, the pillar semiconductor source portion 61P comprises a cylindrical sidewall surface; and the conical semiconductor source portion 61C comprises a lateral conical surface that connects a top periphery of the cylindrical sidewall surface of the pillar semiconductor source portion 61P to a bottom periphery of the outer cylindrical surface of the tubular semiconductor source portion 61T.

In one embodiment, each annular dielectric semiconductor oxide spacer 118 comprises an outer cylindrical sidewall that contacts an upper cylindrical surface segment of an opening in the semiconductor material layer 110. In one embodiment, the metallic source layer 122 comprises a horizontally-extending portion 122H that contacts a bottom surface of the semiconductor material layer 110 and an upward-protruding tubular portion 122U that contacts a lower cylindrical surface segment of the opening in the semiconductor material layer 110. The upward-protruding tubular portion 122U is a portion of the metallic source layer 122 overlies the horizontal plane including the bottom surface of the semiconductor material layer 110 (i.e., the horizontal plane including a horizontal top surface of the metallic source layer 122). In one embodiment, the metallic source layer 122 also comprises a downward-protruding portion 122D that underlies the semiconductor source structure 61. The downward-protruding portion 122D is a portion of the metallic source layer 122 that underlies the horizontal plane includes a horizontal bottom surface of the metallic source layer 122. In one embodiment, the upward-protruding tubular portion 122U of the metallic source layer 122 contacts an entirety of a cylindrical sidewall surface of the pillar semiconductor source portion 61P.

In one embodiment, an outer cylindrical sidewall of the annular dielectric semiconductor oxide spacer 118 contacts an upper cylindrical surface segment of an opening in the semiconductor material layer 110; and an inner cylindrical sidewall of the annular dielectric semiconductor oxide spacer 118 contacts a cylindrical surface segment of the memory film 50. In one embodiment, the metallic source layer 122 is formed directly on a lower cylindrical sidewall surface segment of an opening in the semiconductor material layer 110.

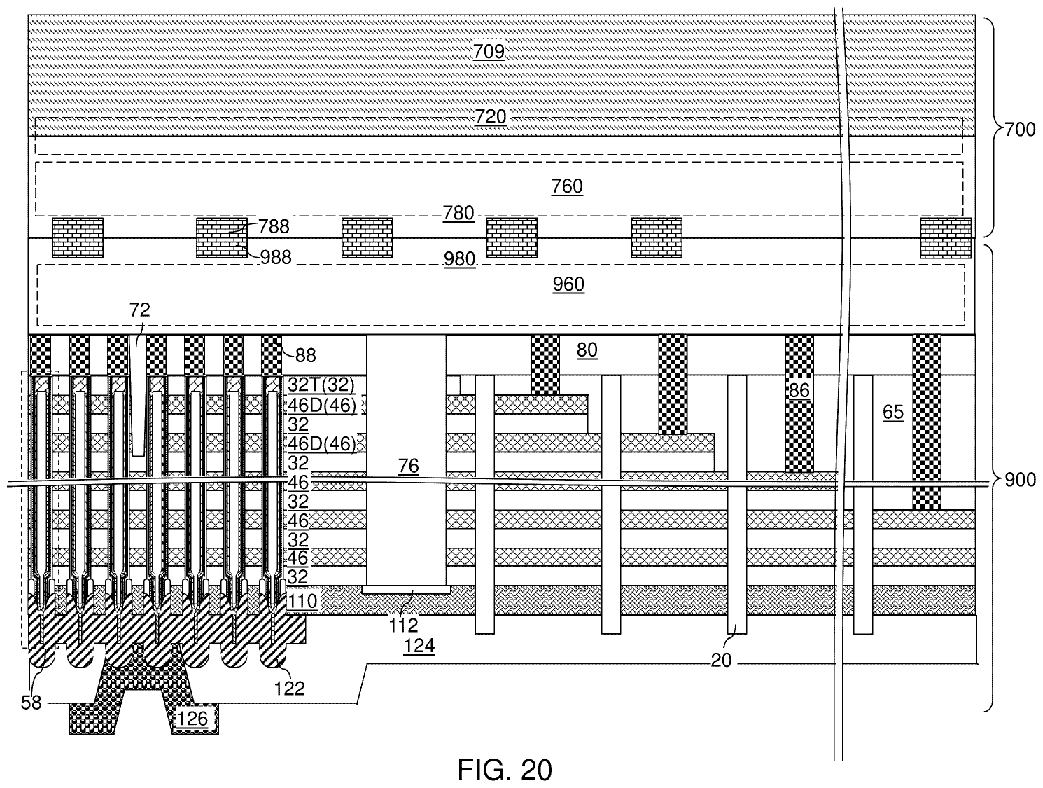

Referring to FIG. 20, a backside dielectric layer 124 can be formed under the metallic source layer 122 and the semiconductor material layer 110. Backside bonding pads 126 can be formed through the backside dielectric layer 124 on bottom surfaces of electrically active nodes, such as the metallic source layer 122 and through-stack via structures (not shown) that vertically extend through peripheral portions of the stepped dielectric material portion 65.

Referring collectively to FIGS. 1-20 and according to various embodiments of the present disclosure, a memory device is provided, which comprises: an alternating stack (32, 46) of insulating layers 32 and electrically conductive layers 46 located over a semiconductor material layer 110; a memory opening 49 vertically extending through the alternating stack (32, 46) and through the semiconductor material layer 110; and a memory opening fill structure 58 located in the memory opening 49 and comprising a vertical semiconductor channel 60 that vertically extends through each electrically conductive layer 46 in the alternating stack (32, 46), a semiconductor source structure 61 adjoined to a first end of the vertical semiconductor channel 60 and laterally surrounded by the semiconductor material layer 110, and a drain region 63 contacting a second end of the vertical semiconductor channel 60, wherein the semiconductor source structure 61 comprises a pillar semiconductor source portion 61P having a first width w1 along a horizontal direction and a tubular semiconductor source portion 61T having an inner cavity and an outer cylindrical surface which has a second width w2 along the horizontal direction, the second width w2 being greater than the first width w1.

In one embodiment, the semiconductor source structure 61 comprises a conical semiconductor source portion 61C connecting the pillar semiconductor source portion 61P and the tubular semiconductor source portion 61T. In one embodiment, the pillar semiconductor source portion 61P comprises a cylindrical sidewall surface; and the conical semiconductor source portion 61C comprises a lateral conical surface that connects a top periphery of the cylindrical sidewall surface of the pillar semiconductor source portion 61P to a bottom periphery of the outer cylindrical surface of the tubular semiconductor source portion 61T.

In one embodiment, the vertical semiconductor channel 60 comprises: a first tubular channel portion 601 having a first cylindrical outer sidewall that has the second width w2 along the horizontal direction; and a second tubular channel portion 602 having a second cylindrical outer sidewall that has a third width w3 along the horizontal direction, the third width w3 being greater than the second width w2. In one embodiment, the vertical semiconductor channel 60 comprises a connecting tapered tubular channel portion 60C that connects the first tubular channel portion 601 and the second tubular channel portion 602 and having a variable lateral dimension that increases with a vertical distance from a horizontal plane including a bottom surface of the semiconductor material layer 110. In one embodiment, a bottom periphery of the first cylindrical outer sidewall of the first tubular channel portion 601 coincides with a top periphery of the outer cylindrical surface of the tubular semiconductor source portion 61T.

In one embodiment, the memory opening fill structure 58 comprises a dielectric core 62 that is laterally surrounded by the vertical semiconductor channel 60. In one embodiment, the dielectric core 62 comprises: a first cylindrical dielectric core portion 621 that is laterally surrounded by the first tubular channel portion 601 and the tubular semiconductor source portion 61T and has a first lateral dimension; and a second cylindrical dielectric core portion 622 that is laterally surrounded by the second tubular channel portion 602 and has a second lateral dimension that is greater than the first lateral dimension. In one embodiment, the semiconductor source structure 61 comprises atoms of an electrical dopant therein; and the dielectric core 62 has a homogeneous material composition throughout and is free of the electrical dopant. In one embodiment, the memory opening fill structure 58 comprises a memory film 50 that laterally surrounds the vertical semiconductor channel 60 and the semiconductor source structure 61.

In one embodiment, the memory device comprises an annular dielectric semiconductor oxide spacer 118 comprising an outer cylindrical sidewall that contacts an upper cylindrical sidewall surface segment of an opening in the semiconductor material layer 110. In one embodiment, the memory device comprises a metallic source layer 122 that comprises a horizontally-extending portion 122H that contacts a bottom surface of the semiconductor material layer 110 and an upward-protruding tubular portion 122U that contacts a lower cylindrical surface segment of the opening in the semiconductor material layer 110. In one embodiment, the metallic source layer 122 further comprises a downward-protruding portion 122D that underlies the semiconductor source structure 61. In one embodiment, the upward-protruding tubular portion 122U of the metallic source layer 122 contacts an entirety of a cylindrical sidewall surface of the pillar semiconductor source portion 61P. In one embodiment, the vertical semiconductor channel 60 comprises p-type polysilicon; the semiconductor material layer 110 comprises intrinsic or lightly doped polysilicon layer; and the semiconductor source structure 61 comprises heavily doped n-type polysilicon having a higher doping concentration than the semiconductor material layer 110.

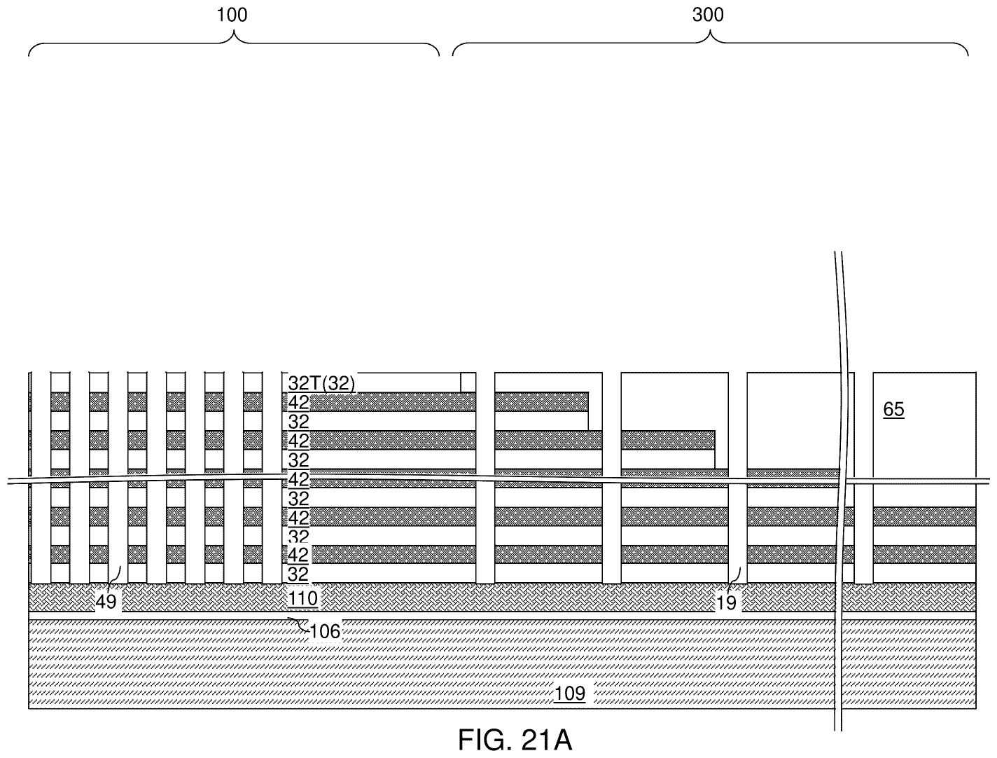

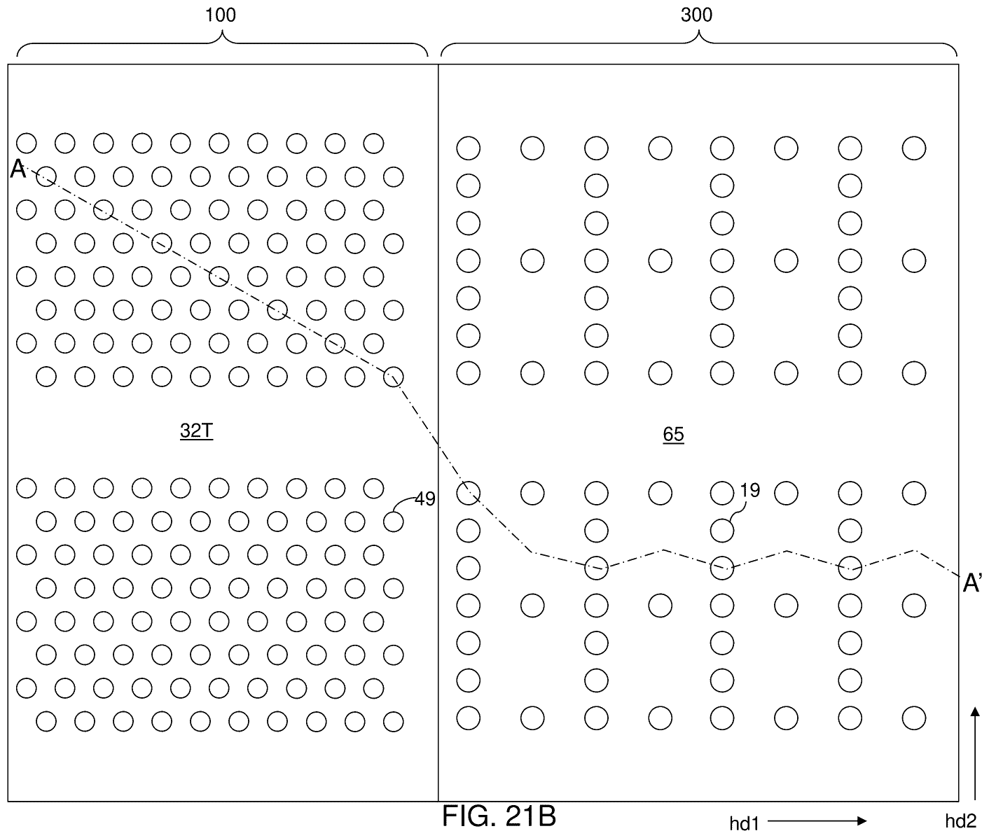

Referring to FIGS. 21A and 21B, a second exemplary structure according to a second embodiment of the present disclosure can be derived from the first exemplary structure illustrated in FIGS. 3A and 3B by replacing the semiconductor substrate 9 with a carrier substrate, and by reducing the depths of the memory openings 49 and the support openings 19 such that the bottom surfaces of the memory openings 49 and the support openings 19 are formed at or in proximity to the horizontal plane including the top surface of the optional semiconductor material layer 110.

Specifically, the semiconductor substrate 9 in the first exemplary structure may be replaced with any carrier substrate 109 that may be subsequently removed selective to the backside insulating layer 106. As such, the carrier substrate 109 may comprise any material that is different from the material of the backside insulating layer 106. In one embodiment, the carrier substrate 109 may comprise a commercially available silicon wafer. The semiconductor material layer 110 in the second exemplary structure may be intrinsic, undoped (i.e., not intentionally doped), or may be doped with dopants of the second conductivity type at an atomic concentration in a range from 1×10¹⁴/cm³ to 2×10²¹/cm³.

The anisotropic etch process that is employed to etch the memory openings 49 and the support openings 19 may have an etch chemistry that etches the materials of the insulating layers 32, the spacer material layers (which may be, for example, the sacrificial material layers 42), and the stepped dielectric material portion 65 selective to the semiconductor material of the semiconductor material layer 110 (if present). If the semiconductor material layer 110 is omitted, then the etch chemistry that etches the materials of the insulating layers 32, the spacer material layers (which may be, for example, the sacrificial material layers 42), and the stepped dielectric material portion 65 is selective to the material of the carrier substrate 109. In one embodiment, a planar surface segment of the semiconductor material layer 110 (if present) or the carrier substrate 109 may be exposed underneath each of the memory openings 49 and the support openings 19. Generally, a first anisotropic etch process that etches materials of the insulating layers 32 and the spacer material layers (such as the sacrificial material layers 42) selective to the material of the semiconductor material layer 110 or the carrier substrate 109 can be performed. First voids comprising the memory openings 49 can be formed through the alternating stack (32, 42).

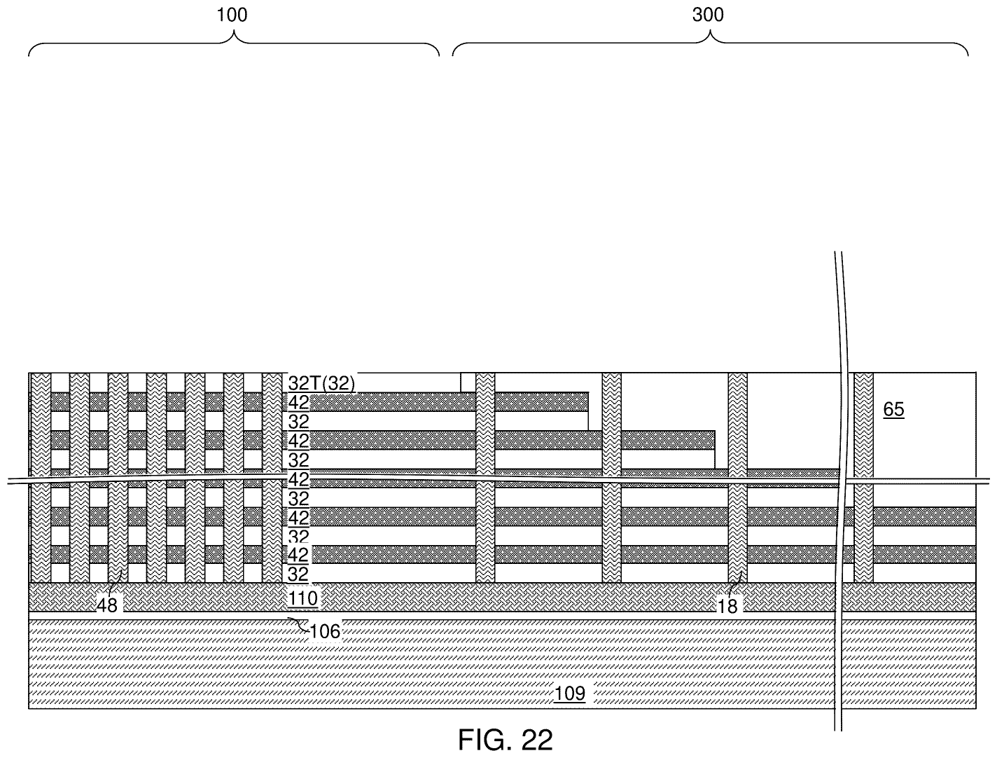

Referring to FIG. 22, the processing steps described with reference to FIG. 4 can be performed to form sacrificial memory opening fill structures 48 and sacrificial support opening fill structures 18 in the memory openings 49 and in the support openings 19, respectively.

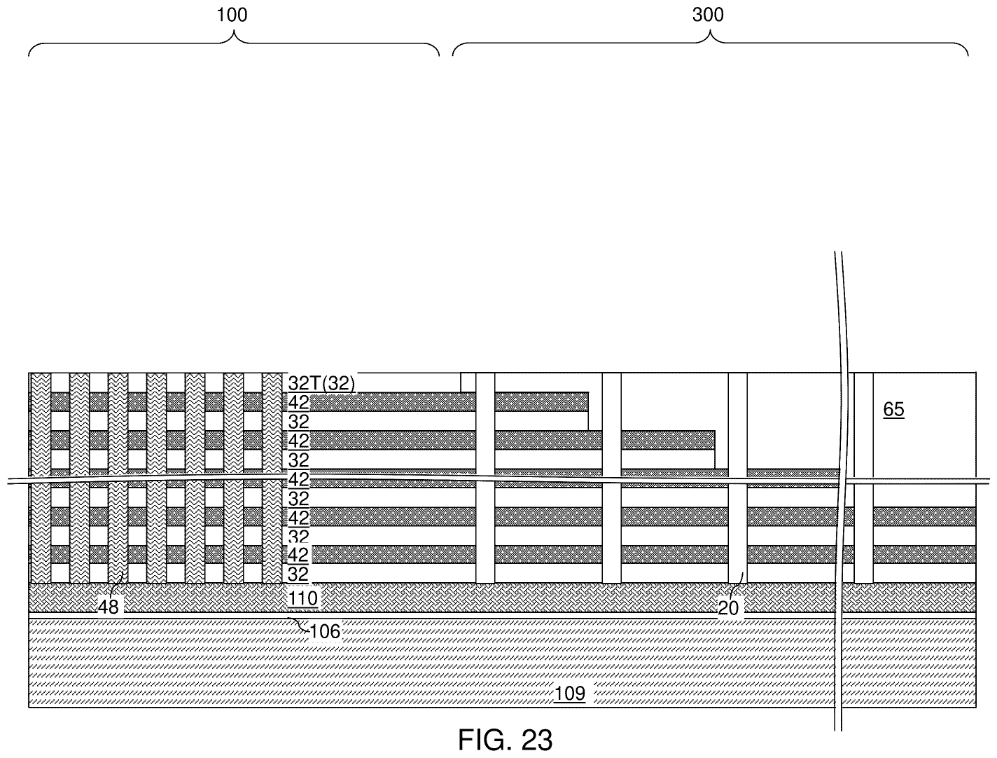

Referring to FIG. 23, the processing steps described with reference to FIG. 5 can be performed to replace the sacrificial support opening fill structures 18 with support pillar structures 20.

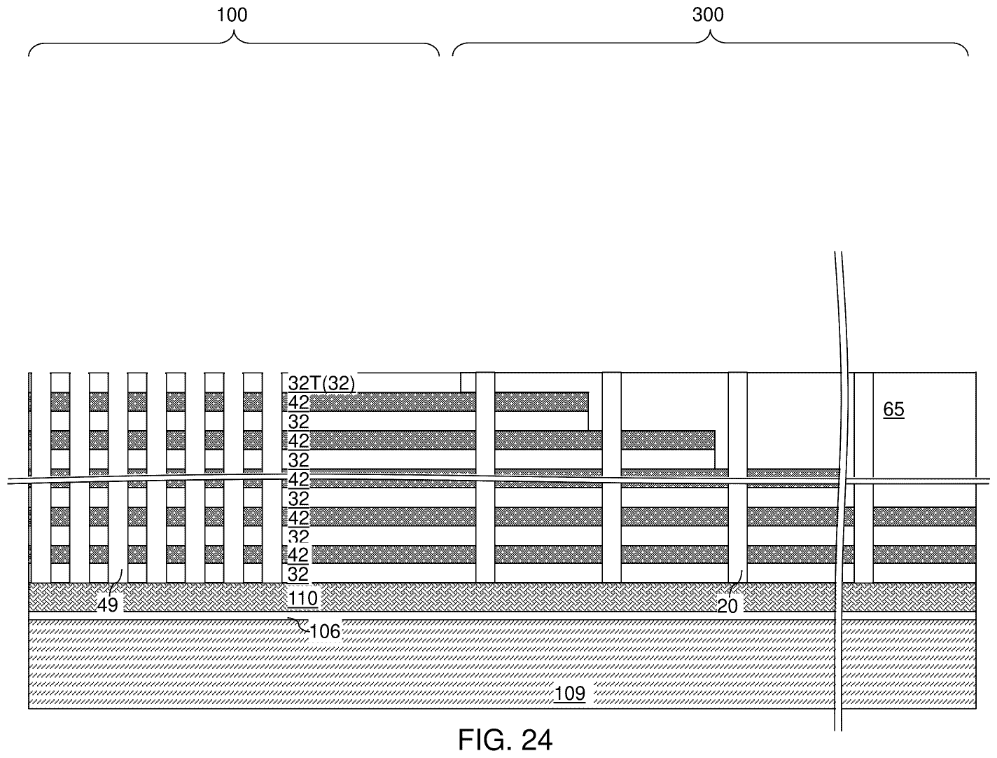

Referring to FIG. 24, the processing steps described with reference to FIG. 6 can be performed to remove the sacrificial memory opening fill structures 48. Voids are formed in the volumes of the memory openings 49.

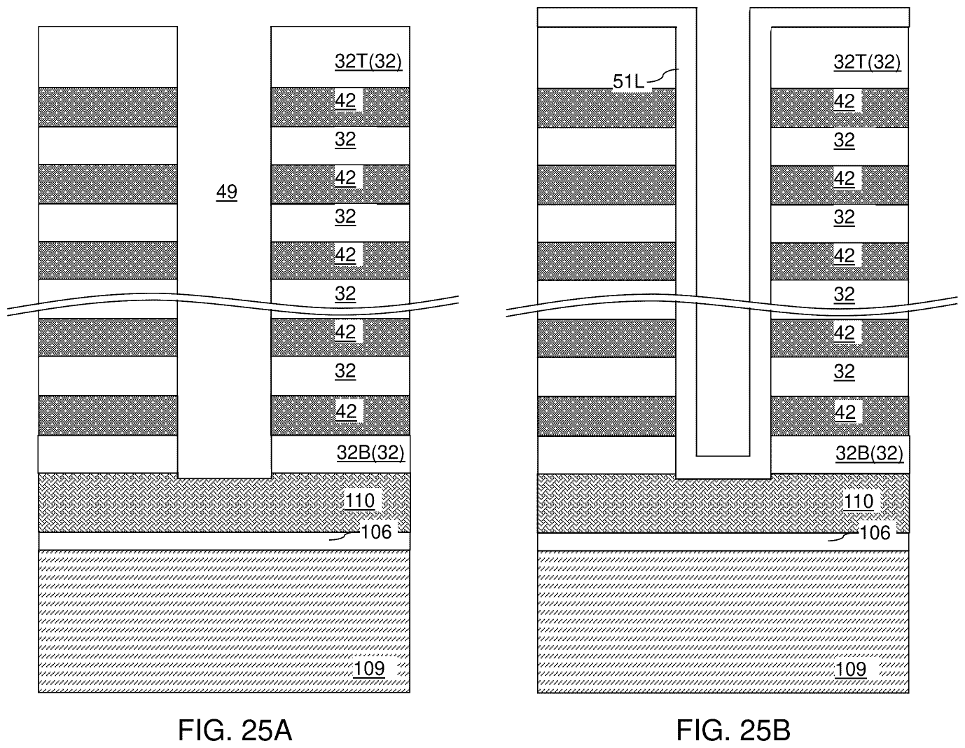

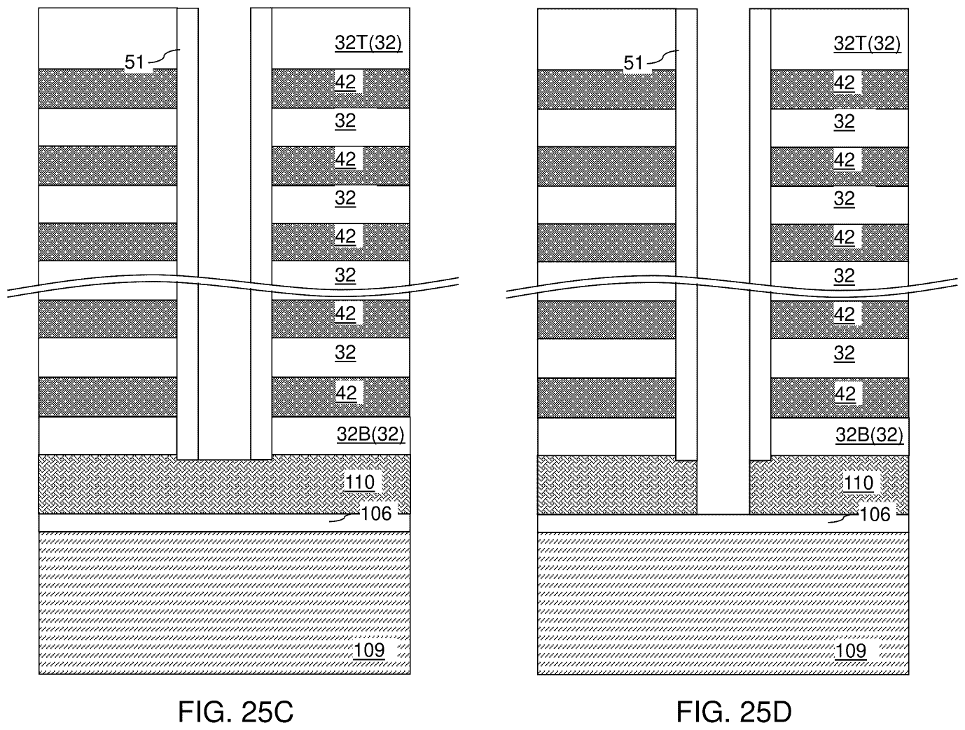

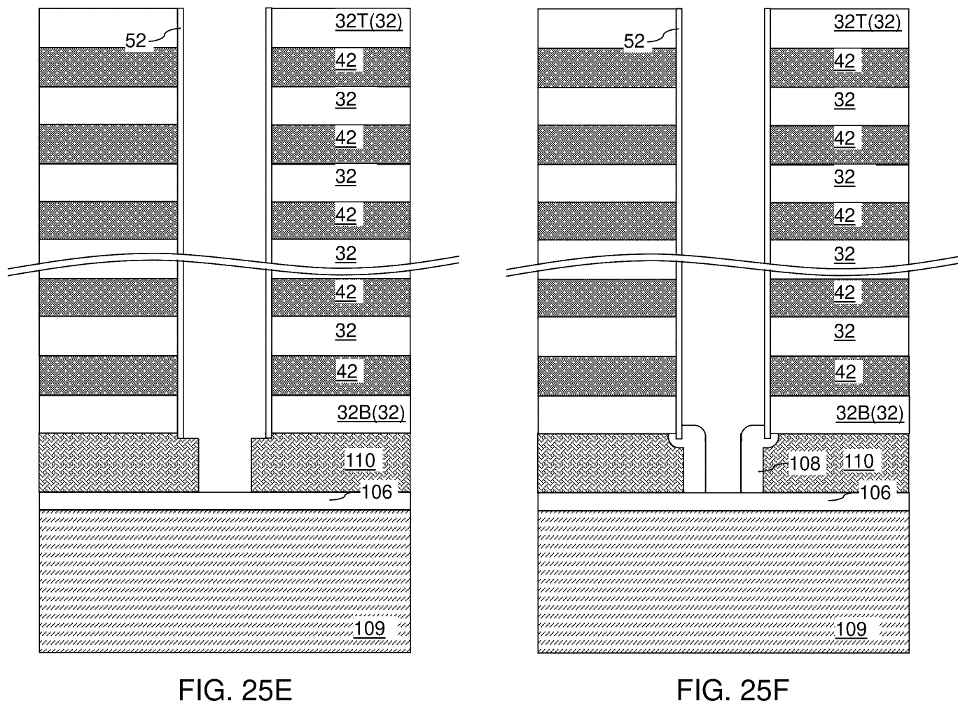

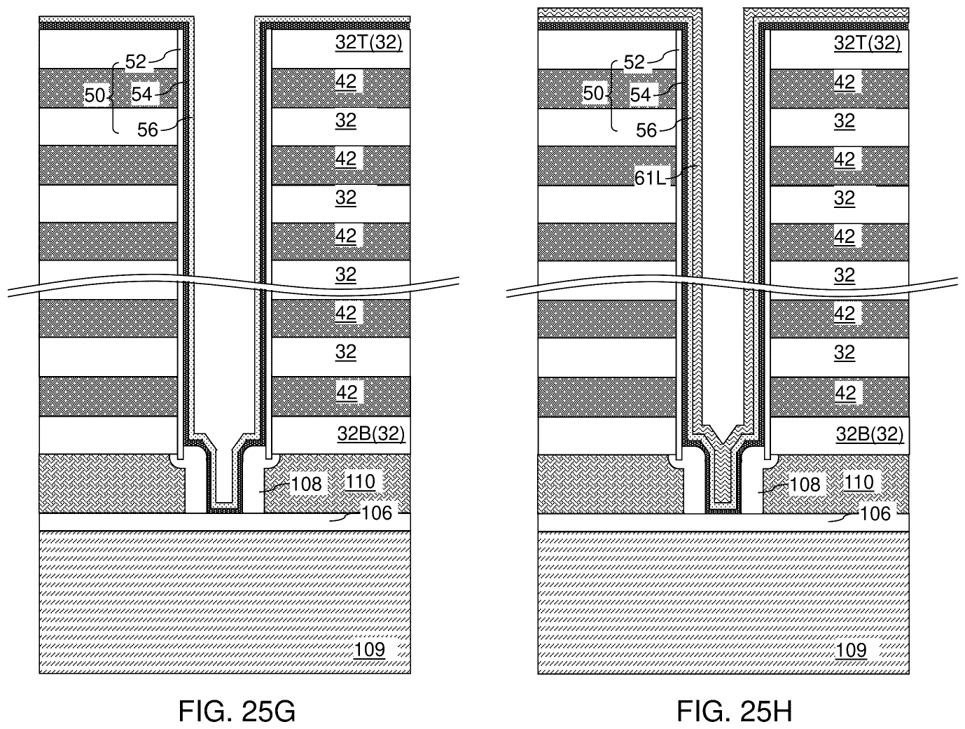

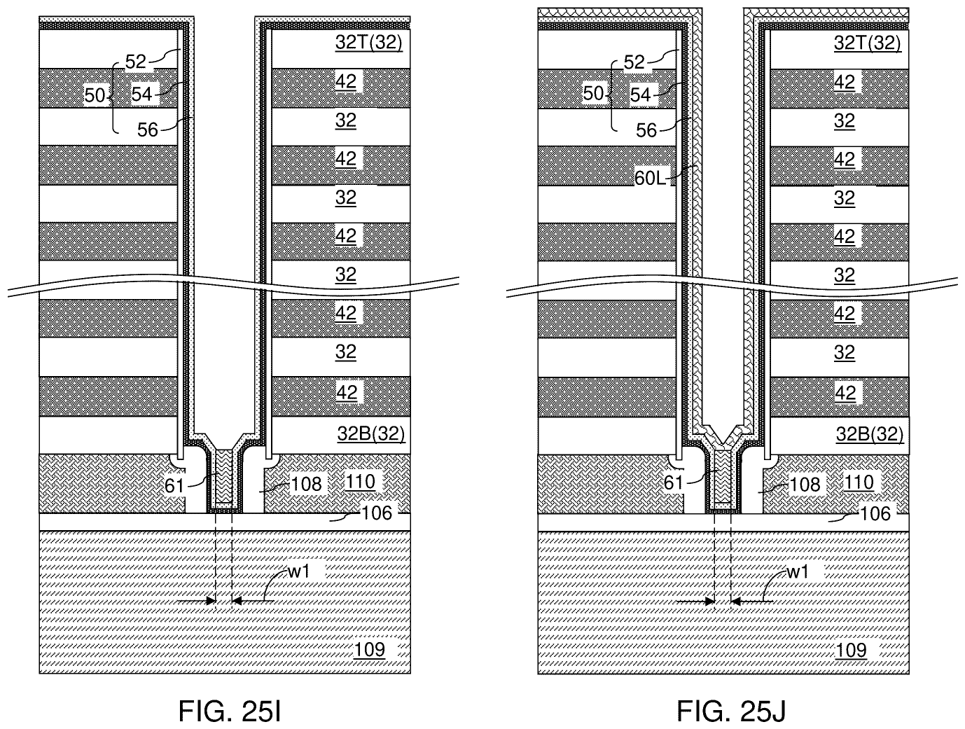

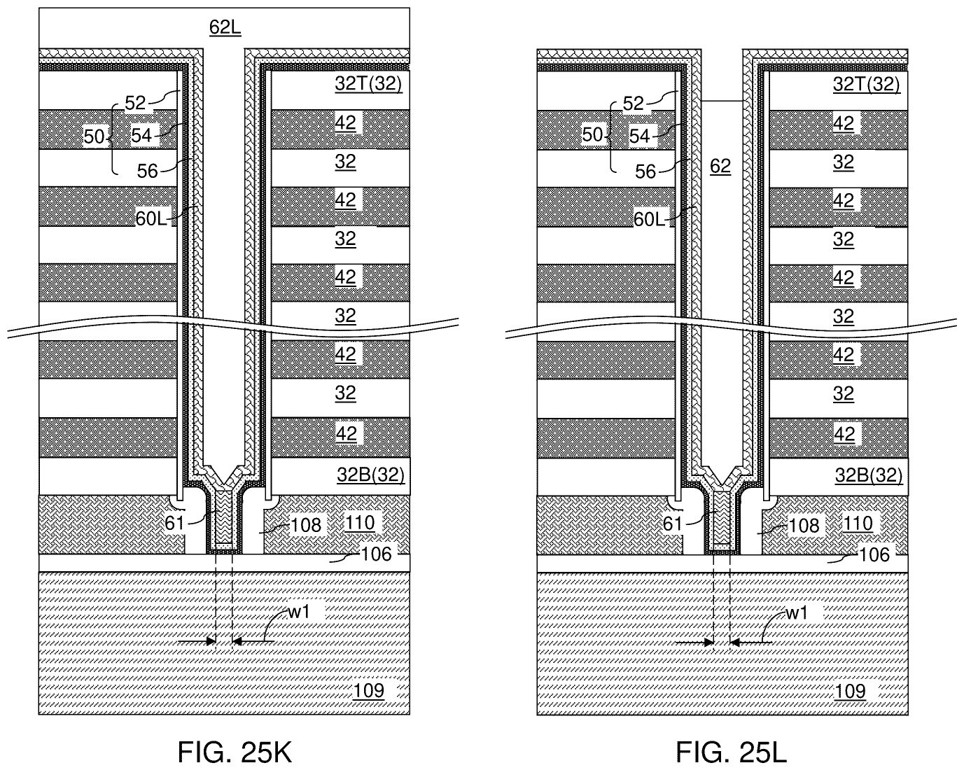

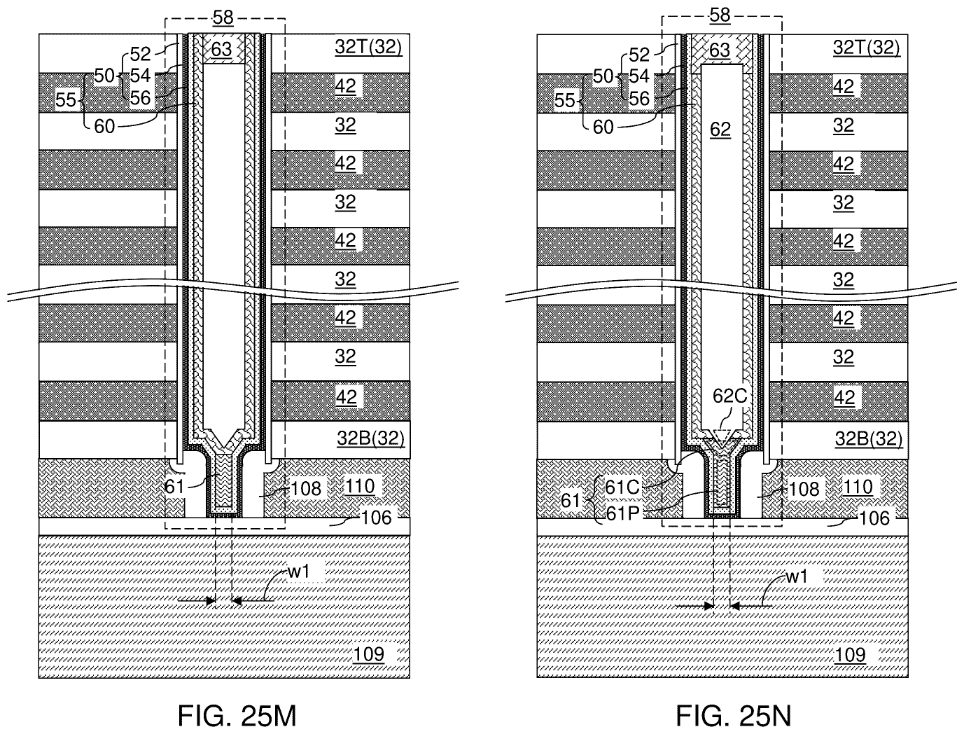

FIGS. 25A-25N are sequential vertical cross-sectional views of a memory opening 49 in the second exemplary structure during formation of a memory opening fill structure 58 according to the second embodiments of the present disclosure.

Referring to FIG. 25A, a memory opening 49 is illustrated after the processing steps of FIG. 24.

Referring to FIG. 25B, a blocking dielectric material layer 51L can be deposited in the periphery of each first void comprising a volume of a memory opening 49 as provided after the processing steps of FIGS. 24 and 25A. The blocking dielectric material layer 51L may comprise any material that may be employed for the blocking dielectric layer 52 described with reference to the first embodiment. The blocking dielectric material layer 51L may be deposited by a conformal deposition process, such as a chemical vapor deposition process or an atomic layer deposition process. The thickness of the blocking dielectric material layer 51L is less than one half of the diameter of each memory opening 49, and may be in a range from 7 nm to 30 nm, such as from 8 nm to 20 nm, although lesser and greater thicknesses may also be employed.

Referring to FIG. 25C, an anisotropic etch process can be performed to remove horizontally-extending portions of the blocking dielectric material layer 51L. For example, a reactive ion etch process that etches the material of the blocking dielectric material layer 51L can be performed. Each remaining portion of the blocking dielectric material layer 51L that remains in a respective memory opening 49 comprises a tubular blocking dielectric spacer 51. An top surface segment of the semiconductor material layer 110 can be physically exposed underneath a void that is laterally surrounded by the tubular blocking dielectric spacer 51.

Referring to FIG. 25D, an additional anisotropic etch process, which is herein referred to as a second anisotropic etch process, can be performed to etch cylindrical portions of the semiconductor material layer 110 that are not masked by the alternating stack (32, 42) or the tubular blocking dielectric spacers 51. Second voids are formed through the semiconductor material layer 110 (if present, or in the carrier substrate 109 if layer 110 is omitted) in areas that are not masked by the alternating stack (32, 42) or the tubular blocking dielectric spacers 51. Each contiguous combination of a volume of a first void as formed at the processing steps of FIG. 25A and a volume of a second void as formed at the processing steps of FIG. 25D constitutes a total volume of a memory opening through the alternating stack (32, 42) and the semiconductor material layer 110. A top surface segment of the backside insulating layer 106 or the carrier substrate 109 can be physically exposed at the bottom of each memory opening.

Referring to FIG. 25E, an isotropic recess etch process can be performed to isotropically recess the tubular blocking dielectric spacers 51. An inner cylindrical portion of each tubular blocking dielectric spacer 51 can be isotropically etched by the isotropic recess etch process. In one embodiment, the etch chemistry of the isotropic recess etch process may be selective to the material of the semiconductor material layer 110 (if present) or the carrier substrate 109. For example, if the tubular blocking dielectric spacers 51 comprise silicon oxide, the isotropic recess etch process may comprise a wet etch process employing dilute hydrofluoric acid. The duration of the isotropic recess etch process can be selected such that an outer cylindrical portion of each tubular blocking dielectric spacer 51 remains after the isotropic recess etch process after the isotropic recess etch process to form a blocking dielectric layer 52. Each blocking dielectric layer 52 may have a cylindrical configuration, and may have a uniform thickness throughout. The thickness of each blocking dielectric layer 52 (i.e., the lateral distance between a cylindrical outer surface and a cylindrical inner surface) may be in a range from 2 nm to 20 nm, such as from 4 nm to 12 nm, although lesser and greater thicknesses may also be employed. In one embodiment, surface portions of the backside insulating layer 106 may be collaterally etched during the isotropic recess etch process.

Generally, a memory opening 49 vertically extending through the alternating stack (32, 42) and the semiconductor material layer 110 can be formed. The volume of a void within the memory opening 49 may have a stepped vertical cross-sectional profile including a straight upper cylindrical sidewall (such as an inner cylindrical sidewall of a blocking dielectric layer 52) that extends through the alternating stack (32, 42), a straight lower cylindrical sidewall that extends through the semiconductor material layer 110, and a horizontal annular surface segment that connects the straight upper cylindrical sidewall and the straight lower cylindrical sidewall.

Referring to FIG. 25F, an oxidation process may be optionally performed to convert physically exposed surface portions of the semiconductor material layer 110 into semiconductor oxide spacer structures 108. The semiconductor oxide spacer structures 108 comprise a dielectric oxide of the semiconductor material of the semiconductor material layer 110. If the semiconductor material layer 110 comprises silicon, then the semiconductor oxide spacer structures 108 comprise silicon oxide. In one embodiment, each semiconductor oxide spacer structure 108 may comprise a cylindrical semiconductor oxide portion and an annular semiconductor oxide portion.

Referring to FIGS. 25G, a memory material layer 54 and an optional dielectric liner 56 can be formed by performing conformal deposition processes. Each of the memory material layer 54 and the dielectric liner 56 may have the same material composition and the same thickness range as in the first embodiment. The combination of the blocking dielectric layers 52, the memory material layer 54, and the optional dielectric liner 56 constitutes a memory film 50.

Referring to FIG. 25H, the processing steps described with reference to FIG. 7D can be performed to form the heavily-doped semiconductor material layer 61L.

Referring to FIG. 25I, the processing steps described with reference to FIG. 7E can be performed to recess the semiconductor material of the heavily-doped semiconductor material layer 61L. Each remaining portion of the heavily-doped semiconductor material layer 61L that remains at the bottom of each memory opening 49 comprises a semiconductor source structure 61. Each semiconductor source structure 61 comprises a cylindrical heavily-doped semiconductor material portion having a doping of the second conductivity type. Each semiconductor source structure 61 may have a shape of a cylindrical pillar having a diameter of the first width w1. Generally, the semiconductor source structure 61 is formed after formation of the memory film 50. In one embodiment, a top surface of the semiconductor source structure 61 is formed at or about a horizontal plane including a top surface of the semiconductor material layer 110 (if present).

Referring to FIG. 25J, the processing steps described with reference to FIG. 7F may be performed to form the semiconductor channel material layer 60L. The semiconductor channel material layer 60L in the second exemplary structure may have the same material composition and the same thickness range as in the first exemplary structure.

Referring to FIG. 25K, the processing steps described with reference to FIG. 7G may be performed to form a dielectric core layer 62L.

Referring to FIG. 25L, the processing steps described with reference to FIG. 7H can be performed to form a dielectric core 62 within each memory opening 49.

Referring to FIG. 25M, the processing steps described with reference to FIG. 7I can be performed to form a drain region 63 within each memory opening 49.

Referring to FIG. 25N, the processing steps described with reference to FIG. 7J can be performed to activate electrical dopants in the semiconductor source structures 61, the vertical semiconductor channels 60, and the drain regions 63, and to crystallize or recrystallize the semiconductor materials of the semiconductor source structures 61, the vertical semiconductor channels 60, the semiconductor material layer 110, and the drain regions 63. The dopants of the second conductivity type in the semiconductor source structure 61 may diffuse upward into a lower portion of the vertical semiconductor channel 60, and the lower portion of the vertical semiconductor channel 60 can be converted into a doped semiconductor material portion 61C having a net doping of the second conductivity type. In this case, the newly-formed semiconductor material portion 61C having a net doping of the second conductivity type is incorporated into the semiconductor source structure 61.

In summary, a memory material layer 54, a semiconductor source structure 61, a vertical semiconductor channel 60, a dielectric core 62, and a drain region 63 can be formed in a remaining volume of the memory opening 49 after formation of the optional semiconductor oxide spacer structure 108 to form a memory opening fill structure 58. Each memory opening fill structure 58 can be located in a respective memory opening 49, and comprises an optional semiconductor oxide spacer structure 108, a vertical semiconductor channel 60 that vertically extends through each sacrificial material layer 42 in the alternating stack (32, 42), a semiconductor source structure 61 adjoined to a first end of the vertical semiconductor channel 60 and optionally laterally surrounded by the semiconductor material layer 110 (if present), and a drain region 63 contacting a second end of the vertical semiconductor channel 60.

In one embodiment, each semiconductor source structure 61 comprises: a pillar semiconductor source portion 61P having a uniform lateral dimension, and a conical semiconductor source portion 61C overlying the pillar semiconductor source portion 61P and having a variable lateral dimension that increases as a function of a vertical distance from a horizontal plane including a bottom surface of the semiconductor material layer 110.

In one embodiment, each memory opening fill structure 58 comprises a memory film 50 that includes a layer stack that includes, from outside to inside, a blocking dielectric layer 52, a memory material layer 54, and a dielectric liner 56. In one embodiment, the entirety of the cylindrical surface segment of an opening in the semiconductor material layer 110 may be located within a first cylindrical vertical plane. In one embodiment, the entirety of the cylindrical interface between the blocking dielectric layer 52 and the memory material layer 54 may be located within a second cylindrical plane. In one embodiment, the first cylindrical vertical plane may be contained entirely within the second cylindrical plane.

In one embodiment, the memory material layer 54 comprises: a first cylindrical portion contacting an upper cylindrical surface segment of an inner sidewall of the blocking dielectric layer 52; a second cylindrical portion contacting an inner cylindrical surface segment of the annular dielectric semiconductor oxide spacer 118; and a connecting portion that connects a top end of the second cylindrical portion to a bottom end of the first cylindrical portion.

In one embodiment, the memory opening fill structure 58 comprises a dielectric core 62; and the dielectric core 62 comprises a conical bottom tip portion 62C contacting a conical inner surface of the conical semiconductor source portion 61C. In one embodiment, dopant ions are not implanted into the dielectric cores 62. In one embodiment, the memory opening fill structure 58 comprises a dielectric core 62 that is laterally surrounded by the vertical semiconductor channel 60; the semiconductor source structure 61 comprises atoms of an electrical dopant therein; and the dielectric core 62 has a homogeneous material composition throughout and is free of the electrical dopant.

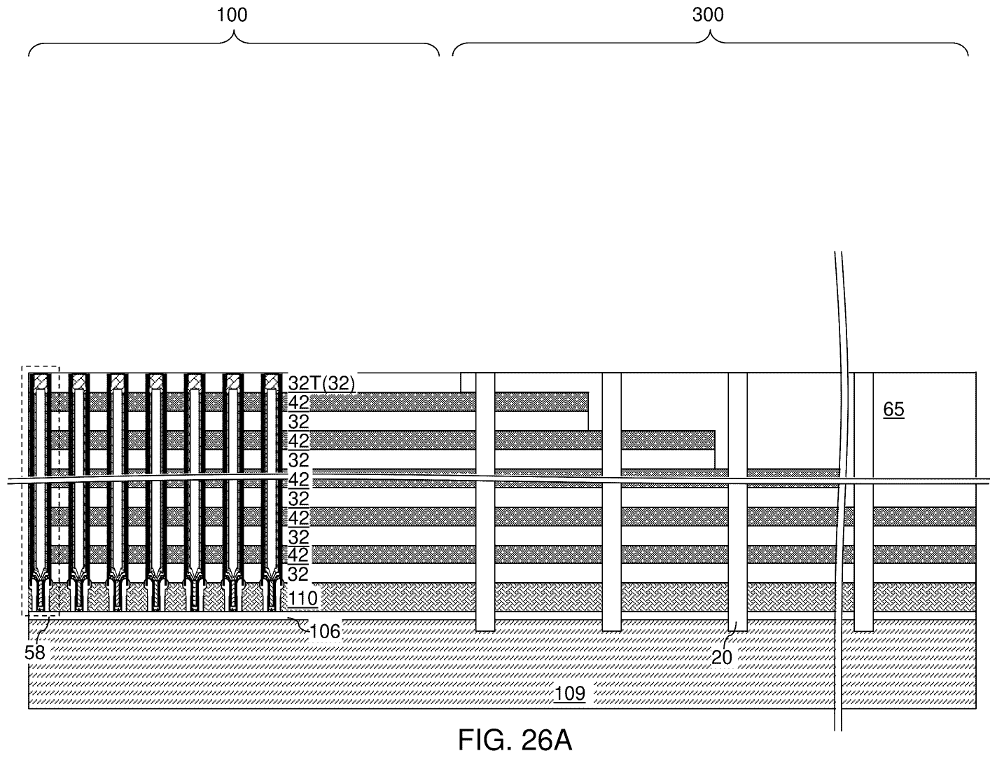

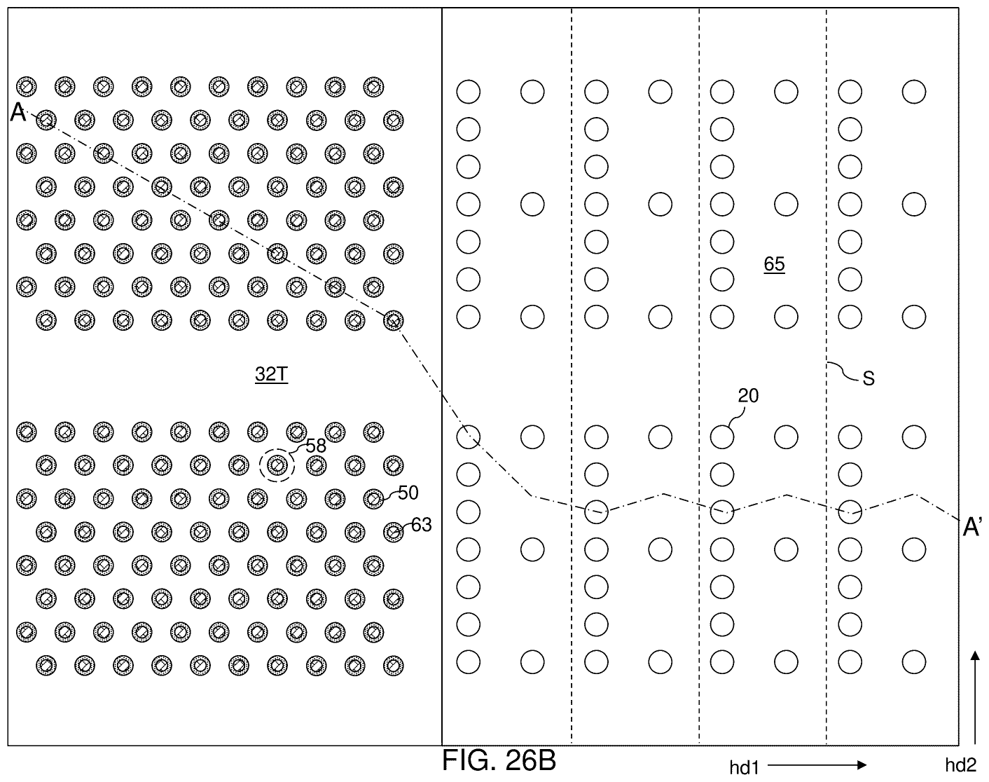

Referring to FIGS. 26A and 26B, the second exemplary structure is illustrated after formation of memory opening fill structures 58 within the memory openings 49. The memory opening fill structures 58 are located in the memory openings 49. Each of the memory opening fill structures 58 comprises a respective memory film 50 and a respective vertical semiconductor channel 60.

The memory opening fill structures 58 are arranged in rows laterally extending along a first horizontal direction hd1, and the rows are laterally spaced apart from each other along a second horizontal direction hd2 that is perpendicular to the first horizontal direction hd1. Each of the memory opening fill structures 58 comprises a vertical stack of memory elements (which may comprise portions of a memory film 50 located at levels of the sacrificial material layers 42), and a respective drain region 63.

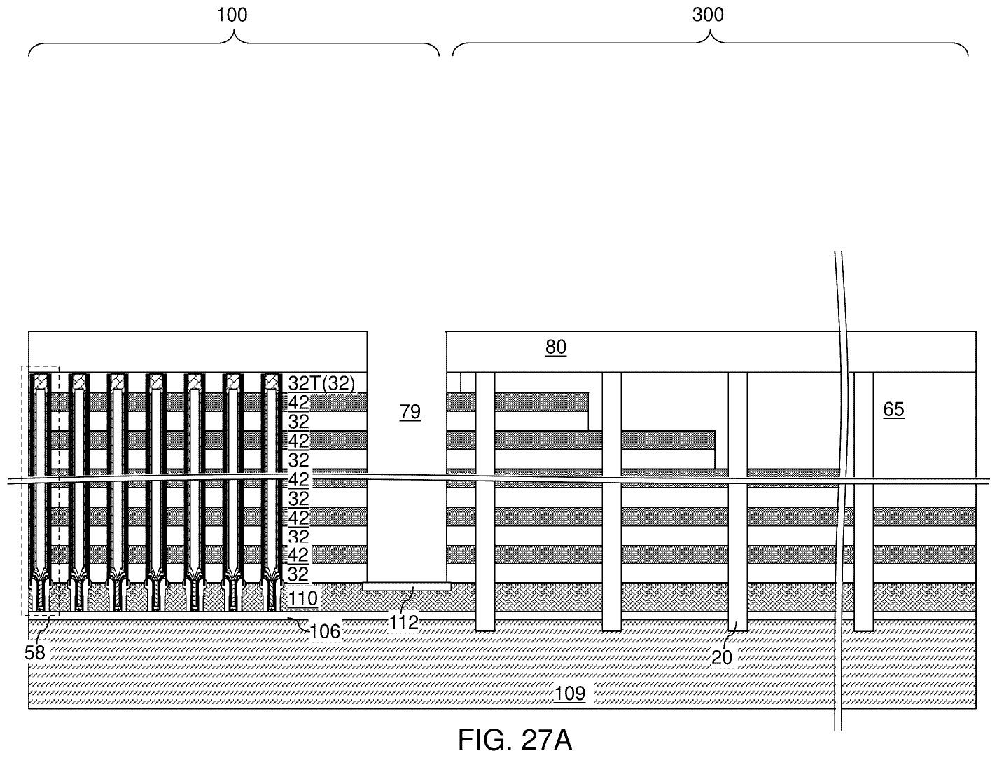

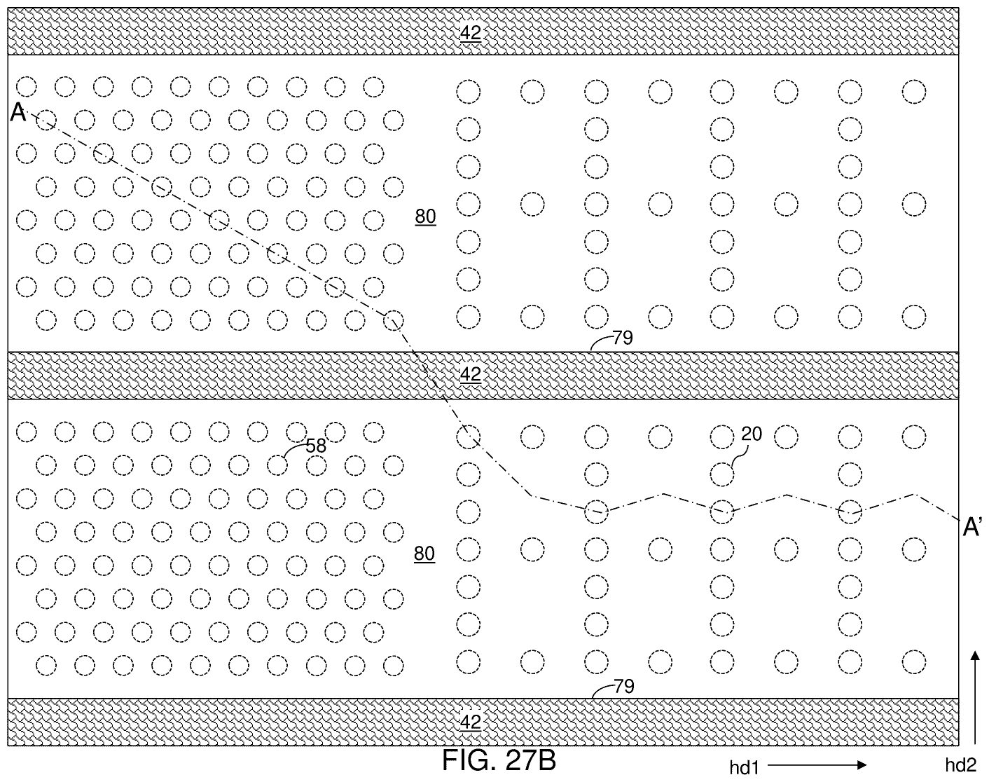

Referring to FIGS. 27A and 27B, the processing steps described with reference to FIGS. 9A and 9B can be performed to form a contact-level dielectric layer 80, lateral isolation trenches 79, and the optional semiconductor oxide barrier layers 112.

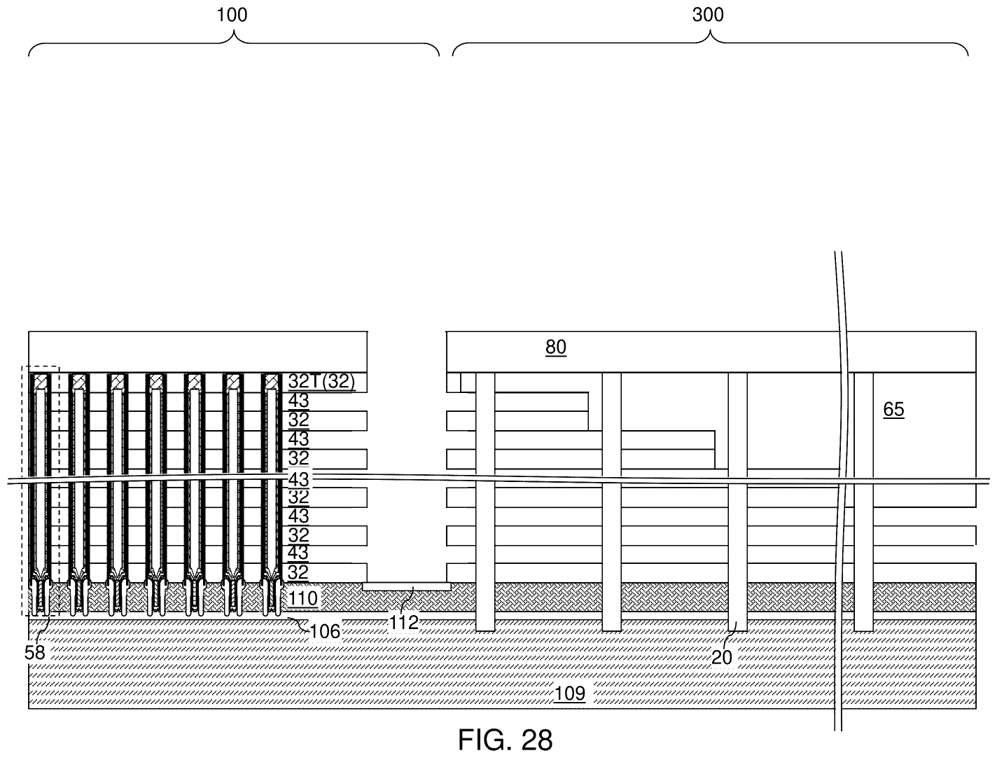

Referring to FIG. 28, the processing steps described with reference to FIG. 10 can be performed to form the laterally-extending cavities 43.

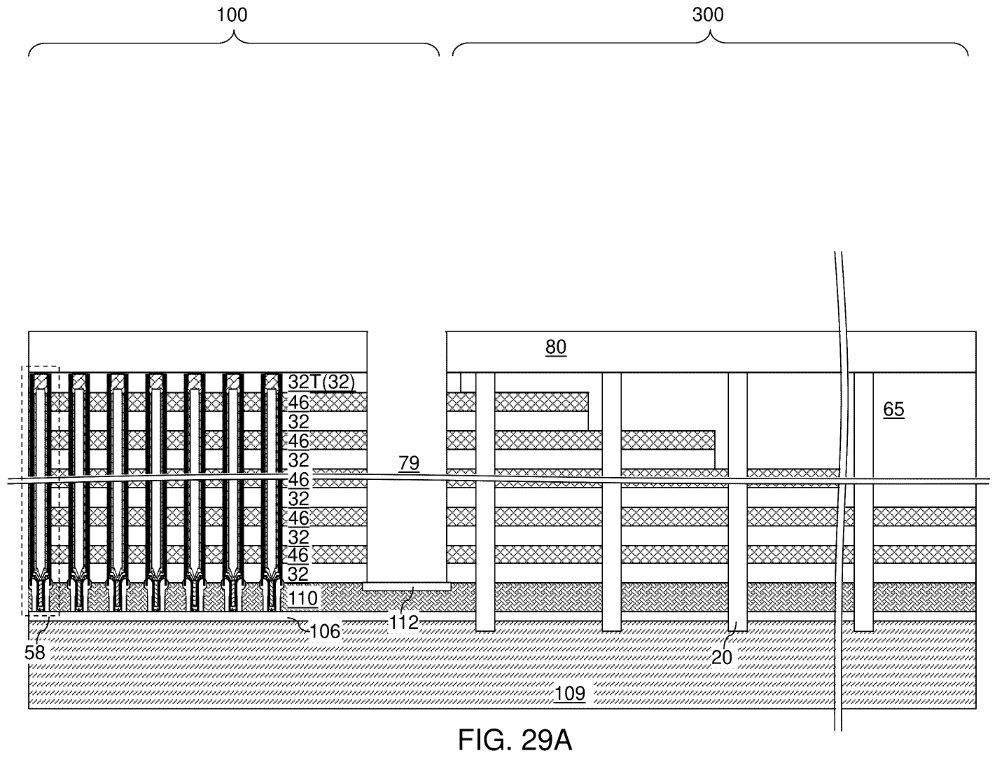

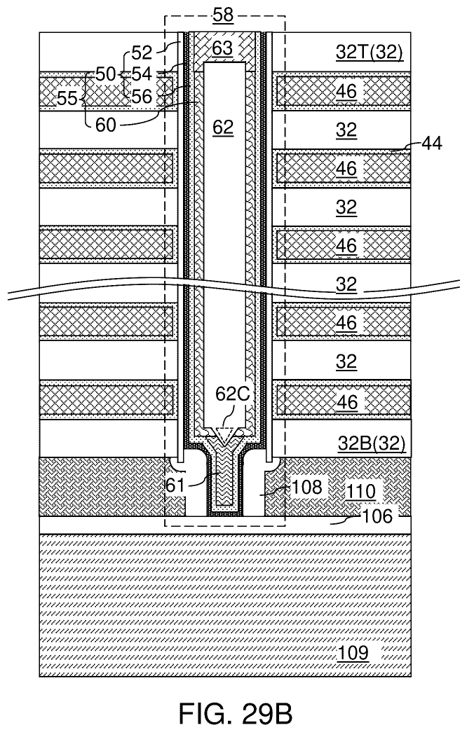

Referring to FIGS. 29A and 29B, the processing steps described with reference to FIGS. 11A and 11B can be performed to form the outer blocking dielectric layer 44 and an electrically conductive layer 46 in each laterally-extending cavity 43.

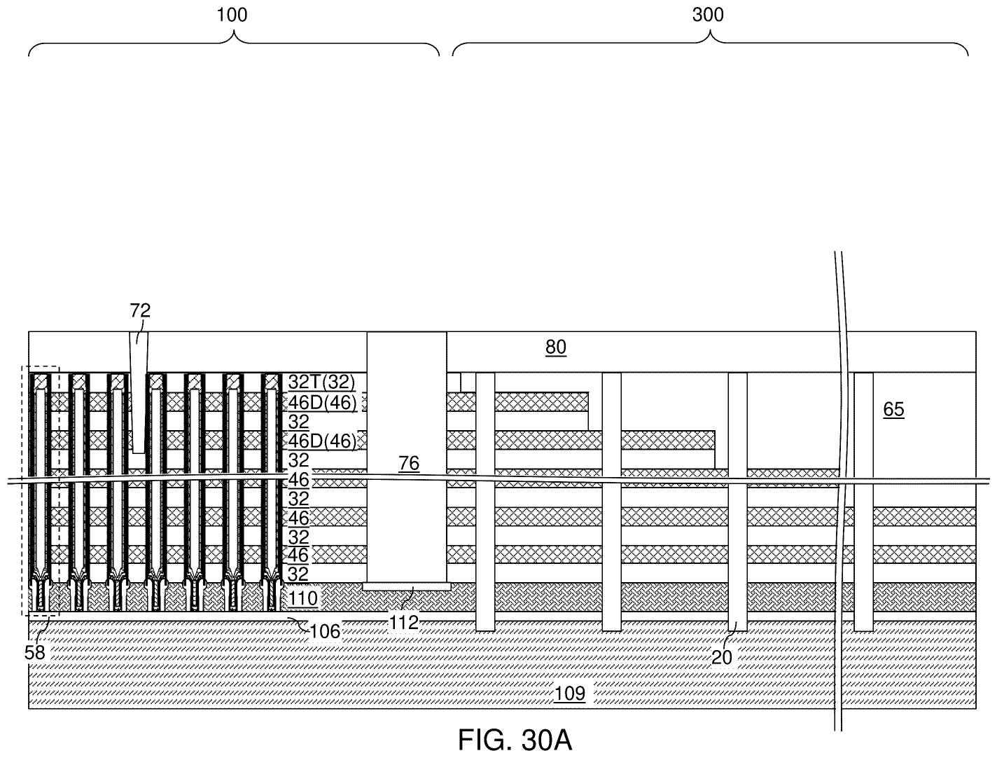

Referring to FIGS. 30A and 30B, the processing steps described with reference to FIGS. 12A and 12B can be performed to form lateral isolation trench fill structures 76 and drain-select-level isolation structures 72.

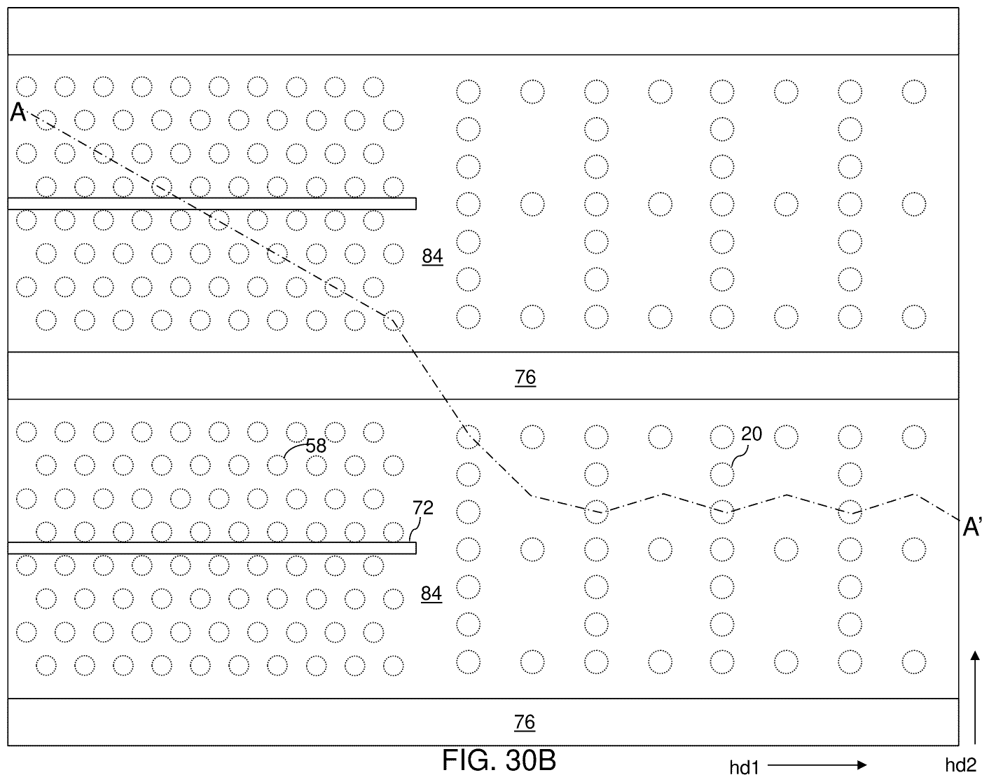

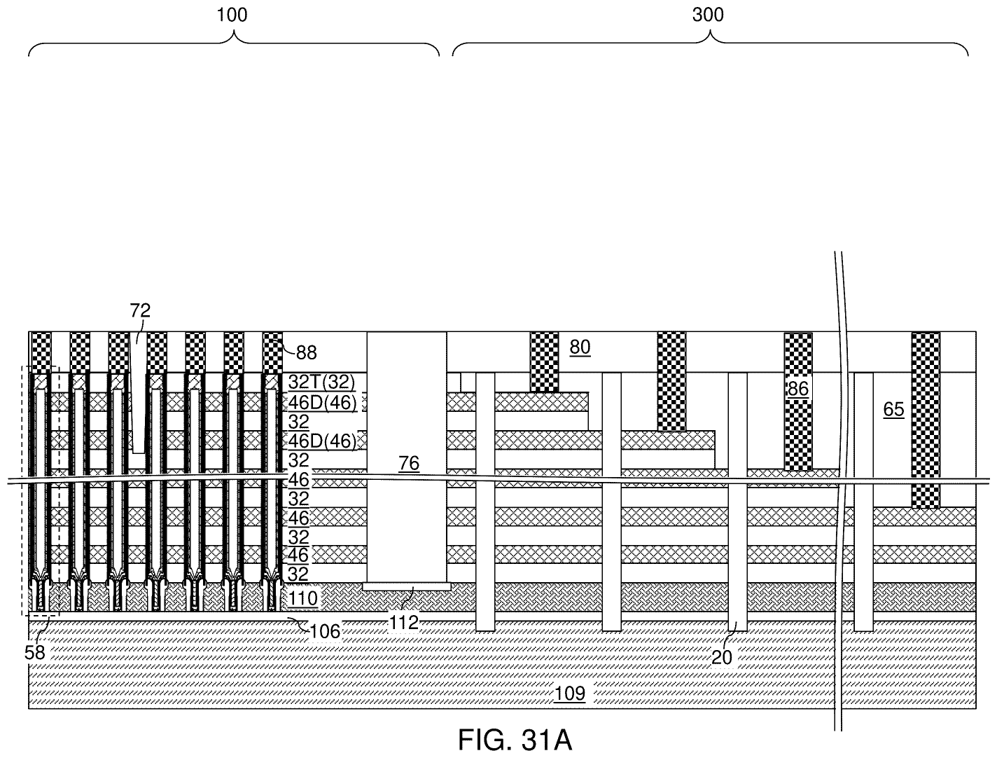

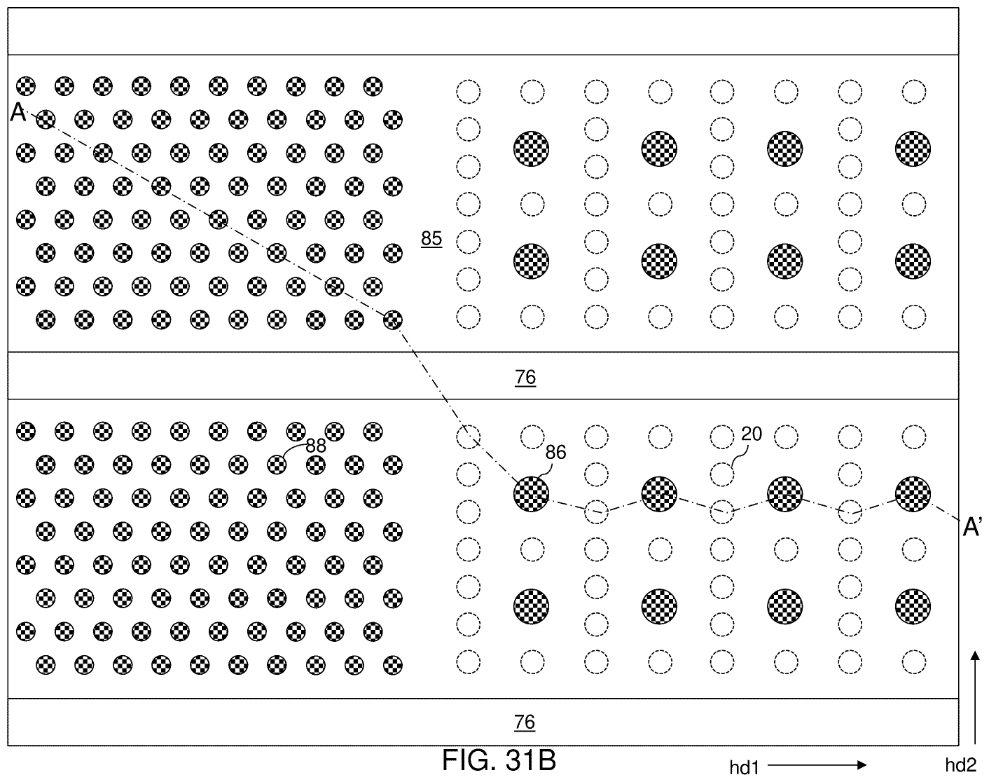

Referring to FIGS. 31A and 31B, the processing steps described with reference to FIGS. 13A and 13B can be performed to form layer contact via structures 86 and drain contact via structures 88.

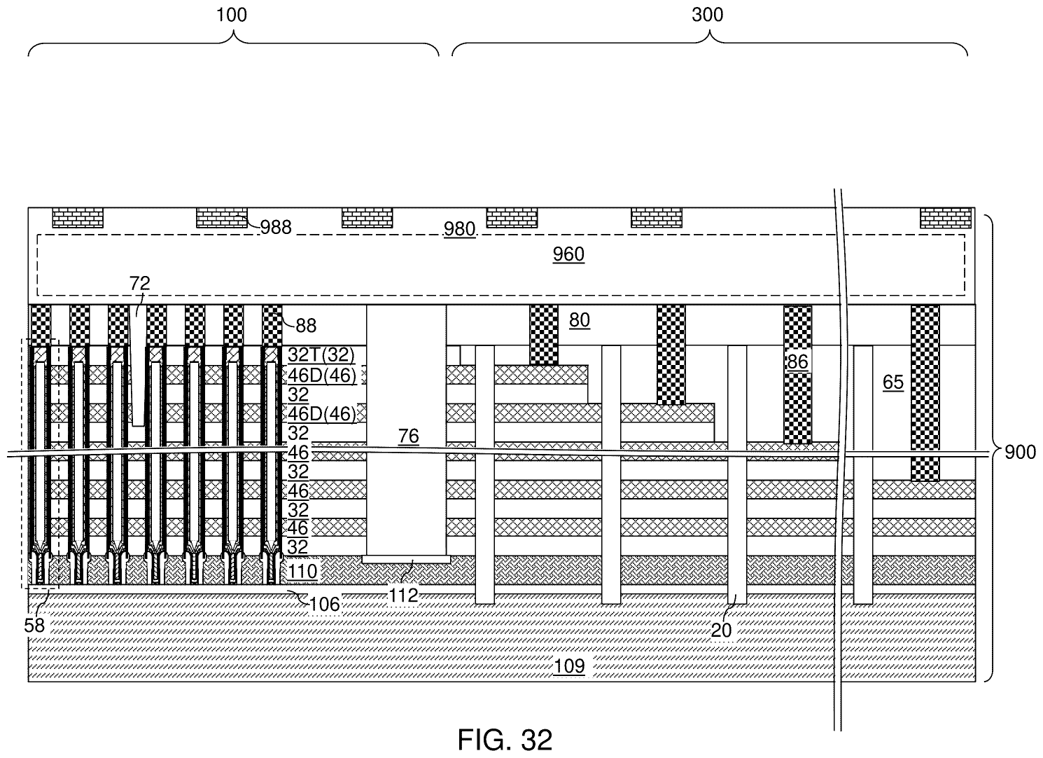

Referring to FIG. 32, the processing steps described with reference to FIG. 14 can be performed to form memory-side dielectric material layers 960 embedding memory-side metal interconnect structures 980 and memory-side bonding pads 988. The memory die 900 is thus formed.

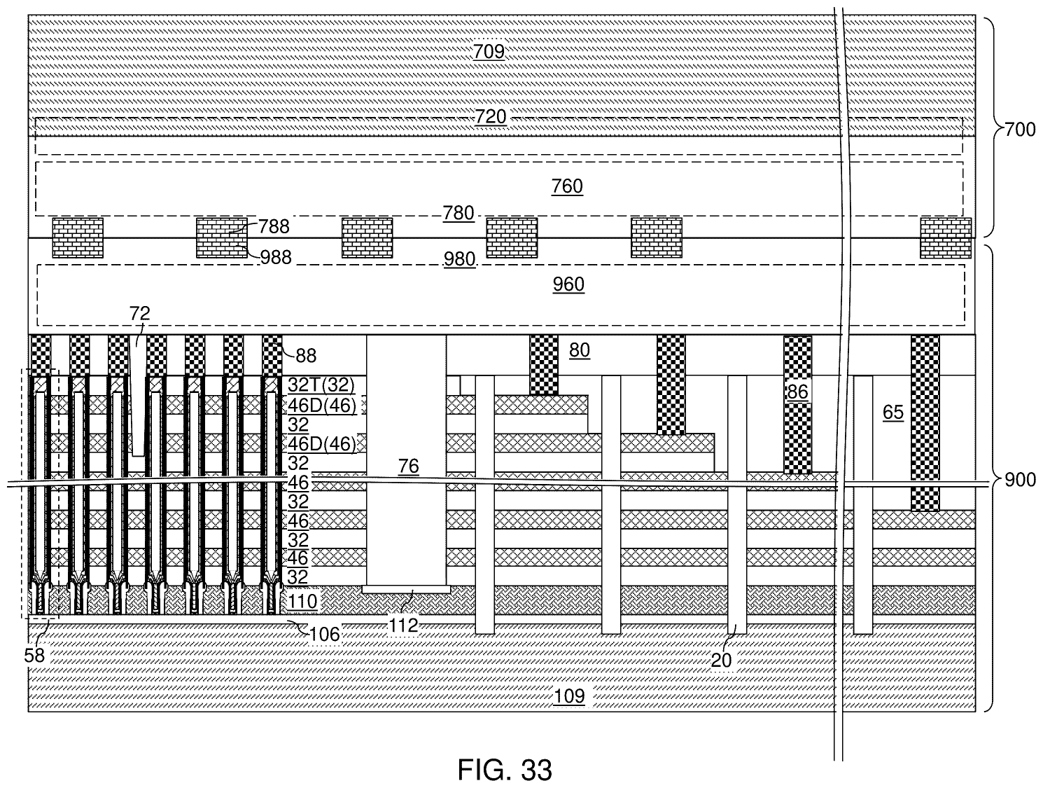

Referring to FIG. 33, the processing steps described with reference to FIGS. 15 and 16 can be performed to bond the logic die 700 to the memory die 900.

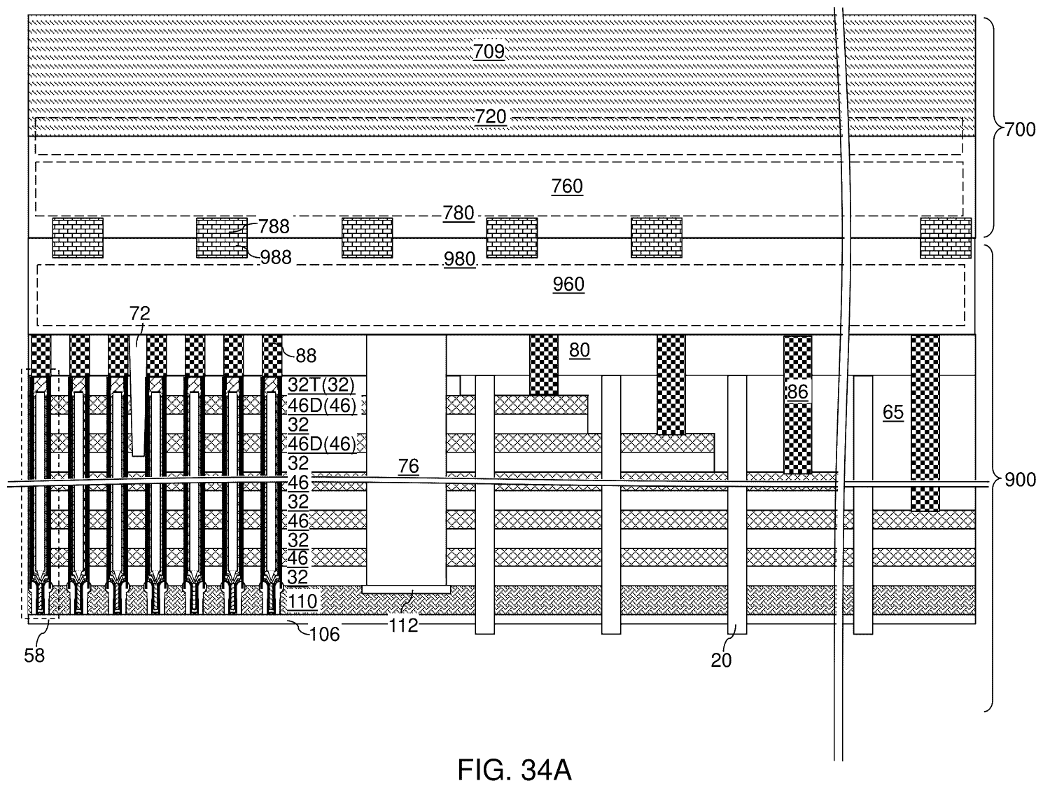

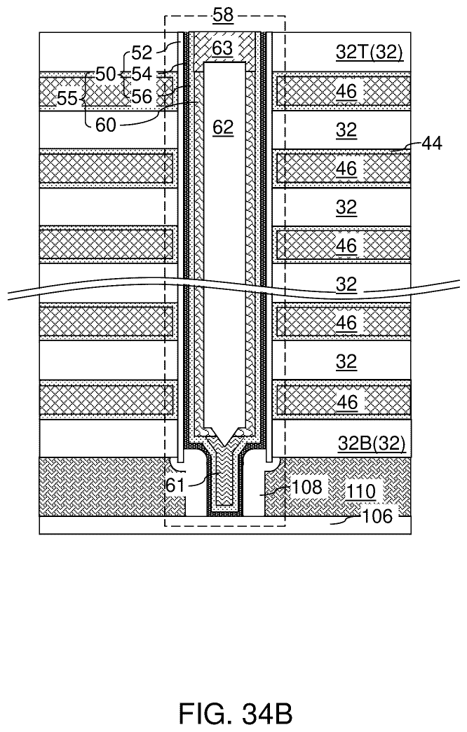

Referring to FIGS. 34A and 34B, the carrier substrate 109 can be removed selective to the backside insulating layer 106, for example, by grinding, polishing, cleaving, an isotropic etch process, an anisotropic etch process, and/or a combination thereof. If an etch process is employed as a terminal step for removing the carrier substrate 109, the backside insulating layer 106 may be employed as an etch stop structure.

In one embodiment, the carrier substrate 109 may comprise a semiconductor substrate, and at least a terminal step of at least one removal process that is employed to remove the carrier substrate 109 may comprise a selective wet etch process that etches the semiconductor material of the carrier substrate 109 selective to the material of the backside insulating layer 106. In an illustrative example, the terminal step of the at least one removal process may comprise a wet etch process using hot trimethyl-2 hydroxyethyl ammonium hydroxide (“hot TMY”) or tetramethyl ammonium hydroxide (TMAH). The entirety of the carrier substrate 109 can be removed by the selective wet etch process. The backside surfaces of the backside insulating layer 106 can be physically exposed upon removal of the carrier substrate 109.

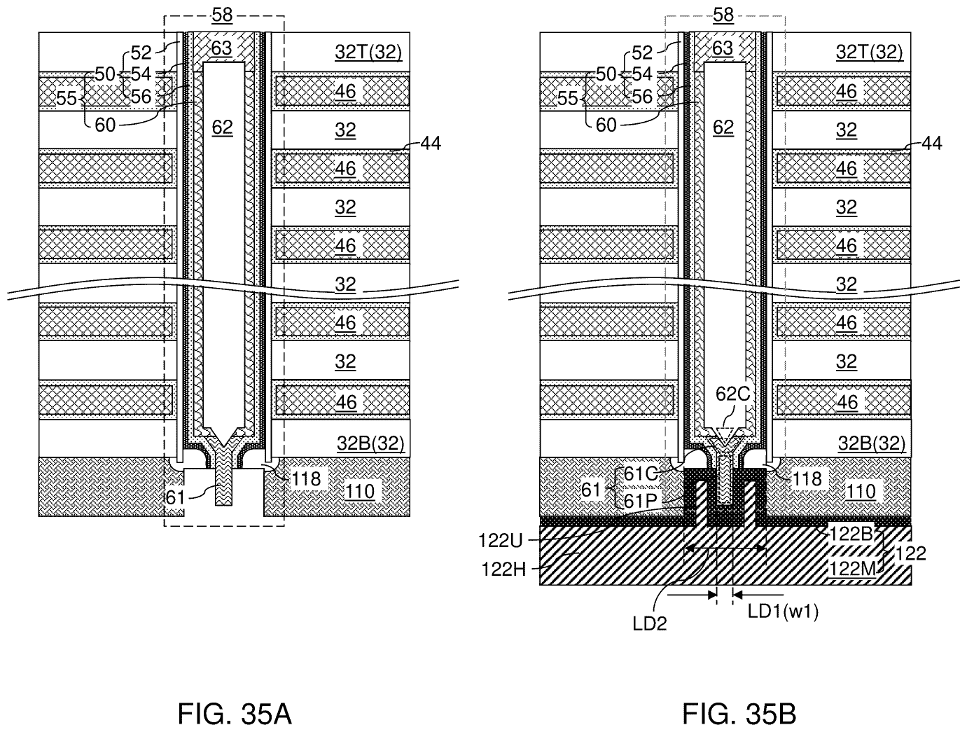

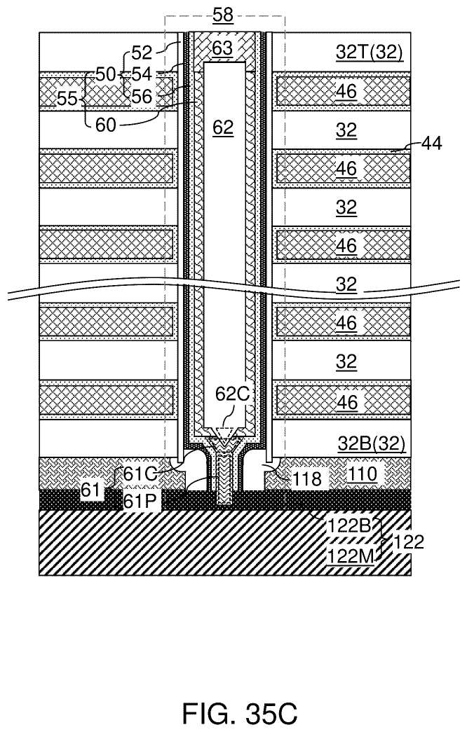

Referring to FIG. 35A, a first isotropic etch process can be performed to etch the materials of the backside insulating layer 106 and the semiconductor oxide spacer structures 108 selective to the material of the semiconductor material layer 110. For example, a wet etch process employing dilute hydrofluoric acid can be performed to etch the entirety of the backside insulating layer 106 and a bottom portion of each semiconductor oxide spacer structure 108. According to an embodiment of the present disclosure, the duration of the first isotropic etch process can be selected such that a top portion of each semiconductor oxide spacer structure 108 remains after the first isotropic etch process. Each remaining top portion of the semiconductor oxide spacer structures 108 has an annular shape, and is herein referred to as an annular dielectric semiconductor oxide spacer 118. Each annular dielectric semiconductor oxide spacer 118 may comprise an annular planar bottom surface.

A second isotropic etch process can be performed to remove physically exposed end portions of the memory material layers 54. For example, if the memory material layers 54 comprise silicon nitride, a wet etch process employing a mixture of phosphoric acid and ethylene glycol can be employed to etch the physically exposed bottom end portions of the memory material layers 54.

In case each memory film 50 comprises a dielectric liner 56, a third isotropic etch process can be performed to remove physically exposed end portions of the dielectric liners 56. For example, a wet etch process employing dilute hydrofluoric acid may be employed to etch physically exposed end portions of the dielectric liners 56. A cylindrical surface and a bottom end surface of each semiconductor source structure 61 can be physically exposed. In summary, the carrier substrate 109, the bottom portion of the semiconductor oxide spacer structure 108, and the bottom portion of the memory film 50 can be removed to expose the bottom end surface of each semiconductor source structure 61.

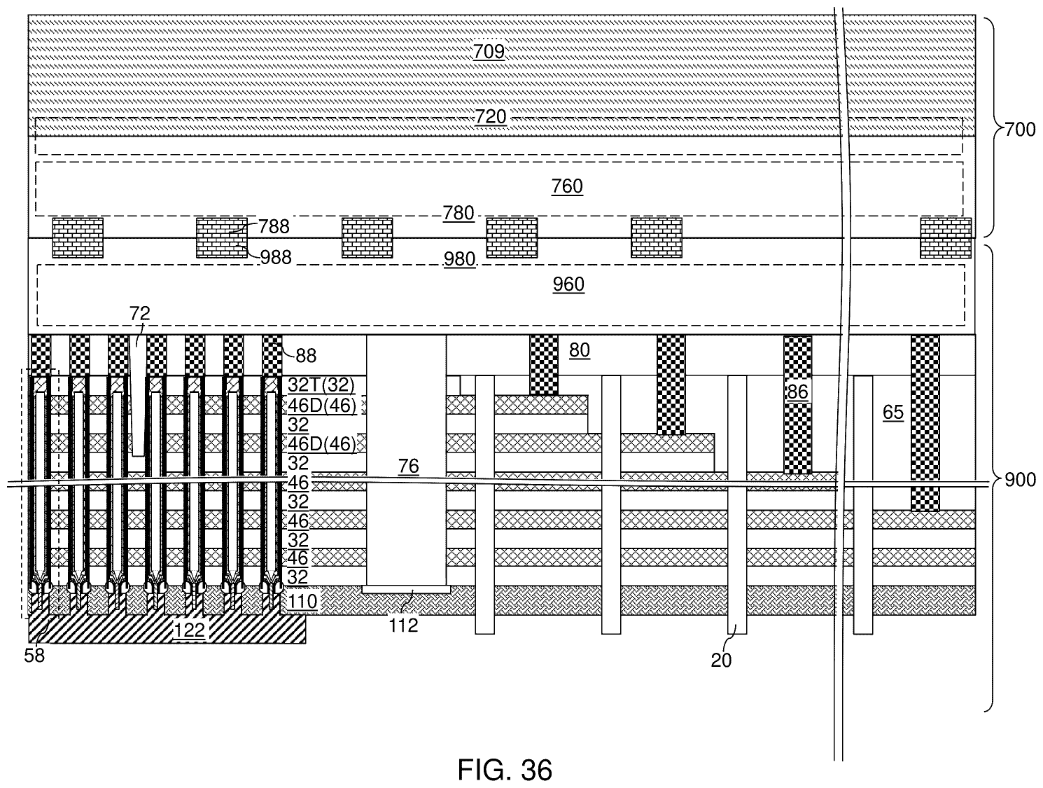

Referring to FIGS. 35B and 36, at least one metallic material can be deposited on the physically exposed surfaces of the semiconductor source structures 61, the memory films 50, the annular dielectric semiconductor oxide spacers 118, and the semiconductor material layer 110 to form a metallic source layer 122. In one embodiment, the metallic source layer 122 may comprise a metallic barrier liner layer 122B and a metal layer 122M. The metallic barrier liner layer 122B may comprise a metallic barrier material such as TiN, TaN, WN, or MON, and may have a thickness in a range from 2 nm to 30 nm, such as from 4 nm to 20 nm. The metal layer 122M comprises a metal such as W, Mo, Ru, Ti, Ta, Co, and/or Cu, and may have thickness in a range from 50 nm to 500 nm. The metallic source layer 122 can be patterned with a suitable pattern.

In one embodiment, each annular dielectric semiconductor oxide spacer 118 comprises: an outer contoured annular surface segment that contacts the semiconductor material layer 110; and an inner contoured annular surface segment that contacts a cylindrical surface segment of a bottom end of the memory material layer 54. In one embodiment, the annular dielectric semiconductor oxide spacer 118 contacts a cylindrical surface segment of a bottom portion of a cylindrical inner sidewall of the blocking dielectric layer 52.

In one embodiment, the metallic source layer 122 comprises a horizontally-extending portion 122H that contacts a bottom surface of the semiconductor material layer 110 and an upward-protruding tubular portion 122U that contacts a cylindrical surface segment of an opening in the semiconductor material layer 110. The upward-protruding tubular portion 122U is located above the horizontal plane including the bottom surface of the semiconductor material layer 110. In one embodiment, the metallic source layer 122 contacts an annular bottom surface of the memory material layer 54 and contacts an annular bottom surface of the dielectric liner 56. In one embodiment, the metallic source layer 122 is not in direct contact with the blocking dielectric layer 52; and an annular dielectric semiconductor oxide spacer 118 comprising a dielectric oxide of a semiconductor material of the semiconductor material layer 110 is interposed between the blocking dielectric layer 52 and the metallic source layer 122.

In one embodiment, the annular dielectric semiconductor oxide spacer 118 comprises an annular top surface contacting an annular bottom surface segment of the memory material layer 54, and comprises an annular bottom surface contacting an annular top surface segment of the upward-protruding tubular portion 122U of the metallic source layer 122. In one embodiment, a lower cylindrical surface segment of the inner sidewall of the blocking dielectric layer 52 contacts a cylindrical surface segment of the annular dielectric semiconductor oxide spacer 118. In one embodiment, an upper cylindrical surface segment of a sidewall of the semiconductor source structure 61 contacts an inner cylindrical surface segment of the memory film 50; and a lower cylindrical surface segment of the sidewall of the semiconductor source structure 61 contacts an inner cylindrical surface of the upward-protruding tubular portion 122U of the metallic source layer 122.

In one embodiment, each semiconductor source structure 61 may comprise a pillar semiconductor source portion 61P having a first lateral dimension LD1 (such as the first width w1), and a cylindrical opening through the semiconductor material layer 110 may have a second lateral opening LD2 that is greater than the first lateral dimension LD2.

FIG. 35C illustrates an alternative configuration of the second exemplary structure of the second embodiment. In this configuration, the semiconductor material layer 110 is thinner than in the configuration shown in FIG. 35B and the semiconductor source structure 61 protrudes below the bottom surface of the semiconductor material layer 110. The metallic source layer 122 contacts the sidewall and the bottom end of the semiconductor source structure 61 that protrude below the bottom surface of the semiconductor material layer 110.

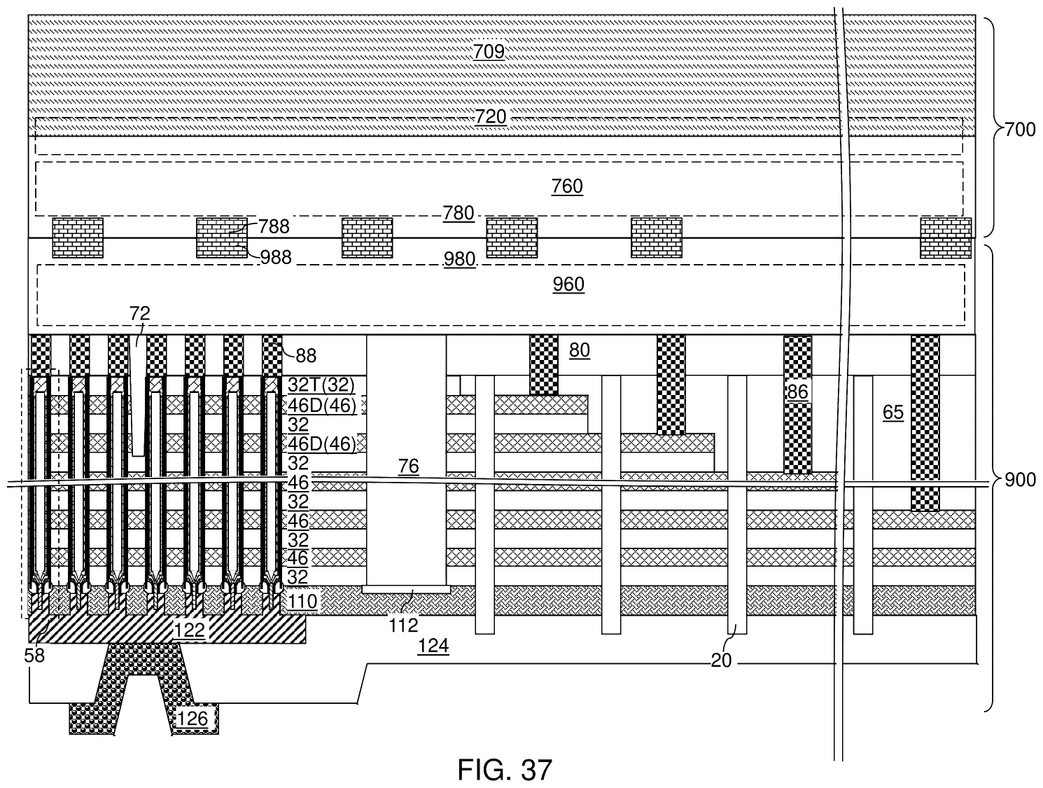

Referring to FIG. 37, a backside dielectric layer 124 can be formed under the metallic source layer 122 and the semiconductor material layer 110. Backside bonding pads 126 can be formed through the backside dielectric layer 124 on bottom surfaces of electrically active nodes, such as the metallic source layer 122 and through-stack via structures (not shown) that vertically extend through peripheral portions of the stepped dielectric material portion 65.

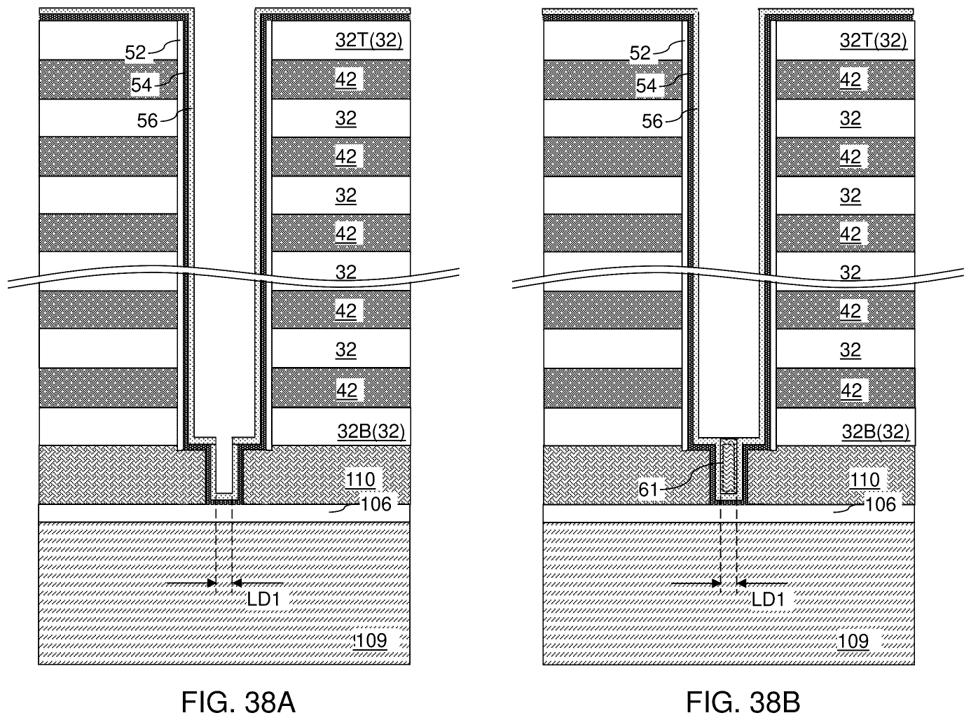

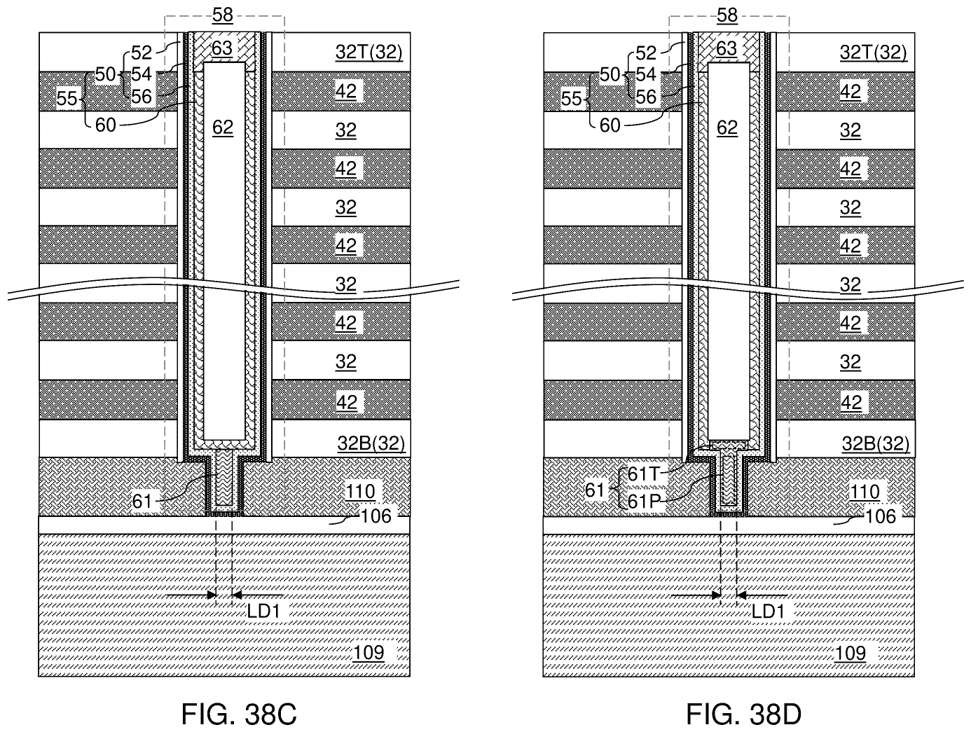

FIGS. 38A-38D are sequential vertical cross-sectional views of a memory opening 49 in an alternative embodiment of the second exemplary structure during formation of a memory opening fill structure 58 according to the second embodiments of the present disclosure.

Referring to FIG. 38A, the alternative configuration of the second exemplary structure can be derived from the second exemplary structure illustrated in FIG. 25E by omitting the processing steps described with reference to FIG. 25F and by performing the processing steps described with reference to FIG. 25G. In other words, formation of the semiconductor oxide spacer structures 108 is omitted, and the memory material layer 54 can be formed directly on the physically exposed cylindrical surface segments and annular horizontal surface segments of the semiconductor material layer 110.

Referring to FIG. 38B, the processing steps described with reference to FIGS. 25H and 25I can be performed to form a semiconductor source structure 61 at the bottom of each memory opening 49.

Referring to FIG. 38C, the processing steps described with reference to FIGS. 25J-25M can be performed to form a vertical semiconductor channel 60, a dielectric core 62, and a drain region 63 within each memory opening 49.

Referring to FIG. 38D, the processing steps described with reference to FIG. 25N may be performed to active electrical dopants in the semiconductor source structures 61, the vertical semiconductor channels 60, and the drain regions 63. Each semiconductor source structure 61 may comprise a pillar semiconductor source portion 61P and a plate semiconductor source portion 61T overlying, and having a greater lateral extent than, the pillar semiconductor source portion 61P.

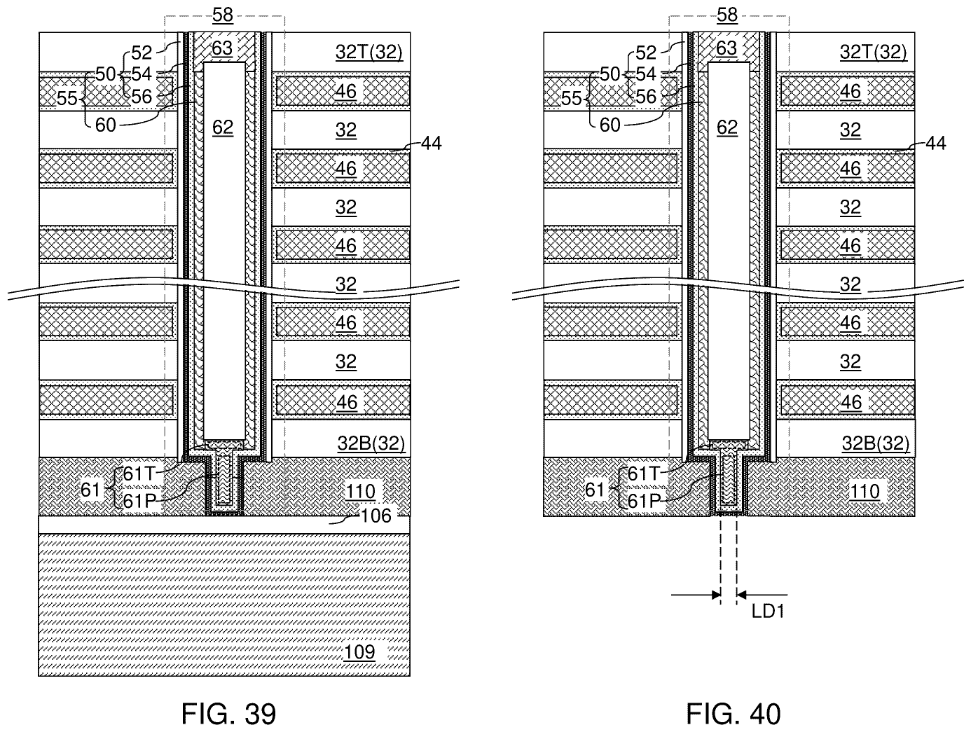

Referring to FIG. 39, the processing steps described with reference to FIGS. 9A-11B can be performed to replace the sacrificial material layers 42 with electrically conductive layers 46.

Referring to FIG. 40, the processing steps described with reference to FIGS. 12A-16 and FIGS. 34A and 34B can be performed to form a bonded assembly including a memory die 900 and a logic die 700, and to remove the carrier substrate 109.

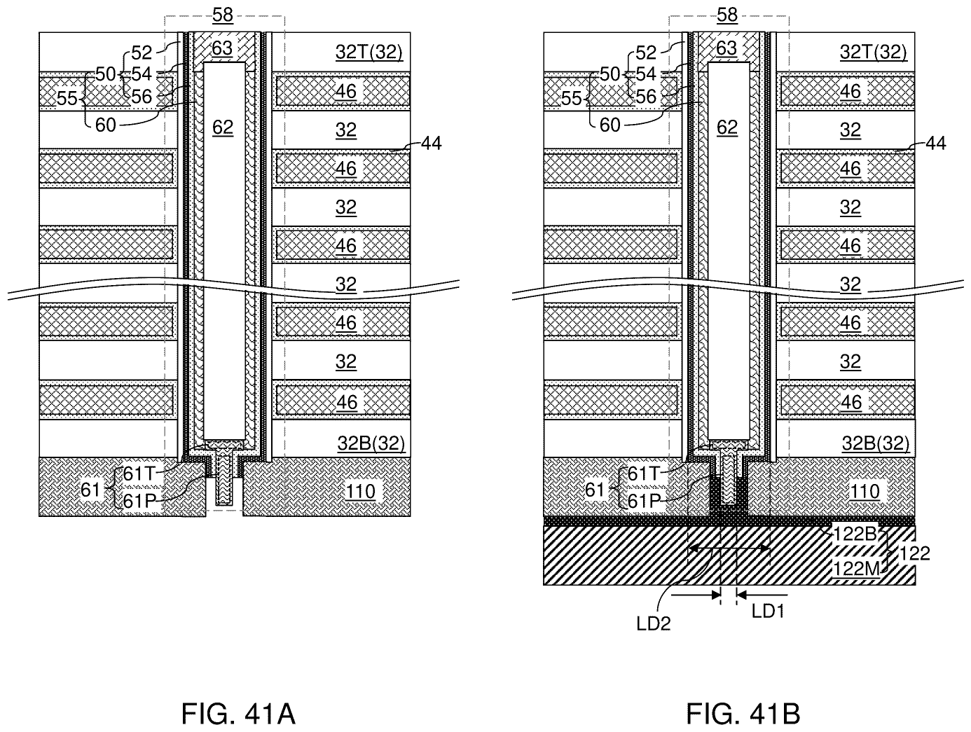

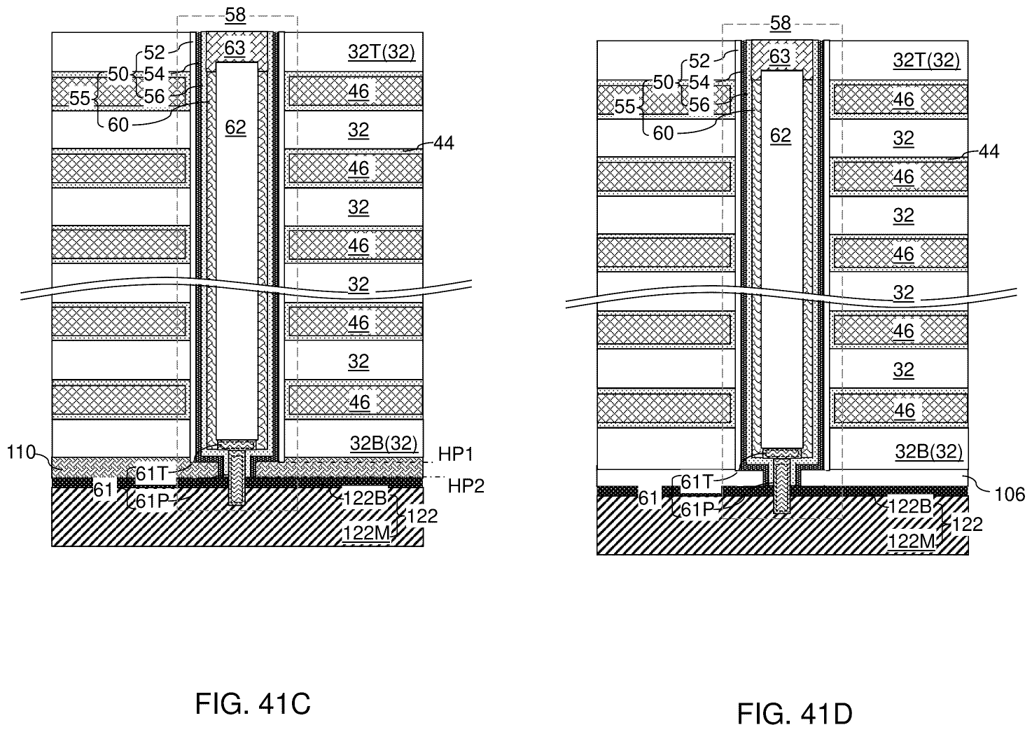

Referring to FIG. 41A, the processing steps described with reference to FIG. 35A can be performed with a modification in view of the absence of the semiconductor oxide spacer structures 108. In this case, the isotropic etch step for etching the material of the semiconductor oxide spacer structures 108 can be omitted. A cylindrical surface segment of each semiconductor source structure 61 may be physically exposed.

Referring to FIG. 41B, the processing steps described with reference to FIG. 35B can be performed to deposit and pattern a metallic source layer 122. In one embodiment, each semiconductor source structure 61 may comprise a pillar semiconductor source portion 61P having a first lateral dimension LD1 (such as the first width w1), and a cylindrical opening through the semiconductor material layer 110 may have a second lateral opening LD2 that is greater than the first lateral dimension LD2.

FIG. 41C illustrates a first alternative configuration of the alternative embodiment of the second exemplary structure of the second embodiment. In this configuration, the semiconductor material layer 110 is thinner than in the configuration shown in FIG. 41B and the semiconductor source structure 61 protrudes below the bottom surface of the semiconductor material layer 110. The metallic source layer 122 contacts the sidewall and the bottom end of the semiconductor source structure 61 that protrude below the bottom surface of the semiconductor material layer 110. The bottom end of the blocking dielectric layer 52 is located in a first horizontal plane HP1, while the bottom end of the memory material layer 54 and the bottom end of the dielectric liner 56 are located in a second horizontal plane HP2 located below the first horizontal plane HP1.

FIG. 41D illustrates a second alternative configuration of the alternative embodiment of the second exemplary structure of the second embodiment. In this configuration, the semiconductor material layer 110 is omitted and the semiconductor source structure 61 protrudes below the bottom surface of the alternating stack (32, 46) (e.g., below the bottom surface of the bottommost insulating layer 32B of the alternating stack). The metallic source layer 122 contacts the sidewall and the bottom end of the semiconductor source structure 61 that protrude below the bottom surface of the alternating stack (32, 46). Optionally, at least a portion of the backside insulating layer 106 may be retained in the completed device of this configuration.

Referring collectively to FIGS. 21-41D, a memory device may comprise: an alternating stack (32, 46) of insulating layers 32 and electrically conductive layers 46; a memory opening 49 vertically extending through the alternating stack (32, 46); a memory opening fill structure 58 located in the memory opening 49 and comprising a memory film 50, a vertical semiconductor channel 60, a semiconductor source structure 61 adjoined to a first end of the vertical semiconductor channel 60, and a drain region 63 contacting a second end of the vertical semiconductor channel 60; and a metallic source layer 122 that contacts a bottom end and a sidewall of the semiconductor source structure 61.

In one embodiment, the memory film 50 comprises a layer stack that includes, from outside to inside, a blocking dielectric layer 52, a memory material layer 54, and a dielectric liner 56. A bottom end of the blocking dielectric layer is located in a first horizontal plane HP1; and a bottom end of the memory material layer and a bottom end of the dielectric liner are located in a second horizontal plane HP2 located below the first horizontal plane HP1.

In one embodiment, an entirety of the cylindrical surface segment of the opening in the semiconductor material layer 110 is located within a cylindrical vertical plane that contains an entirety of a cylindrical interface between the blocking dielectric layer 52 and the memory material layer 54.

In one embodiment, the memory device further comprises a semiconductor material layer 110 located between the metallic source layer 122 and the alternating stack (32, 46), wherein the semiconductor material layer 110 at least partially surrounds the semiconductor source structure 61.

In one embodiment, the metallic source layer 122 comprises a horizontally-extending portion 122H that contacts a bottom surface of the semiconductor material layer and an upward-protruding tubular portion 122U that contacts a cylindrical surface segment of an opening in the semiconductor material layer 110.

In one embodiment, the memory device further comprises an annular dielectric semiconductor oxide spacer 118 comprising: an outer contoured annular surface segment that contacts the semiconductor material layer 110; and an inner contoured annular surface segment that contacts a cylindrical surface segment of the bottom end of the memory material layer 54. In one embodiment, the annular dielectric semiconductor oxide spacer 118 contacts a cylindrical surface segment of a bottom portion of a cylindrical inner sidewall of the blocking dielectric layer 52.

In one embodiment, the metallic source layer 122 contacts an annular bottom surface of the bottom end of the memory material layer 54 and contacts an annular bottom surface of the bottom end of the dielectric liner 56. In one embodiment, the metallic source layer 122 is not in direct contact with the blocking dielectric layer 52; and an annular dielectric semiconductor oxide spacer 118 comprising a dielectric oxide of a semiconductor material of the semiconductor material layer 110 is interposed between the blocking dielectric layer 52 and the metallic source layer 122. In one embodiment, the annular dielectric semiconductor oxide spacer 118 comprises an annular top surface contacting an annular bottom surface segment of the memory material layer 54, and comprises an annular bottom surface contacting an annular top surface segment of the upward-protruding tubular portion of the metallic source layer 122.

In one embodiment, the memory material layer 54 comprises: a first cylindrical portion contacting an upper cylindrical surface segment of an inner sidewall of the blocking dielectric layer 52; a second cylindrical portion contacting an inner cylindrical surface segment of the annular dielectric semiconductor oxide spacer 118; and a connecting portion that connects a top end of the second cylindrical portion to a bottom end of the first cylindrical portion. In one embodiment, a lower cylindrical surface segment of the inner sidewall of the blocking dielectric layer 52 contacts a cylindrical surface segment of the annular dielectric semiconductor oxide spacer 118.

In one embodiment, the semiconductor source structure 61 comprises: a pillar semiconductor source portion 61P having a uniform lateral dimension; and a plate semiconductor source portion 61T overlying and having a greater lateral extent than the pillar semiconductor source portion 61P.

In one embodiment, an upper cylindrical surface segment of a sidewall of the semiconductor source structure 61 contacts an inner cylindrical surface segment of the memory film 50; and a lower cylindrical surface segment of the sidewall of the semiconductor source structure 61 contacts an inner cylindrical surface of the metallic source layer 122. In one embodiment, the memory opening fill structure 58 also comprises a dielectric core 62 that is partially laterally surrounded by the vertical semiconductor channel 60; and the dielectric core 62 comprises a conical bottom tip portion 62C contacting a conical inner surface of the conical semiconductor source portion 61C. In one embodiment, the semiconductor source structure 61 comprises atoms of an electrical dopant therein; and the dielectric core 62 has a homogeneous material composition throughout and is free of the electrical dopant.

The various embodiments of the present disclosure form semiconductor source structures 61 prior to formation of drain regions 63, and activates dopants in the semiconductor source structures 61 concurrently with activation of dopants in the drain regions 63 and optionally crystallizes the material of the semiconductor source structure 61. Formation of the semiconductor source structures 61 is performed entirely before bonding a memory die 900 to a logic die 700. Therefore, laser anneal source dopant activation process and/or a source laser crystallization process after bonding the memory die 900 to the logic die 700 may be omitted.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A memory device, comprising:
an alternating stack of insulating layers and electrically conductive layers located over a semiconductor material layer;
a memory opening vertically extending through the alternating stack and through the semiconductor material layer; and
a memory opening fill structure located in the memory opening and comprising a vertical semiconductor channel that vertically extends through each electrically conductive layer in the alternating stack, a semiconductor source structure adjoined to a first end of the vertical semiconductor channel and laterally surrounded by the semiconductor material layer, and a drain region contacting a second end of the vertical semiconductor channel,
wherein the semiconductor source structure comprises a pillar semiconductor source portion having a first width along a horizontal direction and a tubular semiconductor source portion having an inner cavity and an outer cylindrical surface which has a second width along the horizontal direction, the second width being greater than the first width.

2. The memory device of claim 1, wherein the semiconductor source structure further comprises a conical semiconductor source portion connecting the pillar semiconductor source portion and the tubular semiconductor source portion.

3. The memory device of claim 2, wherein:
the pillar semiconductor source portion comprises a cylindrical sidewall surface; and
the conical semiconductor source portion comprises a lateral conical surface that connects a top periphery of the cylindrical sidewall surface of the pillar semiconductor source portion to a bottom periphery of the outer cylindrical surface of the tubular semiconductor source portion.

4. The memory device of claim 2, wherein the vertical semiconductor channel comprises:
a first tubular channel portion having a first cylindrical outer sidewall that has the second width along the horizontal direction; and
a second tubular channel portion having a second cylindrical outer sidewall that has a third width along the horizontal direction, the third width being greater than the second width.

5. The memory device of claim 4, wherein the vertical semiconductor channel further comprises a connecting tapered tubular channel portion that connects the first tubular channel portion and the second tubular channel portion, and having a variable lateral dimension that increases with a vertical distance from a horizontal plane including a bottom surface of the semiconductor material layer.

6. The memory device of claim 4, wherein a bottom periphery of the first cylindrical outer sidewall of the first tubular channel portion coincides with a top periphery of the outer cylindrical surface of the tubular semiconductor source portion.

7. The memory device of claim 4, wherein the memory opening fill structure further comprises a dielectric core that is laterally surrounded by the vertical semiconductor channel.

8. The memory device of claim 7, wherein the dielectric core comprises:
a first cylindrical dielectric core portion that is laterally surrounded by the first tubular channel portion and the tubular semiconductor source portion and has a first lateral dimension; and
a second cylindrical dielectric core portion that is laterally surrounded by the second tubular channel portion and has a second lateral dimension that is greater than the first lateral dimension.

9. The memory device of claim 7, wherein:
the semiconductor source structure comprises atoms of an electrical dopant therein; and
the dielectric core has a homogeneous material composition throughout and is free of the electrical dopant.

10. The memory device of claim 1, wherein the memory opening fill structure comprises a memory film that laterally surrounds the vertical semiconductor channel and the semiconductor source structure.

11. The memory device of claim 1, further comprising an annular dielectric semiconductor oxide spacer comprising an outer cylindrical sidewall that contacts an upper cylindrical sidewall surface segment of an opening in the semiconductor material layer.

12. The memory device of claim 11, further comprising a metallic source layer that comprises a horizontally-extending portion that contacts a bottom surface of the semiconductor material layer and an upward-protruding tubular portion that contacts a lower cylindrical surface segment of the opening in the semiconductor material layer.

13. The memory device of claim 12, wherein:
the metallic source layer further comprises a downward-protruding portion that underlies the semiconductor source structure;
the upward-protruding tubular portion of the metallic source layer contacts an entirety of a cylindrical sidewall surface of the pillar semiconductor source portion.

14. The memory device of claim 1, wherein:
the vertical semiconductor channel comprises p-type polysilicon;
the semiconductor material layer comprises intrinsic or lightly doped polysilicon layer; and
the semiconductor source structure comprises heavily doped n-type polysilicon having a higher doping concentration than the semiconductor material layer.

15. A method of forming a device structure, comprising:
forming a semiconductor material layer and an alternating stack of insulating layers and spacer material layers over a semiconductor substrate, wherein the spacer material layers are formed as, or are subsequently replaced with, electrically conductive layers;
forming a memory opening vertically extending through the alternating stack, the semiconductor material layer, and an upper portion of the semiconductor substrate;
oxidizing surface portions of the semiconductor material layer and the semiconductor substrate around a bottom portion of the memory opening to form a semiconductor oxide spacer structure including a first cylindrical portion having a first thickness at a level of the semiconductor substrate and a second cylindrical portion having a second thickness at a level of the semiconductor material layer, wherein the first thickness is greater than the second thickness;
forming a memory opening fill structure comprising a memory film, a semiconductor source structure, a vertical semiconductor channel, a dielectric core, and a drain region in a remaining volume of the memory opening;
removing the semiconductor substrate, a bottom portion of the semiconductor oxide spacer structure, and a bottom portion of the memory film; and
forming a metallic source layer on the semiconductor source structure.

16. The method of claim 15, wherein:
the semiconductor source structure is formed after formation of the memory film within a first void of the memory opening that is laterally surrounded by the first cylindrical portion of the semiconductor oxide spacer structure; and
a top surface of the semiconductor source structure is formed at or below a horizontal plane including a bottom surface of the semiconductor material layer.

17. The method of claim 15, wherein:
the semiconductor source structure is formed by conformally depositing a heavily-doped semiconductor material layer over the memory film and by isotropically recessing the doped semiconductor material layer; and
the vertical semiconductor channel is formed by depositing a semiconductor channel material layer 60L that is intrinsic or includes dopants at an atomic concentration less than 3×10¹⁶/cm³.

18. The method of claim 15, further comprising crystallizing the semiconductor source structure prior to removing the semiconductor substrate.

19. The method of claim 15, wherein:
a top portion of the semiconductor oxide spacer structure that remains after removal of the bottom portion of the semiconductor oxide spacer structure comprises an annular dielectric semiconductor oxide spacer;
an outer cylindrical sidewall of the annular dielectric semiconductor oxide spacer contacts an upper cylindrical surface segment of an opening in the semiconductor material layer; and
an inner cylindrical sidewall of the annular dielectric semiconductor oxide spacer contacts a cylindrical surface segment of the memory film.

20. The method of claim 15, wherein:
the metallic source layer is formed directly on a lower cylindrical surface segment of an opening in the semiconductor material layer;
the vertical semiconductor channel comprises p-type polysilicon;
the semiconductor material layer comprises intrinsic or lightly doped polysilicon layer; and
the semiconductor source structure comprises heavily doped n-type polysilicon having a higher doping concentration than the semiconductor material layer.
